(19) United States
(12) Patent Application Publication
(10) Pub. No.: US 2024/0405109 A1
(43) Pub. Date: Dec. 5, 2024

(54) SEMICONDUCTOR DEVICE AND METHOD FOR PRODUCING SAME

(71) Applicant: ROHM CO., LTD., Kyoto-shi (JP)

(72) Inventor: Suguru HONDO, Kyoto-shi (JP)

(73) Assignee: ROHM CO., LTD., Kyoto-shi (JP)

(21) Appl. No.: 18/804,007

(22) Filed: Aug. 14, 2024

Related U.S. Application Data
(63) Continuation of application No. PCT/JP2022/041528, filed on Nov. 8, 2022.

(30) Foreign Application Priority Data
Feb. 18, 2022 (JP) 2022-023925
Feb. 18, 2022 (JP) 2022-023926

(51) Int. Cl. H01L 29/739; H01L 29/49; H01L 29/66

(52) U.S. Cl. CPC H01L 29/7397; H01L 29/4958; H01L 29/66348

(57) ABSTRACT

A semiconductor device includes a chip having a main surface, an IGBT region formed at the main surface, a diode region formed at the main surface, an insulating film formed on the main surface so as to expose the diode region and so as to cover the IGBT region, a plug electrode embedded in a part, which covers the IGBT region, of the insulating film so as to be partially exposed from the insulating film, and a main surface electrode that includes a first electrode film covering the plug electrode so as to expose the diode region and a second electrode film covering the first electrode film and the diode region.

### CROSS-REFERENCE TO RELATED APPLICATIONS

The present application is a bypass continuation of International Patent Application No. PCT/JP2022/041528, filed on Nov. 8, 2022, which claims the benefit of priority to Japanese Patent Application No. 2022-023925 filed in the Japan Patent Office on Feb. 18, 2022 and Japanese Patent Application No. 2022-023926 filed in the Japan Patent Office on Feb. 18, 2022, the entire disclosures of these applications are incorporated herein by reference.

### BACKGROUND

### 1. Field of the Disclosure

The present disclosure relates to a semiconductor device and a manufacturing method for the semiconductor device.

### BACKGROUND ART

### 2. Description of the Related Art

US2017/0047322A1 discloses a semiconductor device that includes a semiconductor substrate, an IGBT (Insulated Gate Bipolar Transistor) portion, an FWD (Free Wheeling Diode) portion, an interlayer insulating film, a contact plug, and an emitter electrode. The IGBT portion is formed in a surface of the semiconductor substrate. The FWD portion is formed in a region, which differs from that of the IGBT portion, at the surface of the semiconductor substrate. The interlayer insulating film covers the surface of the semiconductor substrate.

The interlayer insulating film has a first contact hole that exposes the IGBT portion and a second contact hole that exposes the FWD portion. The contact plug is embedded in the first contact hole and is electrically connected to the IGBT portion. The emitter electrode covers the contact plug on the interlayer insulating film and covers the FWD portion in the second contact hole.

### BRIEF DESCRIPTION OF THE DRAWINGS

FIG. 1 is a plan view showing a semiconductor device according to an embodiment.

FIG. 2 is a plan view showing a layout example of a first main surface shown in FIG. 1.

FIG. 3 is an enlarged plan view of region III shown in FIG. 2.

FIG. 4 is an enlarged plan view of region IV shown in FIG. 3.

FIG. 5 is an enlarged plan view of region V shown in FIG. 4.

FIG. 6 is an enlarged plan view of region VI shown in FIG. 4.

FIG. 7 is a cross sectional view along line VII-VII shown in FIG. 5.

FIG. 8 is a cross sectional view along line VIII-VIII shown in FIG. 6.

FIG. 9 is a cross sectional view along line IX-IX shown in FIG. 5.

FIG. 10 is a cross sectional view along line X-X shown in FIG. 6.

FIG. 11 is an enlarged plan view of region XI shown in FIG. 1.

FIG. 12 is a cross sectional view along line XII-XII shown in FIG. 11.

FIGS. 13A to 13U are cross sectional views showing an example of a manufacturing method for the semiconductor device shown in FIG. 1.

FIG. 14 is a cross sectional view showing a semiconductor device according to a first modification.

FIG. 15 is a cross sectional view showing a semiconductor device according to a second modification.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not necessarily overlap with each other in reduced scale and the like. Also, the same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

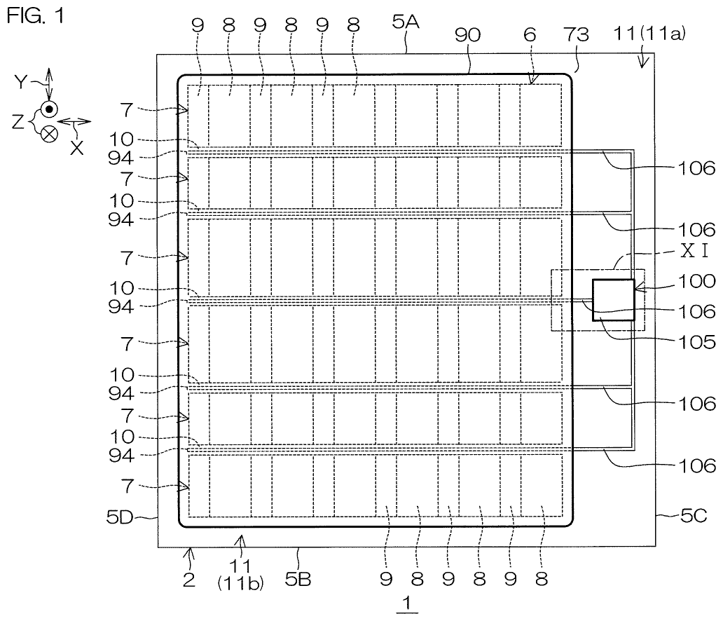

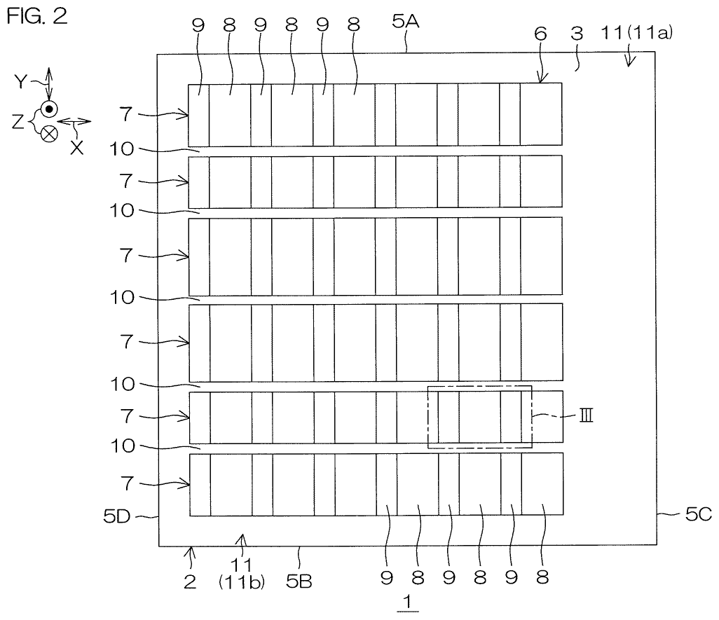

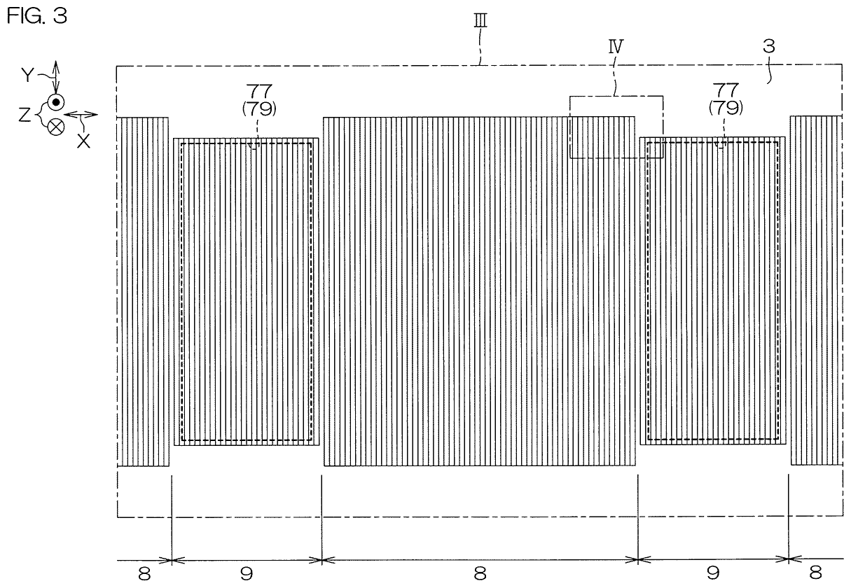

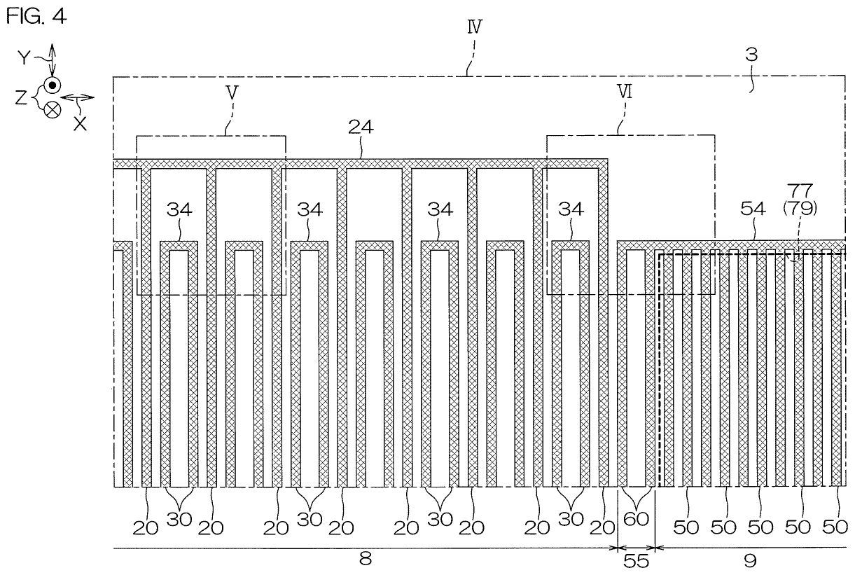

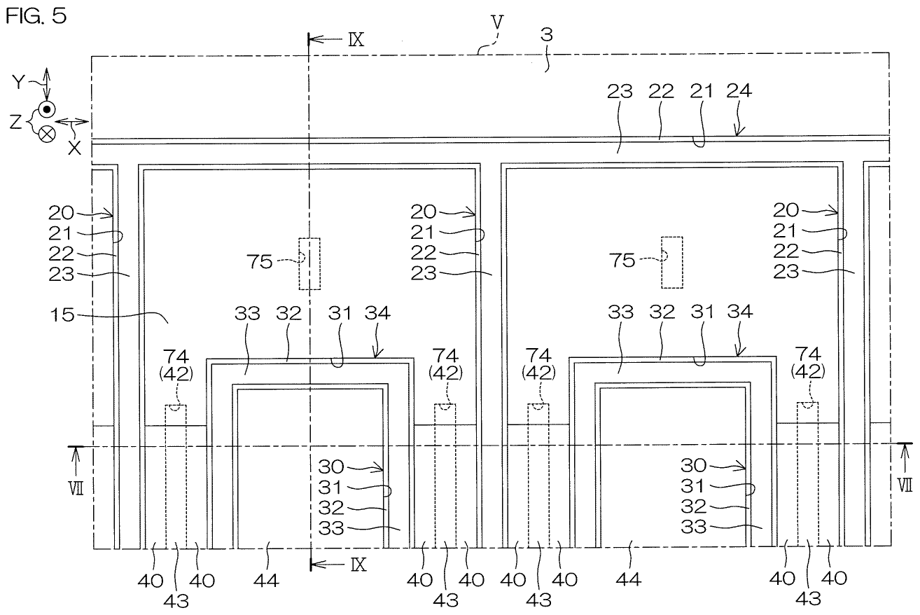

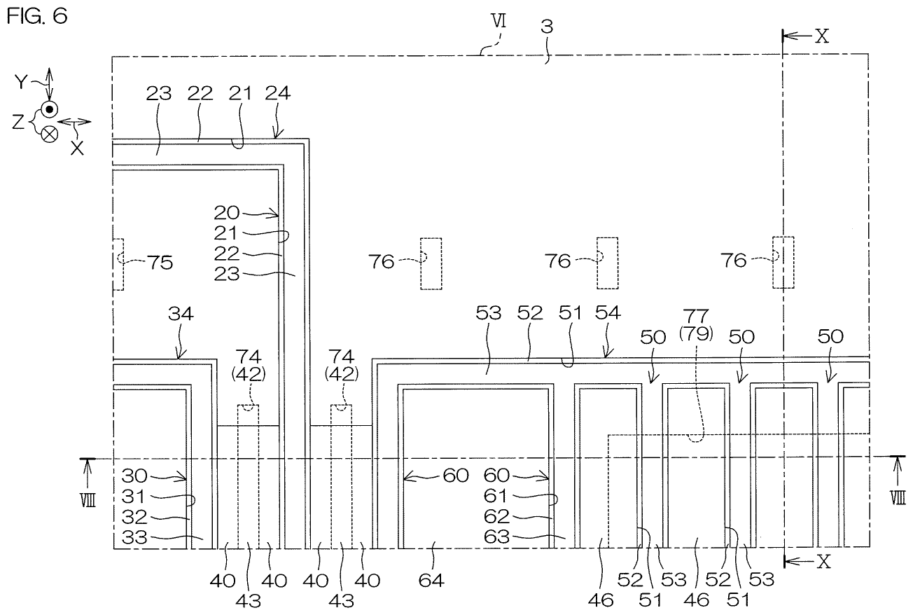

FIG. 1 is a plan view showing a semiconductor device 1 according to an embodiment. FIG. 2 is a plan view showing a layout example of a first main surface 3 shown in FIG. 1. FIG. 3 is an enlarged plan view of region III shown in FIG. 2. FIG. 4 is an enlarged plan view of region IV shown in FIG. 3. FIG. 5 is an enlarged plan view of region V shown in FIG. 4. FIG. 6 is an enlarged plan view of region VI shown in FIG. 4.

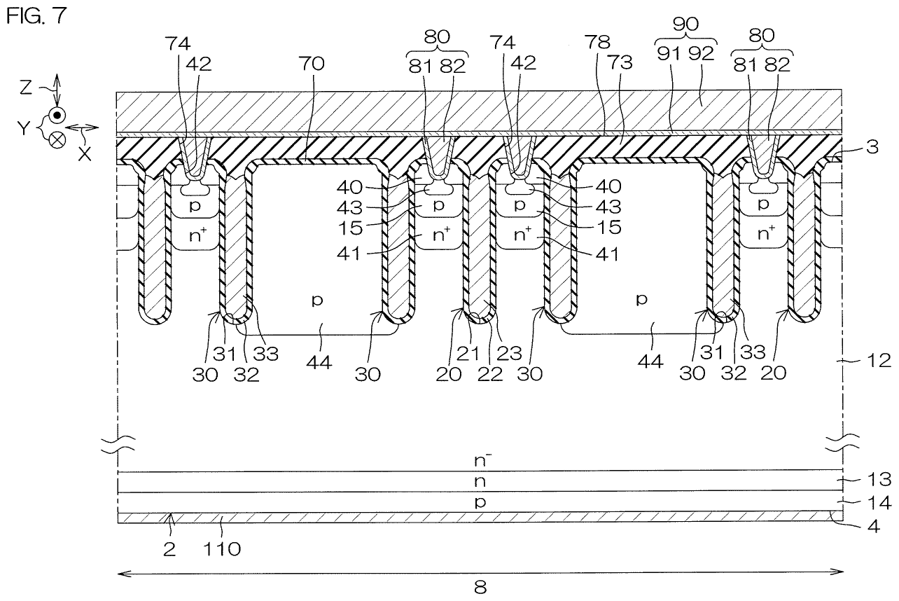

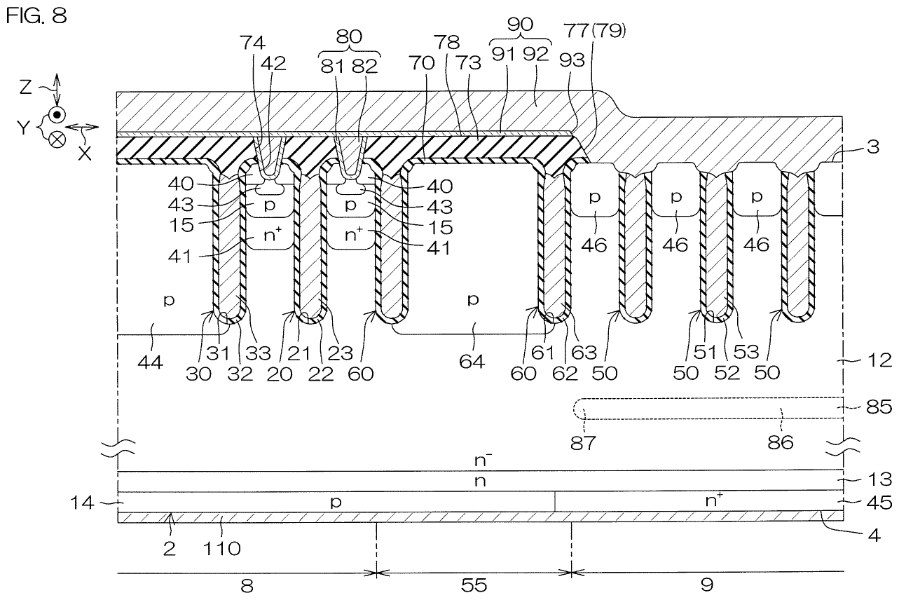

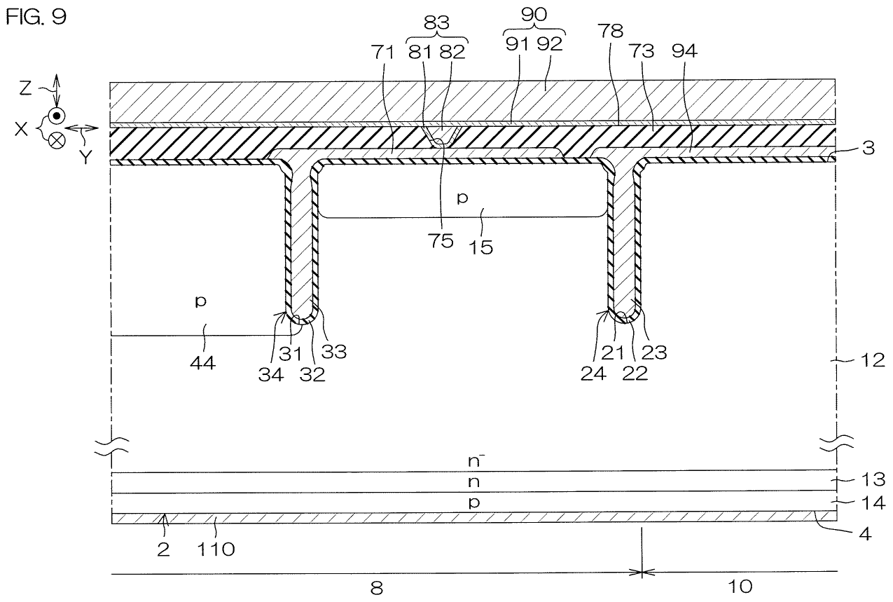

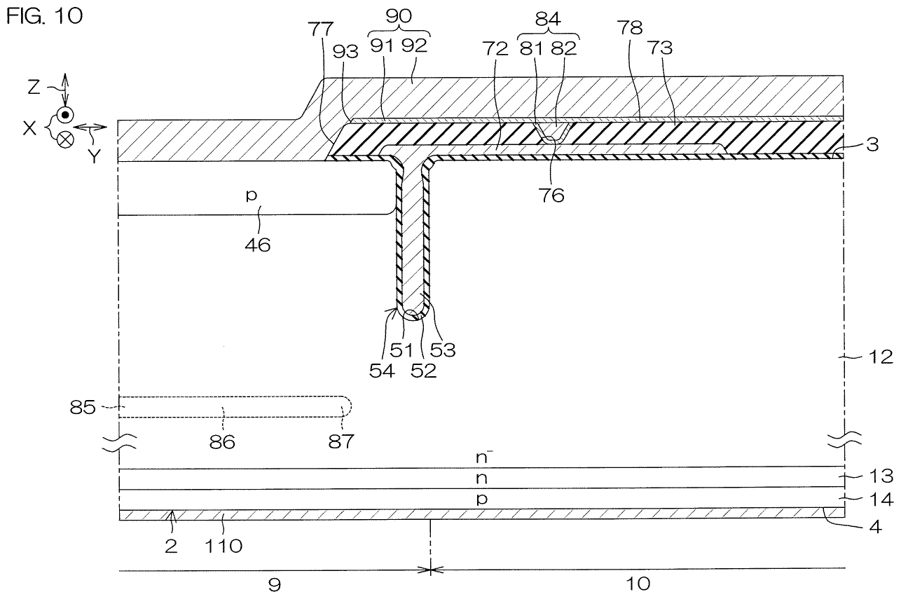

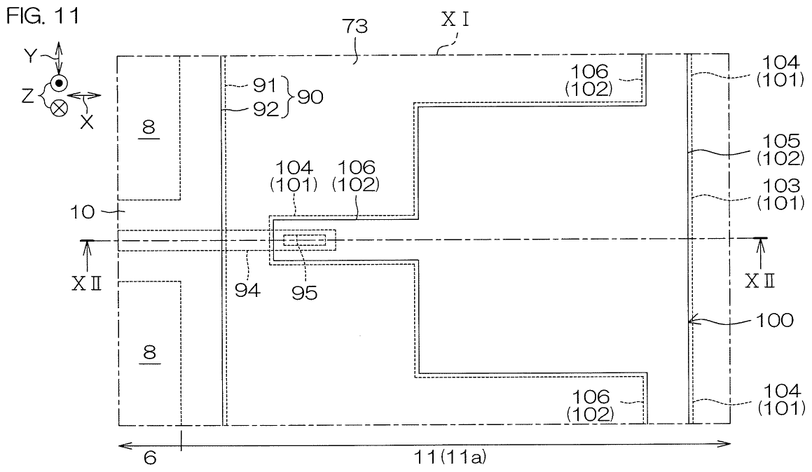

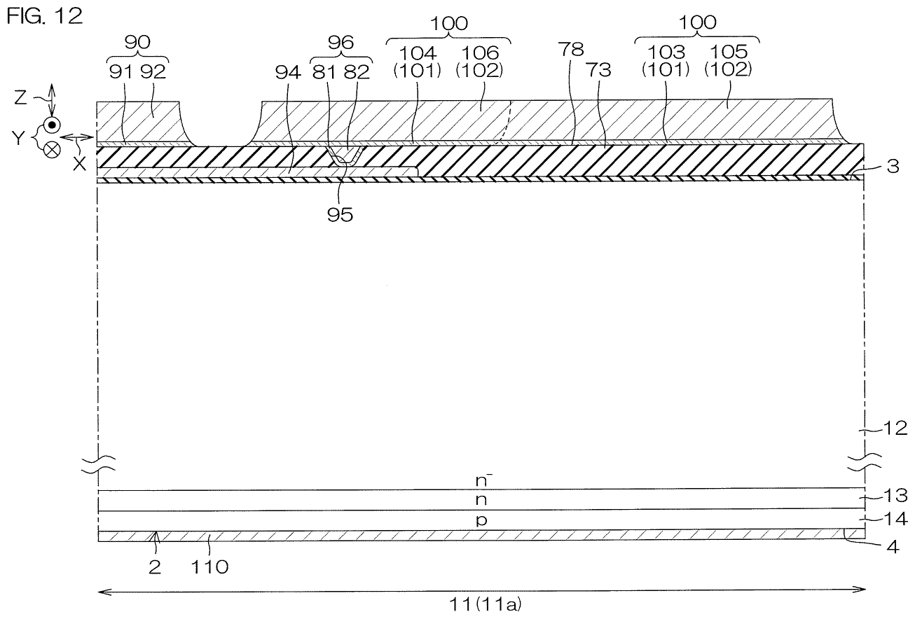

FIG. 7 is a cross sectional view along line VII-VII shown in FIG. 5. FIG. 8 is a cross sectional view along line III-VIII shown in FIG. 6. FIG. 9 is a cross sectional view along line IX-IX shown in FIG. 5. FIG. 10 is a cross sectional view along line X-X shown in FIG. 6. FIG. 11 is an enlarged plan view of region XI shown in FIG. 1. FIG. 12 is a cross sectional view along line XII-XII shown in FIG. 11.

Referring to FIG. 1 to FIG. 12, the semiconductor device 1 is an RC-IGBT semiconductor device (semiconductor switching device) having an RC-IGBT (Reverse Conducting-IGBT) that integrally includes an IGBT (Insulated Gate Bipolar Transistor) and a diode. The diode is a reflux diode with respect to the IGBT.

The semiconductor device 1 includes a chip 2 having a hexahedral shape (specifically, a rectangular parallelepiped shape). In this embodiment, the chip 2 has a single layer structure made of a silicon single crystal substrate (semiconductor substrate). The chip 2 may have a thickness of not less than 50 μm and not more than 400 μm. The chip 2 has a first main surface 3 on one side, a second main surface 4 on the other side, and first to fourth side surfaces 5A to 5D that connect the first main surface 3 and the second main surface 4 together.

The first main surface 3 and the second main surface 4 are each formed in a quadrangular shape in a plan view seen from their normal directions Z (hereinafter, simply referred to as a “plan view”). The normal direction Z is also a thickness direction of the chip 2. The first side surface 5A and the second side surface 5B extend in a first direction X along the first main surface 3, and face each other in a second direction Y that intersects the first direction X (specifically, perpendicularly intersects the first direction X). The third side surface 5C and the fourth side surface 5D extend in the second direction Y, and face each other in the first direction X.

The semiconductor device 1 includes an active region 6 formed at the first main surface 3. The active region 6 includes at least one (in this embodiment, a plurality of) RC-IGBT region 7. The plurality of RC-IGBT regions 7 are formed at an inward portion of the first main surface 3 at a distance from a peripheral edge (the first to fourth side surfaces 5A to 5D) of the first main surface 3 in a plan view.

In this embodiment, the plurality of RC-IGBT regions 7 are each formed in a band shape extending in the first direction X, and are arranged at a distance from each other in the second direction Y. In other words, the plurality of RC-IGBT regions 7 are arranged in a stripe shape extending in the first direction X in a plan view. The plurality of RC-IGBT regions 7 each have a first end portion on one side (third side surface 5C side) and a second end portion on the other side (fourth side surface 5D side).

The plurality of RC-IGBT regions 7 each include at least one (in this embodiment, a plurality of) IGBT region 8 and at least one (in this embodiment, a plurality of) diode region 9. The plurality of IGBT regions 8 are each formed in a quadrangular shape in a plan view. The plurality of diode regions 9 are each formed in a quadrangular shape in a plan view. The plurality of IGBT regions 8 are arranged at a distance from each other in the first direction X in each of the RC-IGBT regions 7. The plurality of diode regions 9 are each arranged in a region differing from the IGBT regions 8 in each of the plurality of RC-IGBT regions 7.

Specifically, the plurality of diode regions 9 are each arranged so as to adjoin at least one IGBT region 8. In this embodiment, the plurality of diode regions 9 are arranged alternately with the plurality of IGBT regions 8 along the first direction X. The first and second end portions of each of the RC-IGBT regions 7 are each formed by the IGBT region 8 or by the diode region 9.

The plurality of IGBT regions 8 according to one of the RC-IGBT regions 7 may face the plurality of IGBT regions 8 according to one other RC-IGBT region 7 in the second direction Y. Likewise, the plurality of diode regions 9 according to one of the RC-IGBT regions 7 may face the plurality of diode regions 9 according to one other RC-IGBT region 7 in the second direction Y. In other words, the plurality of IGBT regions 8 may be arranged in a matrix manner at a distance from each other in the first and second directions X and Y in a plan view. Also, the plurality of diode regions 9 may be arranged in a matrix manner at a distance from each other in the first and second directions X and Y in a plan view.

The plurality of IGBT regions 8 according to one of the RC-IGBT regions 7 may face the plurality of diode regions 9 according one other RC-IGBT region 7 in the second direction Y. Likewise, the plurality of diode regions 9 according to one of the RC-IGBT regions 7 may face the plurality of IGBT regions 8 according one other RC-IGBT region 7 in the second direction Y. In other words, the plurality of IGBT regions 8 may be arranged in a staggered manner at a distance from each other in the first and second directions X and Y in a plan view. Also, the plurality of diode regions 9 may be arranged in a staggered manner at a distance from each other in the first and second directions X and Y in a plan view.

Each of the IGBT regions 8 has a first plane area. Each of the diode regions 9 has a second plane area. The second plane area may be substantially equal to the first plane area, or may differ from the first plane area. The second plane area may exceed the first plane area, or may be less than the first plane area. Preferably, the second plane area is equal to or less than the first plane area. In other words, preferably, the total plane area of the plurality of diode regions 9 is equal to or less than the total plane area of the plurality of IGBT regions 8. Particularly preferably, the second plane area is less than the first plane area. In other words, particularly preferably, the total plane area of the plurality of diode regions 9 is less than the total plane area of the plurality of IGBT regions 8.

In this embodiment, the active region 6 includes at least one (in this embodiment, a plurality of) street region 10 defined between the plurality of RC-IGBT regions 7 in the first main surface 3. The plurality of street regions 10 are each formed in a band shape extending in the first direction X in a plan view, and are formed at a distance from each other in the second direction Y. In other words, the plurality of street regions 10 are arranged in a stripe shape extending in the second direction Y in a plan view.

The semiconductor device 1 includes an outer region 11 formed outside the active region 6 in the first main surface 3. The outer region 11 is a region that does not include the RC-IGBT region 7. The outer region 11 includes a first region 11a and a second region 11b. In this embodiment, the first region 11a is provided on the third side surface 5C side with respect to the active region 6 in a plan view, and is formed in a band shape extending in the second direction Y. The second region 11b is formed in an annular shape surrounding the active region 6 together with the first region 11a in a plan view. The second region 11b is formed so as to be narrower than the first region 11a.

The semiconductor device 1 includes an n-type drift region 12 formed inside the chip 2. The drift region 12 is formed in the whole area of the inside of the chip 2. In this embodiment, the chip 2 is made of an n-type semiconductor substrate, and the drift region 12 is formed by use of a part of the chip 2. The n-type impurity concentration of the drift region 12 may be not less than 1×10¹³ cm⁻³ and not more than 1×10¹⁵ cm⁻³.

The semiconductor device 1 includes an n-type buffer region 13 formed in a surficial portion of the second main surface 4. The buffer region 13 extends in a layer shape along the second main surface 4, and is exposed from a part of the first to fourth side surfaces 5A to 5D. The buffer region 13 has an n-type impurity concentration higher than that of the drift region 12. The n-type impurity concentration of the buffer region 13 may be not less than 1×10¹⁵ cm⁻³ and not more than 1×10¹⁷ cm⁻³.

The semiconductor device 1 includes a p-type collector region 14 formed in the surficial portion of the second main surface 4 in each of the IGBT regions 8. In this embodiment, the collector region 14 is formed in a layer shape extending along the second main surface 4 in the whole area of the second main surface 4. The collector region 14 is exposed from the second main surface 4 and from a part of the first to fourth side surfaces 5A to 5D. The p-type impurity concentration of the collector region 14 may be not less than 1×10¹⁵ cm⁻³ and not more than 1×10¹⁸ cm⁻³.

The semiconductor device 1 includes a p-type base region 15 formed in a surficial portion of the first main surface 3 in each of the IGBT regions 8. The base region 15 may be referred to as a “body region” or as a “channel region.” The base region 15 is formed in a layer shape extending along the first main surface 3 in each of the IGBT regions 8. The p-type impurity concentration of the base region 15 may be not less than 1×10¹⁵ cm⁻³ and not more than 1×10¹⁸ cm⁻³.

The semiconductor device 1 includes a plurality of first trench electrode structures 20 formed in the first main surface 3 in each of the IGBT regions 8. The first trench electrode structure 20 may be referred to as a “gate trench structure.” A gate potential is to be given to the first trench electrode structure 20.

The plurality of first trench electrode structures 20 pass through the base region 15 so as to reach the drift region 12 in a cross sectional view. The plurality of first trench electrode structures 20 are arranged at a distance from each other in the first direction X in a plan view, and are each formed in a band shape extending in the second direction Y. In other words, the plurality of first trench electrode structures 20 are arranged in a stripe shape extending in the second direction Y. The plurality of first trench electrode structures 20 each have a first end portion on one side (on the first side surface 5A side) and a second end portion on the other side (on the second side surface 5B side) with respect to a longitudinal direction (second direction Y).

The plurality of first trench electrode structures 20 may be arranged at a distance of not less than 1 μm and not more than 10 μm from each other in the first direction X. Each of the first trench electrode structures 20 may have a width of not less than 0.5 μm and not more than 3 μm. Each of the first trench electrode structures 20 may have a depth of not less than 1 μm and not more than 10 μm.

A configuration of the single first trench electrode structure 20 will be hereinafter described. The first trench electrode structure 20 includes a first trench 21, a first insulating film 22, and a first embedded electrode 23. The first trench 21 is dug down from the first main surface 3 toward the second main surface 4, and defines a wall surface of the first trench electrode structure 20.

The first trench 21 may be formed in a tapered shape in which the width of the opening becomes narrower from the opening toward the bottom wall. Preferably, the bottom wall of the first trench 21 is formed in a curved shape toward the second main surface 4. As a matter of course, the bottom wall of the first trench 21 may be formed in parallel with the first main surface 3. In this case, preferably, a corner portion of the bottom wall of the first trench 21 is formed in a curved shape.

The first trench 21 includes an inclined portion that is diagonally inclined with respect to both the first main surface 3 and the sidewall in the opening end. The inclined portion is formed at a distance toward the first main surface 3 side with respect to an intermediate portion within a depth range of the first trench 21. Specifically, the inclined portion is formed at a distance toward the first main surface 3 side with respect to a bottom portion of the base region 15. In this embodiment, the inclined portion consists of a recessed portion that is concavely hollowed toward the second main surface 4 in the opening end. Hence, the first trench 21 has a wide portion, which has an opening width exceeding an opening width on the bottom wall side, on the opening side.

The first insulating film 22 covers a wall surface of the first trench 21 in a film shape, and defines a recessed space in the first trench 21. The first insulating film 22 may include at least one among a silicon oxide film, a silicon nitride film, a silicon oxide-nitride film, and an aluminum oxide film. Preferably, the first insulating film 22 includes a silicon oxide film made of an oxide of the chip 2. In a part, which covers the inclined portion, of the first trench 21, the first insulating film 22 has a thick film portion that is thicker than the other parts.

The first embedded electrode 23 is embedded in the first trench 21 with the first insulating film 22 between the first embedded electrode 23 and the first trench 21. A gate potential is to be given to the first embedded electrode 23. The first embedded electrode 23 may include conductive polysilicon. The first embedded electrode 23 faces both the drift region 12 and the base region 15 across the first insulating film 22. The first embedded electrode 23 may have an upper end portion placed on the bottom wall side of the first trench 21 with respect to the first main surface 3.

The upper end portion of the first embedded electrode 23 is bundled toward the inward side of the first trench 2 because of the thick film portion of the first insulating film 22. The upper end portion of the first embedded electrode 23 may have a recessed portion that is hollowed toward the bottom wall of the first trench 21. The recessed portion may be formed in a tapered shape toward the bottom wall of the first trench 21.

The semiconductor device 1 includes at least one (in this embodiment, a plurality of) first trench connection structure 24 formed in the first main surface 3 so as to be electrically connected to the plurality of first trench electrode structures 20 in each of the IGBT regions 8. The plurality of first trench connection structures 24 each include the first trench 21, the first insulating film 22, and the first embedded electrode 23 in the same way as the first trench electrode structure 20.

The plurality of first trench connection structures 24 include one first trench connection structure 24 and one other first trench connection structure 24. The one first trench connection structure 24 is formed in a band shape extending in the first direction X so as to connect the first end portions of the plurality of first trench electrode structures 20. The one other first trench connection structure 24 is formed in a band shape extending in the first direction X so as to connect the second end portions of the plurality of first trench electrode structures 20.

The semiconductor device 1 includes a plurality of second trench electrode structures 30 formed in the first main surface 3 in each of the IGBT regions 8. The second trench electrode structure 30 may be referred to as an “emitter trench structure.” A potential (in this embodiment, emitter potential) differing from the gate potential is to be given to the second trench electrode structure 30.

In this embodiment, at least two second trench electrode structures 30 are respectively arranged in regions between pairs of first trench electrode structures 20 adjoining each other. Specifically, the plurality of second trench electrode structures 30 are each formed in a mesa region defined by the pair of first trench electrode structures 20 and by the pair of first trench connection structures 24.

The plurality of second trench electrode structures 30 pass through the base region 15 so as to reach the drift region 12 in a cross sectional view. The plurality of second trench electrode structures 30 are arranged at a distance from each other in the first direction X in a plan view, and are each formed in a band shape extending in the second direction Y. In other words, the plurality of second trench electrode structures 30 are arranged in a stripe shape extending in the second direction Y.

The plurality of second s trench electrode structures 30 are shorter than the plurality of first trench electrode structures 20 with respect to the longitudinal direction (second direction Y). The plurality of second trench electrode structures 30 each have a first end portion on one side (first side surface 5A side) and a second end portion on the other side (second side surface 5B side) in regard to the longitudinal direction (second direction Y).

The plurality of second trench electrode structures 30 may be arranged at a distance of not less than 1.5 μm and not more than 15 μm from each other in the first direction X. Preferably, the distance of the plurality of second trench electrode structures 30 is larger than the distance of the first and second trench electrode structures 20 and 30 adjoining each other.

Each of the second trench electrode structures 30 may have a width of not less than 0.5 μm and not more than 3 μm. Preferably, the width of each of the second trench electrode structures 30 is substantially equal to the width of each of the first trench electrode structures 20. Each of the second trench electrode structures 30 may have a depth of not less than 1 μm and not more than 10 μm. Preferably, the depth of each of the second trench electrode structures 30 is substantially equal to the depth of each of the first trench electrode structures 20.

A configuration of the single second trench electrode structure 30 will be hereinafter described. The second trench electrode structure 30 includes a second trench 31, a second insulating film 32, and a second embedded electrode 33. The second trench 31 is dug down from the first main surface 3 toward the second main surface 4, and defines a wall surface of the second trench electrode structure 30.

The second trench 31 may be formed in a tapered shape in which the width of the opening becomes narrower from the opening toward the bottom wall. Preferably, the bottom wall of the second trench 31 is formed in a curved shape toward the second main surface 4. As a matter of course, the bottom wall of the second trench 31 may be formed in parallel with the first main surface 3. In this case, preferably, a corner portion of the bottom wall of the second trench 31 is formed in a curved shape.

The second trench 31 includes an inclined portion that is diagonally inclined with respect to both the first main surface 3 and the sidewall in the opening end. The inclined portion is formed at a distance toward the first main surface 3 side with respect to an intermediate portion within a depth range of the second trench 31. Specifically, the inclined portion is formed at a distance toward the second main surface 4 side with respect to a bottom portion of the base region 15. In this embodiment, the inclined portion consists of a recessed portion that is concavely hollowed toward the second main surface 4 in the opening end. Hence, the second trench 31 has a wide portion, which has an opening width exceeding an opening width on the bottom wall side, on the opening side.

The second insulating film 32 covers a wall surface of the second trench 31 in a film shape, and defines a recessed space in the second trench 31. The second insulating film 32 may include at least one among a silicon oxide film, a silicon nitride film, a silicon oxide-nitride film, and an aluminum oxide film. Preferably, the second insulating film 32 includes a silicon oxide film made of an oxide of the chip 2. Particularly preferably, the second insulating film 32 includes the same insulation material as the first insulating film 22. In a part, which covers the inclined portion, of the second trench 31, the second insulating film 32 has a thick film portion that is thicker than the other parts.

The second embedded electrode 33 is embedded in the second trench 31 with the second insulating film 32 between the second embedded electrode 33 and the second trench 31. An emitter potential is to be given to the second embedded electrode 33. The second embedded electrode 33 may include conductive polysilicon. The second embedded electrode 33 faces both the drift region 12 and the base region 15 across the second insulating film 32. The second embedded electrode 33 may have an upper end portion placed on the bottom wall side of the second trench 31 with respect to the first main surface 3.

The upper end portion of the second embedded electrode 33 is bundled toward the inward side of the second trench 31 because of the thick film portion of the second insulating film 32. The upper end portion of the second embedded electrode 33 may have a recessed portion that is hollowed toward the bottom wall of the second trench 31. The recessed portion may be formed in a tapered shape toward the bottom wall of the second trench 31.

The semiconductor device 1 includes at least one (in this embodiment, a plurality of) second trench connection structure 34 formed at the first main surface 3 so as to be electrically connected to the plurality of second trench electrode structures 30 in each of the IGBT regions 8. The plurality of second trench connection structures 34 each include the second trench 31, the second insulating film 32, and the second embedded electrode 33 in the same way as the second trench electrode structure 30.

The plurality of second trench connection structures 34 include one second trench connection structure 34 and one other second trench connection structure 34. The one second trench connection structure 34 is formed in a band shape extending in the first direction X so as to connect the first end portions of the plurality of second trench electrode structures 30. The one other second trench connection structure 34 is formed in a band shape extending in the first direction X so as to connect the second end portions of the plurality of second trench electrode structures 30.

The semiconductor device 1 includes a plurality of n-type emitter regions 40 formed in a surficial portion of the base region 15 in each of the IGBT regions 8. The plurality of emitter regions 40 are arranged at both sides of the plurality of first trench electrode structures 20, respectively, and are each formed in a band shape extending along the plurality of first trench electrode structures 20 in a plan view. The plurality of emitter regions 40 each have an n-type impurity concentration that is higher than the drift region 12. The n-type impurity concentration of the plurality of emitter regions 40 may be not less than 1×10¹⁹ cm⁻³ and not more than 1×10²⁰ cm⁻³.

In this embodiment, the semiconductor device 1 includes a plurality of n-type CS regions (Carrier Storage regions) 41 formed in a region directly below the base region 15 in each of the IGBT regions 8. The plurality of CS regions 41 suppress the discharge of carriers (holes) into the base region 15, and promote the accumulation of carriers (holes) in a region directly below the plurality of first trench electrode structures 20. In other words, the plurality of CS regions 41 promote on-resistance reduction and on-voltage reduction from the inside of the chip 2.

The plurality of CS regions 41 are arranged at both sides of the plurality of first trench electrode structures 20, respectively, and are each formed in a band shape extending along the plurality of first trench electrode structures 20 in a plan view. The plurality of CS regions 41 are each formed in a region between the bottom portion of the base region 15 and a bottom wall of the first trench electrode structure 20 in regard to the thickness direction of the chip 2. Preferably, the plurality of CS regions 41 are at a distance from the bottom wall of the first trench electrode structure 20 toward the base region 15 side.

Preferably, a bottom portion of the plurality of CS regions 41 is located closer to the bottom wall side of the first trench electrode structure 20 than an intermediate portion of the first trench electrode structure 20. The plurality of CS regions 41 have an n-type impurity concentration that is higher than the drift region 12. Preferably, the n-type impurity concentration of the plurality of CS regions 41 is lower than the emitter region 40. The n-type impurity concentration of the plurality of CS regions 41 may be not less than 1×10¹⁵ cm⁻³ and not more than 1×10¹⁷ cm⁻³.

The semiconductor device 1 includes a plurality of contact holes 42 formed in the first main surface 3 in each of the IGBT regions 8. The plurality of contact holes 42 are formed at both sides of the plurality of first trench electrode structures 20, respectively, at a distance from the plurality of first trench electrode structures 20 in the first direction X. The plurality of contact holes 42 may be each formed in a tapered shape in which the width of the opening becomes narrower from the opening toward the bottom wall. The plurality of contact holes 42 are dug down from the first main surface 3 toward the second main surface 4 so as to expose at least the emitter region 40.

The plurality of contact holes 42 may be at a distance from a bottom portion of the emitter region 40 toward the first main surface 3 side so as not to reach the base region 15. As a matter of course, the plurality of contact holes 42 may pass through the emitter region 40 so as to reach the base region 15. The plurality of contact holes 42 are each formed in a band shape extending along the plurality of first trench electrode structures 20 in a plan view. The plurality of contact holes 42 are shorter than the plurality of first trench electrode structures 20 with respect to the longitudinal direction (second direction Y).

The semiconductor device 1 includes a plurality of p-type contact regions 43 formed in a region differing from the plurality of emitter regions 40 in the surficial portion of the base region 15 in each of the IGBT regions 8. Specifically, the plurality of contact regions 43 are each formed in a region along a corresponding one of the contact holes 42. The plurality of contact regions 43 are each formed in a band shape extending along the corresponding contact hole 42 in a plan view.

A bottom portion of the plurality of contact regions 43 is formed in a region between the bottom wall of the contact hole 42 and the bottom portion of the base region 15. The plurality of contact regions 43 have a p-type impurity concentration higher than the base region 15. The p-type impurity concentration of the plurality of contact regions 43 may be not less than 1×10¹⁹ cm⁻³ and not more than 1×10²⁰ cm⁻³.

The semiconductor device 1 includes a plurality of p-type well regions 44 formed in the surficial portion of the first main surface 3 in each of the IGBT regions 8. The plurality of well regions 44 are formed in regions between adjoining pairs of second trench electrode structures 30. Specifically, the plurality of well regions 44 are each formed in a mesa region that is defined by the plurality of second trench electrode structures 30 and by the plurality of second trench connection structures 34.

The plurality of well regions 44 are formed more deeply than the base region 15 in regard to the thickness direction of the chip 2. Specifically, the plurality of well regions 44 are formed more deeply than an intermediate portion of the plurality of second trench electrode structures 30 in regard to the thickness direction of the chip 2. More specifically, the plurality of well regions 44 are formed more deeply than the plurality of second trench electrode structures 30 in regard to the thickness direction of the chip 2. The plurality of well regions 44 may have a part (bottom portion) that covers a bottom wall of the plurality of second trench electrode structures 30.

The plurality of well regions 44 are formed in a band shape extending along the second trench electrode structure 30 in a plan view. The plurality of well regions 44 may have a p-type impurity concentration higher than the p-type impurity concentration of the base region 15. The p-type impurity concentration of the plurality of well regions 44 may be not less than 1×10¹⁶ cm⁻³ and not more than 1×10²⁰ cm⁻³. In this embodiment, the well region 44 is formed in an electrically floating state.

The plurality of well regions 44 compose an IE structure (Injection Enhanced structure) in the IGBT region 8. Specifically, the well regions 44 form the IE structure together with the plurality of plurality of second trench electrode structures 30, and separate the plurality of first trench electrode structures 20. The IE structure limits a movement path of holes that flow into the base region 15, and accumulates holes in a region directly below the base region 15. In other words, the IE structure promotes on-resistance reduction and on-voltage reduction from the inside of the chip 2.

The semiconductor device 1 includes an n-type cathode region 45 formed in the surficial portion of the second main surface 4 in each of the diode regions 9. The cathode region 45 may be referred to as a “first polar region.” In this embodiment, the cathode region 45 is formed in a layer shape extending along the second main surface 4 in a part (which is located in the diode region 9) of the second main surface 4. The cathode region 45 passes through the collector region 14 so as to be connected to the buffer region 13.

The cathode region 45 is a region that has an n-type impurity concentration exceeding the p-type impurity concentration of the collector region 14 and in which the conductivity type of a part of the collector region 14 is replaced from the p-type to the n-type. Preferably, the cathode region 45 has the n-type impurity concentration higher than that of the drift region 12 (buffer region 13). The n-type impurity concentration of the cathode region 45 may be not less than 1×10¹⁹ cm⁻³ and not more than 1×10²⁰ cm⁻³.

The semiconductor device 1 includes a p-type anode region 46 formed in the surficial portion of the first main surface 3 in each of the diode regions 9. The anode region 46 may be referred to as a “second polar region.” The anode region 46 is formed in a layer shape extending along the first main surface 3 in each of the diode regions 9, and faces the cathode region 45 in the thickness direction of the chip 2. In this embodiment, the whole area of the anode region 46 faces at least one part of the cathode region 45.

As a matter of course, the anode region 46 may face a part of the collector region 14 and a part of the cathode region 45 in the thickness direction of the chip 2. The anode region 46 is formed more shallowly than the plurality of first trenches 21 in regard to the thickness direction of the chip 2. Specifically, the anode region 46 is formed more shallowly than the intermediate portion of the plurality of first trenches 21 in regard to the thickness direction of the chip 2. The anode region 46 may have a depth substantially equal to that of the base region 15.

As a matter of course, the anode region 46 may be formed more deeply than the base region 15 in regard to the thickness direction of the chip 2. In this case, the anode region 46 may be formed more deeply than the intermediate portion of the plurality of first trench electrode structures 20 (second trench electrode structure 30) in regard to the thickness direction of the chip 2.

The anode region 46 makes a pn-junction with the drift region 12. Hence, a pn-junction diode is formed in which the anode region 46 is set as an anode and in which the cathode region 45 (drift region 12) is set as a cathode. The anode region 46 may have a p-type impurity concentration substantially equal to that of the base region 15. As a matter of course, the p-type impurity concentration of the anode region 46 may be higher than the p-type impurity concentration of the base region 15 or may be lower than the p-type impurity concentration of the base region 15. The p-type impurity concentration of the anode region 46 may be not less than 1×10¹⁵ cm⁻³ and not more than 1×10¹⁸ cm⁻³.

The semiconductor device 1 includes a plurality of third trench electrode structures 50 formed in the first main surface 3 in each of the diode regions 9. The third trench electrode structure 50 may be referred to as an “anode trench structure.” A potential (in this embodiment, anode potential) differing from the gate potential is to be given to the third trench electrode structure 50. In this embodiment, the anode potential is an emitter potential.

The plurality of third trench electrode structures 50 pass through the anode region 46 so as to reach the drift region 12 in a cross sectional view. The plurality of third trench electrode structures 50 are arranged at a distance from each other in the first direction X in a plan view, and are each formed in a band shape extending in the second direction Y. In other words, the plurality of third trench electrode structures 50 are arranged in a stripe shape extending in the second direction Y.

The plurality of third trench electrode structures 50 are shorter than the plurality of first trench electrode structures 20 with respect to the longitudinal direction (second direction Y). The plurality of third trench electrode structures 50 have a length substantially equal to that of the plurality of second trench electrode structures 30 with respect to the longitudinal direction (second direction Y). The plurality of third trench electrode structures 50 each have a first end portion on one side (first side surface 5A side) and a second end portion on the other side (second side surface 5B side) with respect to the longitudinal direction (second direction Y).

The plurality of third trench electrode structures 50 may be arranged at a distance of not less than 1 μm and not more than 10 μm from each other in the first direction X. The distance of the plurality of third trench electrode structures 50 is smaller than the distance of the plurality of first trench electrode structures 20. The distance of the plurality of third trench electrode structures 50 is smaller than the distance of the plurality of second trench electrode structures 30. Preferably, the distance of the plurality of third trench electrode structures 50 is substantially equal to the distance of both the first trench electrode structure 20 and the second trench electrode structure 30 that adjoin each other.

Each of the third trench electrode structures 50 may have a width of not less than 0.5 μm and not more than 3 μm. Preferably, the width of each of the third trench electrode structures 50 is substantially equal to the width of each of the first trench electrode structures 20. Each of the third trench electrode structures 50 may have a depth of not less than 1 μm and not more than 10 μm. Preferably, the depth of each of the third trench electrode structures 50 is substantially equal to the depth of each of the first trench electrode structures 20.

A configuration of the single third trench electrode structure 50 will be hereinafter described. The third trench electrode structure 50 includes a third trench 51, a third insulating film 52, and a third embedded electrode 53. The third trench 51 is dug down from the first main surface 3 toward the second main surface 4, and defines a wall surface of the third trench electrode structure 50.

The third trench 51 may be formed in a tapered shape in which the width of the opening becomes narrower from the opening toward the bottom wall. Preferably, the bottom wall of the third trench 51 is formed in a curved shape toward the second main surface 4. As a matter of course, the bottom wall of the third trench 51 may be formed in parallel with the first main surface 3. In this case, preferably, a corner portion of the bottom wall of the third trench 51 is formed in a curved shape.

The third trench 51 includes an inclined portion that is diagonally inclined with respect to both the first main surface 3 and the sidewall in the opening end. The inclined portion is formed at a distance toward the first main surface 3 side with respect to an intermediate portion within a depth range of the third trench 51. Specifically, the inclined portion is formed at a distance toward the first main surface 3 side with respect to a bottom portion of the anode region 46. In this embodiment, the inclined portion consists of a recessed portion that is concavely hollowed toward the second main surface 4 in the opening end. Hence, the third trench 51 has a wide portion, which has an opening width exceeding an opening width on the bottom wall side, on the opening side.

The third insulating film 52 covers a wall surface of the third trench 51 in a film shape, and defines a recessed space in the third trench 51. The third insulating film 52 may include at least one among a silicon oxide film, a silicon nitride film, a silicon oxide-nitride film, and an aluminum oxide film. Preferably, the third insulating film 52 includes a silicon oxide film made of an oxide of the chip 2. Particularly preferably, the third insulating film 52 includes the same insulation material as the first insulating film 22. In this embodiment, the third insulating film 52 exposes the inclined portion of the third trench 51.

The third embedded electrode 53 is embedded in the third trench 51 with the third insulating film 52 between the third embedded electrode 53 and the third trench 51. An anode potential (in this embodiment, an emitter potential) is given to the third embedded electrode 53. The third embedded electrode 53 may include conductive polysilicon. The third embedded electrode 53 faces both the anode region 46 and the drift region 12 across the third insulating film 52.

The third embedded electrode 53 may have an upper end portion placed on the bottom wall side of the third trench 51 with respect to the first main surface 3. The upper end portion of the third embedded electrode 53 is bundled toward the inward side of the second trench 31 because of the thick film portion of the third insulating film 52. The upper end portion of the third embedded electrode 53 may have a recessed portion that is hollowed toward the bottom wall of the third trench 51. The recessed portion may be formed in a tapered shape toward the bottom wall of the third trench 51.

The semiconductor device 1 includes at least one (in this embodiment, a plurality of) third trench connection structure 54 formed in the first main surface 3 so as to be electrically connected to the plurality of third trench electrode structures 50 in each of the diode regions 9. The plurality of third trench connection structures 54 each include the third trench 51, the third insulating film 52, and the third embedded electrode 53 in the same way as the third trench electrode structure 50.

The plurality of third trench connection structures 54 include one third trench connection structure 54 and one other third trench connection structure 54. The one third trench connection structure 54 is formed in a band shape extending in the first direction X so as to connect the first end portions of the plurality of third trench electrode structures 50. The one other third trench connection structure 54 is formed in a band shape extending in the first direction X so as to connect the second end portions of the plurality of third trench electrode structures 50.

The semiconductor device 1 includes a plurality of fourth trench electrode structures 60 formed in the first main surface 3 in a boundary region 55 between each of the IGBT regions 8 and each of the diode regions 9. In this embodiment, at least two fourth trench electrode structures 60 are arranged in a region between the outermost first trench electrode structure 20 and the outermost third trench electrode structure 50.

The plurality of fourth trench electrode structures 60 pass through the anode region 46 (base region 15) so as to reach the drift region 12 in a cross sectional view. The plurality of fourth trench electrode structures 60 are arranged at a distance from each other in the first direction X in a plan view, and are each formed in a band shape extending in the second direction Y. In other words, the plurality of fourth trench electrode structures 60 are arranged in a stripe shape extending in the second direction Y. The plurality of fourth trench electrode structures 60 are shorter than the plurality of first trench electrode structures 20 with respect to the longitudinal direction (second direction Y).

The plurality of fourth trench electrode structures 60 each have a first end portion on one side (first side surface 5A side) and a second end portion on the other side (second side surface 5B side) with respect to the longitudinal direction (second direction Y). The first end portion of the plurality of fourth trench electrode structures 60 is connected to the one third trench connection structure 54. The second end portion of the plurality of fourth trench electrode structures 60 is connected to the one other third trench connection structure 54.

The plurality of fourth trench electrode structures 60 may be arranged at a distance of not less than 1.5 μm and not more than 15 μm from each other in the first direction X. Preferably, the distance of the plurality of fourth trench electrode structures 60 is larger than the distance of the plurality of third trench electrode structures 50. Preferably, the distance of the plurality of fourth trench electrode structures 60 is smaller than the distance of the plurality of first trench electrode structures 20. Preferably, the distance of the plurality of fourth trench electrode structures 60 is substantially equal to the distance of the plurality of second trench electrode structures 30.

Each of the fourth trench electrode structures 60 may have a width of not less than 0.5 μm and not more than 3 μm. Preferably, the width of each of the fourth trench electrode structures 60 is substantially equal to the width of each of the third trench electrode structures 50. Each of the fourth trench electrode structures 60 may have a depth of not less than 1 μm and not more than 10 μm. Preferably, the depth of each of the fourth trench electrode structures 60 is substantially equal to the depth of each of the third trench electrode structures 50.

The plurality of fourth trench electrode structures 60 include a fourth trench 61, a fourth insulating film 62, and a fourth embedded electrode 63. The fourth trench 61, the fourth insulating film 62, and the fourth embedded electrode 63 are substantially the same in form as the second trench 31, the second insulating film 32, and the second embedded electrode 33, respectively. The fourth trench 61, the fourth insulating film 62, and the fourth embedded electrode 63 shall be described by referring to the second trench 31, the second insulating film 32, and second embedded electrode 33, respectively, and the description of the fourth trench 61, the fourth insulating film 62, and the fourth embedded electrode 63 shall be omitted.

The semiconductor device 1 includes a p-type boundary well region 64 formed in the surficial portion of the first main surface 3 in the boundary region 55. The boundary well region 64 is formed in a region between the plurality of fourth trench electrode structures 60. Specifically, the boundary well region 64 is formed in a mesa region that is defined by the pair of fourth trench electrode structures 60 and by the pair of third trench connection structures 54.

The boundary well region 64 is formed more deeply than the base region 15 and than the anode region 46 in regard to the thickness direction of the chip 2. Specifically, the boundary well region 64 is formed more deeply than an intermediate portion of the plurality of fourth trench electrode structures 60 in regard to the thickness direction of the chip 2. More specifically, the boundary well region 64 is formed more deeply than the plurality of fourth trench electrode structures 60 in regard to the thickness direction of the chip 2. The boundary well region 64 may have a part (bottom portion) that covers a bottom wall of the plurality of fourth trench electrode structures 60.

The boundary well region 64 is formed in a band shape extending along the fourth trench electrode structure 60 in a plan view. The boundary well region 64 may have a p-type impurity concentration higher than the p-type impurity concentration of the anode region 46. The p-type impurity concentration of the boundary well region 64 may be not less than 1×10¹⁶ cm⁻³ and not more than 1×10²⁰ cm⁻³. The p-type impurity concentration of the boundary well region 64 may be substantially equal to the p-type impurity concentration of the well region 44.

The boundary well region 64 faces the collector region 14 in the thickness direction of the chip 2. In this embodiment, the whole area of the boundary well region 64 faces the collector region 14 in the thickness direction of the chip 2. As a matter of course, the boundary well region 64 may face a part of the collector region 14 and a part of the cathode region 45 in the thickness direction of the chip 2. In this embodiment, the boundary well region 64 is formed in an electrically floating state.

The boundary well region 64 composes a boundary IE structure in the boundary region 55. Specifically, the boundary well region 64 forms the boundary IE structure together with the plurality of fourth trench electrode structures 60, and separates the outermost first trench electrode structure 20 from the outermost third trench electrode structure 50. The boundary IE structure limits a movement path of holes that flow into the base region 15 in the boundary region 55, and promotes the accumulation of holes in a region directly below the base region 15.

The semiconductor device 1 includes a main surface insulating film 70 that selectively covers the first main surface 3. The main surface insulating film 70 may include at least one among a silicon oxide film, a silicon nitride film, a silicon oxide-nitride film, and an aluminum oxide film. Preferably, the main surface insulating film 70 includes a silicon oxide film made of an oxide of the chip 2. Particularly preferably, the main surface insulating film 70 has a single layer structure made of a single insulating film.

The main surface insulating film 70 extends along the first main surface 3 in a film shape, and may be continuous with the peripheral edge (first to fourth side surfaces 5A to 5D) of the chip 2. The main surface insulating film 70 covers the first main surface 3 so as to expose the plurality of first trench electrode structures 20, the plurality of first trench connection structures 24, the plurality of second trench electrode structures 30, and the plurality of second trench connection structures 34 in each of the IGBT regions 8. Specifically, the main surface insulating film 70 covers the plurality of emitter regions 40 and the plurality of well regions 44 in each of the IGBT regions 8, and is continuous with the first insulating film 22 and with the second insulating film 32.

The main surface insulating film 70 covers the first main surface 3 so as to expose the anode region 46, the plurality of third trench electrode structures 50, and the plurality of third trench connection structures 54 in each of the diode regions 9. Specifically, the main surface insulating film 70 covers a peripheral edge portion of the anode region 46 in each of the diode regions 9, and is continuous with the third insulating film 52. The main surface insulating film 70 covers the first main surface 3 so as to expose the plurality of fourth trench electrode structures 60 in each of the boundary regions 55. Specifically, the main surface insulating film 70 covers the boundary well region 64 in each of the boundary regions 55, and is continuous with the third insulating film 52 and with the fourth insulating film 62.

The semiconductor device 1 includes a plurality of first wiring films 71 arranged on the main surface insulating film 70 so as to be electrically connected to the second embedded electrode 33. The first wiring film 71 may be referred to as a “first emitter wiring film.” The plurality of first wiring films 71 are each formed of a pull-out portion that is pulled out in a band shape from the second embedded electrode 33 of a corresponding one of the second trench connection structures 34 toward the adjoining first trench connection structure 24. In other words, the plurality of first wiring films 71 are each made of conductive polysilicon.

The semiconductor device 1 includes a plurality of second wiring films 72 arranged on the main surface insulating film 70 so as to be electrically connected to the third embedded electrode 53. The second wiring film 72 may be referred to as a “second emitter wiring film.” The plurality of second wiring films 72 are each formed of a pull-out portion that is pulled out in a band shape from the third embedded electrode 53 of a corresponding one of the third trench connection structures 54 toward the adjoining street region 10. In other words, the plurality of second wiring films 72 are each made of conductive polysilicon.

The semiconductor device 1 includes an interlayer insulating film 73 covering the main surface insulating film 70. The interlayer insulating film 73 may include at least one among a silicon oxide film, a silicon nitride film, a silicon oxide-nitride film, and an aluminum oxide film. The interlayer insulating film 73 may include at least one among an NSG (Non-doped Silicate Glass) film, a PSG (Phosphor Silicate Glass) film, and a BPSG (Boron Phosphor Silicate Glass) film as an example of the silicon oxide film. The interlayer insulating film 73 may have a single layer structure made of a single insulating film or a layered structure including a plurality of insulating films. The interlayer insulating film 73 has a thickness exceeding the thickness of the main surface insulating film 70. The thickness of the interlayer insulating film 73 may be not less than 0.5 μm and not more than 5 μm. Preferably, the thickness of the interlayer insulating film 73 is 1 μm or more.

The interlayer insulating film 73 extends in a layer shape along the first main surface 3, and may be continuous with the peripheral edge (first to fourth side surfaces 5A to 5D) of the chip 2. The interlayer insulating film 73 selectively covers the plurality of IGBT regions 8, the plurality of diode regions 9, and the plurality of boundary regions 55. The interlayer insulating film 73 covers the main surface insulating film 70, the plurality of first trench electrode structures 20, the plurality of first trench connection structures 24, the plurality of second trench electrode structures 30, the plurality of second trench connection structures 34, and the plurality of first wiring films 71 in each of the IGBT regions 8.

The interlayer insulating film 73 covers the main surface insulating film 70, the plurality of third trench electrode structures 50, the plurality of third trench connection structures 54, and the plurality of second wiring films 72 in each of the diode regions 9. The interlayer insulating film 73 covers the main surface insulating film 70, the plurality of third trench connection structures 54, and the plurality of fourth trench electrode structures 60 in each of the boundary regions 55.

The interlayer insulating film 73 has a plurality of first openings 74 that expose the plurality of emitter regions 40, respectively, in each of the IGBT regions 8. In this embodiment, the plurality of first openings 74 are formed in a one-to-one correspondence relationship with the plurality of contact holes 42, and each of the first openings 74 communicates with a corresponding one of the contact holes 42. The plurality of first openings 74 are each formed in a band shape extending along a corresponding one of the contact holes 42 in a plan view. The plurality of first openings 74 may be each formed in a tapered shape in which the width of the opening becomes narrower toward the corresponding contact hole 42.

The interlayer insulating film 73 has a plurality of second openings 75 that expose the plurality of first wiring films 71, respectively, in each of the IGBT regions 8. The planar shape of each of the second openings 75 and the number of the second openings 75 with respect to each of the first wiring films 71 are arbitrary. In this embodiment, each of the second openings 75 is formed in a quadrangular shape in a plan view. Each of the second openings 75 may be formed in a polygonal shape other than a quadrangular shape, a circular shape or an elliptical shape in a plan view.

The interlayer insulating film 73 has a plurality of third openings 76 that expose the plurality of second wiring films 72, respectively, in each of the diode regions 9. The planar shape of each of the third openings 76 and the number of the third openings 76 with respect to each of the second wiring films 72 are arbitrary. In this embodiment, each of the third openings 76 is formed in a quadrangular shape in a plan view. Each of the third openings 76 may be formed in a polygonal shape other than a quadrangular shape, a circular shape or an elliptical shape in a plan view.

The interlayer insulating film 73 includes a diode opening 77 that passes through the main surface insulating film 70 in each of the diode regions 9 and that exposes the anode region 46 and the plurality of third trench electrode structures 50. In this embodiment, the single diode opening 77 is formed with respect to the single diode region 9. In other words, in this embodiment, a plurality of diode openings 77 are not formed in the single diode region 9. In this embodiment, the diode opening 77 exposes an inward portion of the anode region 46 and an inward portion of the plurality of third trench electrode structures 50. The diode opening 77 exposes all of the third trench electrode structures 50 in each of the diode regions 9.

The interlayer insulating film 73 has an insulation main surface 78 extending along the first main surface 3 and an opening wall surface 79 that defines the diode opening 77. The opening wall surface 79 has an inclined surface that makes an acute angle with the first main surface 3. The inclined surface may be formed in a linear shape, in a concave curved shape toward the first main surface 3, or in a convex curved shape receding from the first main surface 3 in a cross sectional view. The inclination angle of the opening wall surface 79 may be not less than 30° and less than 90°. Preferably, the inclination angle exceeds 45°. Particularly preferably, the inclination angle is 60° or more.

The inclination angle is an angle between the first main surface 3 and the inclined surface within the interlayer insulating film 73. Specifically, the inclination angle is an angle that is made between a straight line, which connects a starting point and an ending point of the inclined surface together, and the first main surface 3. As a matter of course, the wall surface that defines each of the diode openings 77 may be formed so as to be perpendicular to the first main surface 3 (i.e., inclination angle=90°).

The semiconductor device 1 includes a plurality of first plug electrodes 80 embedded in the plurality of first openings 74 so as to be partially exposed from the interlayer insulating film 73. Each of the first plug electrodes 80 enters the inside of the contact hole 42 from the first opening 74, and is electrically connected to the emitter region 40 and to the contact region 43. In other words, the first plug electrode 80 includes a part in contact with the interlayer insulating film 73 (main surface insulating film 70) and a part in contact with the chip 2.

In this embodiment, the first plug electrode 80 has a layered structure including a first electrode portion 81 and a second electrode portion 82. The first electrode portion 81 is formed in a film shape along the wall surface of the contact hole 42 and along the wall surface of the first opening 74, and defines a recessed space. The first electrode portion 81 may include a titanium-based metal film. The first electrode portion 81 may have a single layer structure consisting of a titanium film or a titanium nitride film. The first electrode portion 81 may have a layered structure including a titanium film and a titanium nitride film that are stacked together in arbitrary order.

The second electrode portion 82 is embedded in the contact hole 42 and in the first opening 74 with the first electrode portion 81 between the second electrode portion 82 and the contact hole 42 and between the second electrode portion 82 and the first opening 74. The second electrode portion 82 may include at least one among tungsten, molybdenum, nickel, pure aluminum (whose purity is 99% or more), pure copper (whose purity is 99% or more), an aluminum alloy, and a copper alloy.

The second electrode portion 82 may include at least one among an AlCu alloy, an AlSi alloy, and an AlSiCu alloy as an example of the aluminum alloy (copper alloy). Preferably, the second electrode portion 82 includes a conductive material differing from that of the first electrode portion 81. Preferably, the second electrode portion 82 includes tungsten. In this embodiment, the second electrode portion 82 is made of tungsten.

The semiconductor device 1 includes a plurality of second plug electrodes 83 embedded in the plurality of second openings 75 so as to be partially exposed from the interlayer insulating film 73. Each of the second plug electrodes 83 is electrically connected to the first wiring film 71 in a corresponding one of the second openings 75. Each of the second plug electrodes 83 has a layered structure including the first electrode portion 81 and the second electrode portion 82 in the same way as the first plug electrode 80.

The semiconductor device 1 includes a plurality of third plug electrodes 84 embedded in the plurality of third openings 76 so as to be partially exposed from the interlayer insulating film 73. Each of the third plug electrodes 84 is electrically connected to the second wiring film 72 in a corresponding one of the third openings 76. Each of the third plug electrodes 84 has a layered structure including the first electrode portion 81 and the second electrode portion 82 in the same way as the first plug electrode 80.

The semiconductor device 1 includes a plurality of life time killer regions 85 formed inside the chip 2 in the plurality of diode regions 9, respectively. In this embodiment, the plurality of life time killer regions 85 are formed one by one with respect to the plurality of diode regions 9. In other words, in this embodiment, only one life time killer region 85 is formed with respect to the single diode region 9, and the plurality of life time killer regions 85 are not formed with respect to the single diode region 9. A configuration of the single life time killer region 85 will be hereinafter described.

The life time killer region 85 is a region that includes crystal defects introduced into the chip 2. The life time killer region 85 may be referred to as a “crystal defect region.” The lifetime of a carrier (electron or hole) of the life time killer region 85 is shorter than the lifetime of a carrier located outside the life time killer region 85. The life time killer region 85 is a recombination center of a carrier.

The crystal defect may include a void, a dangling bond, a dislocation, a rare gas element, a metal element, or a complex defect caused by these elements and by constituent elements of the chip 2. Preferably, the life time killer region 85 has a crystal defect formed by substances (elements) other than both a trivalent element (p-type impurity) and a quinquevalent element (n-type impurity). As an example, the life time killer region 85 may have a crystal defect formed by irradiating either one or both of a hydrogen ion and a helium ion to the inside of the chip 2. In this embodiment, the life time killer region 85 has a crystal defect that includes helium ions.

The life time killer region 85 reduces the loss of the diode region 9, which is caused when performing a reverse recovery operation, by regulating the carrier lifetime. In this embodiment, the life time killer region 85 is not formed in the IGBT region 8 inside the chip 2. In other words, the life time killer region 85 does not face the first trench electrode structure 20, the first trench connection structure 24, the second trench electrode structure 30, and the second trench connection structure 34 in regard to the thickness direction of the chip 2. This structure makes it possible to avoid irradiating a helium ion onto the IGBT region 8. Therefore, damage to the first trench electrode structure 20, which is caused by the helium ion, is restrained. Hence, a variation in gate threshold voltage or the like is restrained.

Preferably, the life time killer region 85 is formed in a region located on the first main surface 3 side with respect to an intermediate portion within the thickness range of the chip 2. With this structure, the depth position of the life time killer region 85 on the basis of the first main surface 3 becomes shallower than the depth position of the life time killer region 85 on the basis of the second main surface 4. Therefore, when helium ions or the like are irradiated from the first main surface 3 side, the irradiation position of the helium ions or the like with respect to the chip 2 becomes shallow.

Hence, the life time killer region 85 is accurately formed. Also, the acceleration energy of helium ions or the like is made smaller than in a case in which helium ions or the like are irradiated from the second main surface 4 side. Hence, the thickness of a resist mask is reduced, and therefore costs brought by the resist mask are reduced.

The life time killer region 85 is arranged in a region between the cathode region 45 and the anode region 46 in regard to the thickness direction of the chip 2, and is formed in a layer shape extending along the first main surface 3. In this embodiment, the whole area of the life time killer region 85 faces at least one part of the cathode region 45 in the thickness direction of the chip 2. As a matter of course, the life time killer region 85 may face a part of the collector region 14 and a part of the cathode region 45 in the thickness direction of the chip 2.

The life time killer region 85 is formed within a thickness range between the cathode region 45 and the plurality of third trench electrode structures 50 in regard to the thickness direction of the chip 2. The depth position of the life time killer region 85 with respect to the bottom wall of the third trench electrode structure 50 is smaller than the depth position of the life time killer region 85 with respect to the cathode region 45.

The life time killer region 85 faces the plurality of third trench electrode structures 50 in the thickness direction of the chip 2. In this embodiment, the life time killer region 85 faces all of the third trench electrode structures 50 arranged in the single diode region 9. In this embodiment, the life time killer region 85 does not face the third trench connection structure 54 in the thickness direction of the chip 2. As a matter of course, the life time killer region 85 may face the third trench connection structure 54 in the thickness direction of the chip 2.

In this embodiment, the life time killer region 85 is separated from the boundary well region 64 toward the diode region 9 side so as not to face the boundary well region 64 in the thickness direction of the chip 2. The life time killer region 85 may be separated from the fourth trench electrode structure 60 toward the diode region 9 side so as not to face the fourth trench electrode structure 60 in the thickness direction of the chip 2.

As a matter of course, the life time killer region 85 may have a part that faces the fourth trench electrode structure 60 in the thickness direction of the chip 2. Also, the life time killer region 85 may have a part that faces the boundary well region 64 in the thickness direction of the chip 2. In other words, the life time killer region 85 may have a part pulled out from the diode region 9 toward the boundary region 55. In this case, it is possible to regulate the lifetime of a hole that flows from the IGBT region 8 into the diode region 9.

The life time killer region 85 has a part that faces the interlayer insulating film 73 in regard to the thickness direction of the chip 2. In this embodiment, the life time killer region 85 has a peripheral edge portion placed outside the diode opening 77 in a plan view. In this embodiment, the peripheral edge portion of the life time killer region 85 extends along the diode opening 77 (opening wall surface 79) in a plan view.

Specifically, the peripheral edge portion of the life time killer region 85 extends in parallel with the diode opening 77 (opening wall surface 79) in a plan view. In this embodiment, the peripheral edge portion of the life time killer region 85 surrounds the diode opening 77 (opening wall surface 79) in a plan view. In other words, the life time killer region 85 is formed in a self-aligned manner with respect to the opening wall surface 79.

The peripheral edge portion of the life time killer region 85 faces the interlayer insulating film 73 (opening wall surface 79) in the thickness direction of the chip 2. In this embodiment, the life time killer region 85 faces two places of the interlayer insulating film 73 (opening wall surface 79) in regard to the thickness direction of the chip 2, and does not face parts of three or more places of the interlayer insulating film 73 in one cross section that crosses the single diode opening 77 in the first direction X. In this embodiment, the life time killer region 85 faces two places of the interlayer insulating film 73 (opening wall surface 79) in regard to the thickness direction of the chip 2, and does not face parts of three or more places of the interlayer insulating film 73 in one cross section that crosses the single diode opening 77 in the second direction Y.

The life time killer region 85 has a facing region 86 that faces the interlayer insulating film 73 and a non-facing region 87 that does not face the interlayer insulating film 73 in regard to the thickness direction of the chip 2. The life time killer region 85 has the facing region 86 in a peripheral edge portion, and has the non-facing region 87 in an inward portion. In this embodiment, the life time killer region 85 does not have the facing region 86 in the inward portion.

Preferably, the ratio of the non-facing region 87 in the life time killer region 85 exceeds the ratio of the facing region 86 in the life time killer region 85. As a matter of course, the ratio of the non-facing region 87 may be less than the ratio of the facing region 86. The ratio of the facing region 86 may be 25% or less, and the ratio of the non-facing region 87 may be 75% or more. Preferably, the ratio of the facing region 86 is 10% or less, and, preferably, the ratio of the non-facing region 87 is 90% or more. Particularly preferably, the ratio of the facing region 86 is 5% or less, and, particularly preferably, the ratio of the non-facing region 87 is 95% or more.

Preferably, the thickness of the life time killer region 85 is less than the thickness of the well region 44 (boundary well region 64). The thickness of the life time killer region 85 may be less than the thickness of the base region 15 (thickness of the anode region 46), or may exceed the thickness of the base region 15 (thickness of the anode region 46). The thickness of the life time killer region 85 may be less than the thickness of the interlayer insulating film 73. The thickness of the life time killer region 85 may exceed the thickness of the main surface insulating film 70, or may be less than the thickness of the main surface insulating film 70. The thickness of the life time killer region 85 may be not less than 0.1 μm and not more than 5 μm.

In this embodiment, an example has been shown in which the life time killer region 85 has a part that faces the interlayer insulating film 73 (opening wall surface 79). However, the life time killer region 85 that does not face the interlayer insulating film 73 (opening wall surface 79) may be formed. In other words, the life time killer region 85 may be formed only in a region surrounded by the diode opening 77 (opening wall surface 79) in a plan view.

In this embodiment, an example has been shown in which the single life time killer region 85 is formed in each of the diode regions 9. However, the plurality of life time killer regions 85 may be formed at a distance from each other in the thickness direction of the chip 2 in each of the diode regions 9. In this case, each of the life time killer regions 85 has substantially the same form, except that each of the life time killer regions 85 differs in the to-be-formed place (irradiation position of ions or the like) inside the chip 2. The aforementioned description is applied to the description of each of the life time killer regions 85.

The semiconductor device 1 includes an emitter main surface electrode 90 (first main surface electrode) arranged on the interlayer insulating film 73 in the active region 6. The emitter main surface electrode 90 has a layered structure including a first emitter electrode film 91 and a second emitter electrode film 92 stacked together in this order from the interlayer insulating film 73 side. Preferably, the first emitter electrode film 91 is made of a metal film (first emitter metal film).

The first emitter electrode film 91 may include at least one among a tungsten film, a molybdenum film, a nickel film, a pure aluminum film (whose purity is 99% or more), a pure copper film (whose purity is 99% or more), an aluminum alloy film, and a copper alloy film. The first emitter electrode film 91 may include at least one among an AlCu alloy film, an AlSi alloy film, and an AlSiCu alloy film as an example of the aluminum alloy film (copper alloy film). The first emitter electrode film 91 may have a single layer structure made of a single electrode film, or may have a layered structure including a plurality of electrode films. Preferably, the first emitter electrode film 91 has a single layer structure.

The first emitter electrode film 91 may include the same conductive material as the first electrode portion 81 of the first plug electrode 80, or may include a conductive material differing from that of the first electrode portion 81 of the first plug electrode 80. The first emitter electrode film 91 may include the same conductive material as the second electrode portion 82 of the first plug electrode 80, or may include a conductive material differing from that of the second electrode portion 82 of the first plug electrode 80. Preferably, the first emitter electrode film 91 has a resistance value less than the resistance value of the first wiring film 71 (second wiring film 72).

Preferably, the first emitter electrode film 91 is thinner than the interlayer insulating film 73. The first emitter electrode film 91 may be thicker than the main surface insulating film 70, or may be thinner than the main surface insulating film 70. The thickness of the first emitter electrode film 91 may be not less than 0.1 μm and not more than 1 μm. Preferably, the thickness of the first emitter electrode film 91 is not less than 0.3 μm and not more than 0.6 μm.

The first emitter electrode film 91 has a part that directly covers the plurality of first plug electrodes 80. In other words, the first emitter electrode film 91 has a part that directly covers the first electrode portion 81 and the second electrode portion 82 of the plurality of first plug electrodes 80. The first emitter electrode film 91 is electrically connected to the plurality of emitter regions 40 through the plurality of first plug electrodes 80. The first emitter electrode film 91 covers the whole area of the plurality of first plug electrodes 80.

The first emitter electrode film 91 has a part that directly covers the plurality of second plug electrodes 83. The first emitter electrode film 91 is electrically connected to the plurality of first wiring films 71 through the plurality of second plug electrodes 83. The first emitter electrode film 91 covers the whole area of the plurality of second plug electrodes 83.

The first emitter electrode film 91 has a part that directly covers the plurality of third plug electrodes 84. The first emitter electrode film 91 is electrically connected to the plurality of second wiring films 72 through the plurality of third plug electrodes 84. The first emitter electrode film 91 covers the whole area of the plurality of third plug electrodes 84.

In this embodiment, the first emitter electrode film 91 is arranged on the interlayer insulating film 73 so as to cover the plurality of RC-IGBT regions 7 in a plan view. In this embodiment, the first emitter electrode film 91 has a peripheral edge that collectively surrounds the plurality of RC-IGBT regions 7 in a plan view. In this embodiment, the first emitter electrode film 91 is formed in a polygonal shape (specifically, quadrangular shape) having four sides parallel to the first to fourth side surfaces 5A to 5D in a plan view.

As a matter of course, the first emitter electrode film 91 may be formed in a polygonal shape other than a quadrangular shape, a circular shape or an elliptical shape in a plan view. The first emitter electrode film 91 may cover a region equal to or more than 30% of the first main surface 3 in a plan view. Preferably, the first emitter electrode film 91 covers a region equal to or more than 50% of the first main surface 3 in a plan view. Particularly preferably, the first emitter electrode film 91 covers a region equal to or more than 75% of the first main surface 3 in a plan view. Preferably, the first emitter electrode film 91 covers a region equal to or less than 90% of the first main surface 3 in a plan view.

The first emitter electrode film 91 is arranged only on the interlayer insulating film 73 so as not to cover the plurality of diode regions 9. The first emitter electrode film 91 has a plurality of electrode openings 93 that expose the plurality of diode regions 9. Preferably, each of the electrode openings 93 exposes at least one part of each of the opening wall surfaces 79. Particularly preferably, each of the electrode openings 93 exposes the whole area of each of the opening wall surfaces 79.

In other words, the first emitter electrode film 91 is arranged only on the insulation main surface 78, and is not arranged on the opening wall surface 79. Also, the opening wall surface 79 exposed from the first emitter electrode film 91 overlaps with the life time killer region 85 in a plan view. In this embodiment, the electrode opening 93 surrounds the diode opening 77 in a plan view. The electrode opening 93 may be formed at a distance outwardly from the peripheral edge portion of the life time killer region 85 in a plan view. In this case, the electrode opening 93 may surround the life time killer region 85 in a plan view.

As a matter of course, the electrode opening 93 may be located on a more inward side than the peripheral edge portion of the life time killer region 85 in a plan view. In other words, the first emitter electrode film 91 may have a part that overlaps with the peripheral edge portion of the life time killer region 85 in a plan view. In this case, the electrode opening 93 may be surrounded by the peripheral edge portion of the life time killer region 85 in a plan view.

The electrode opening 93 may be formed on the insulation main surface 78 at a distance from the opening wall surface 79. In other words, the electrode opening 93 may expose a part of the insulation main surface 78 from between the opening wall surface 79 and the electrode opening 93. Preferably, the distance between the diode opening 77 and the electrode opening 93 is not less than 0.1 μm and not more than 5 μm. Particularly preferably, the distance between the diode opening 77 and the electrode opening 93 is 1 μm or less.

The first emitter electrode film 91 faces the plurality of first trench electrode structures 20, the plurality of first trench connection structures 24, the plurality of second trench electrode structures 30, the plurality of second trench connection structures 34, the plurality of third trench connection structures 54, and the plurality of fourth trench electrode structures 60 across the interlayer insulating film 73. The first emitter electrode film 91 faces the plurality of emitter regions 40, the plurality of well regions 44, and the plurality of boundary well regions 64 across the interlayer insulating film 73. The first emitter electrode film 91 may have a part that faces a part of the plurality of third trench electrode structures 50 across the interlayer insulating film 73.

In this embodiment, a configuration has been shown in which the single first emitter electrode film 91 collectively covers the plurality of first plug electrodes 80, the plurality of second plug electrodes 83, and the plurality of third plug electrodes 84. However, the plurality of first emitter electrode films 91 may be arranged on the interlayer insulating film 73 so as to individually cover the plurality of first plug electrodes 80, the plurality of second plug electrodes 83, and the plurality of third plug electrodes 84.

The second emitter electrode film 92 forms a main body of the emitter main surface electrode 90. Preferably, the second emitter electrode film 92 is made of a metal film (second emitter metal film). The second emitter electrode film 92 may include at least one among a pure aluminum film (whose purity is 99% or more), a pure copper film (whose purity is 99% or more), an aluminum alloy film, and a copper alloy film. The second emitter electrode film 92 may include at least one among an AlCu alloy film, an AlSi alloy film, and an AlSiCu alloy film as an example of the aluminum alloy film (copper alloy film).

The second emitter electrode film 92 may have a single layer structure made of a single metal film, or may have a layered structure including a plurality of metal films. Preferably, the second emitter electrode film 92 has a single layer structure. Preferably, the second emitter electrode film 92 includes a conductive material differing from that of the first emitter electrode film 91. Particularly preferably, the second emitter electrode film 92 is made of a conductive material differing from that of the first emitter electrode film 91. Preferably, the second emitter electrode film 92 has a resistance value less than the resistance value of the first wiring film 71 (second wiring film 72).

Preferably, the second emitter electrode film 92 is thicker than the first emitter electrode film 91. Preferably, the second emitter electrode film 92 is thicker than the main surface insulating film 70. Particularly preferably, the second emitter electrode film 92 is thicker than the interlayer insulating film 73. The thickness of the second emitter electrode film 92 may be not less than 3 μm and not more than 6 μm. Preferably, the thickness of the second emitter electrode film 92 is not less than 4 μm and not more than 5 μm.

The second emitter electrode film 92 is arranged on the interlayer insulating film 73 so as to cover the plurality of RC-IGBT regions 7 in a plan view. In this embodiment, the second emitter electrode film 92 has a peripheral edge that collectively surrounds the plurality of RC-IGBT regions 7 in a plan view. In this embodiment, the second emitter electrode film 92 is formed in a polygonal shape (specifically, quadrangular shape) having four sides parallel to the first to fourth side surfaces 5A to 5D in a plan view. As a matter of course, the second emitter electrode film 92 may be formed in a polygonal shape other than a quadrangular shape, a circular shape or an elliptical shape in a plan view.

The second emitter electrode film 92 may cover a region equal to or more than 30% of the first main surface 3 in a plan view. Preferably, the second emitter electrode film 92 covers a region equal to or more than 50% of the first main surface 3 in a plan view. Particularly preferably, the second emitter electrode film 92 covers a region equal to or more than 75% of the first main surface 3 in a plan view. Preferably, the second emitter electrode film 92 covers a region equal to or less than 90% of the first main surface 3 in a plan view.

The second emitter electrode film 92 covers the plurality of diode regions 9 and the first emitter electrode film 91. Specifically, the second emitter electrode film 92 directly covers the first emitter electrode film 91. Hence, the second emitter electrode film 92 is electrically connected to the plurality of (all) first plug electrodes 80, to the plurality of (all) second plug electrodes 83, and to the plurality of (all) third plug electrodes 84 through the first emitter electrode film 91.

The second emitter electrode film 92 faces the plurality of (all) first plug electrodes 80 across the first emitter electrode film 91. The second emitter electrode film 92 faces the plurality of (all) second plug electrodes 83 across the first emitter electrode film 91. The second emitter electrode film 92 faces the plurality of (all) third plug electrodes 84 across the first emitter electrode film 91. The second emitter electrode film 92 does not have a part that directly covers the first plug electrode 80, a part that directly covers the second plug electrode 83, and a part that directly covers the third plug electrode 84.

The second emitter electrode film 92 has a part that directly covers the interlayer insulating film 73. Specifically, the second emitter electrode film 92 passes through the plurality of opening wall surfaces 79 from above the first emitter electrode film 91, and is pulled out to the inside of the plurality of diode openings 77. In other words, the second emitter electrode film 92 has a part that directly covers the plurality of opening wall surfaces 79. The second emitter electrode film 92 may have a part that directly covers the main surface insulating film 70 in the plurality of opening wall surfaces 79.

Preferably, the second emitter electrode film 92 covers the whole area of the opening wall surface 79. In a case in which the electrode opening 93 is separated from the diode opening 77, the second emitter electrode film 92 may have a part that covers the insulation main surface 78 (interlayer insulating film 73) in a region between the diode opening 77 and the electrode opening 93.

The second emitter electrode film 92 directly covers the anode region 46 in each of the diode openings 77, and is electrically connected to the anode region 46. Preferably, the second emitter electrode film 92 is directly connected to the plurality of third trench electrode structures 50 in each of the diode openings 77.

Preferably, the second emitter electrode film 92 is directly connected to all of the third trench electrode structures 50 in each of the diode openings 77. Preferably, the second emitter electrode film 92 has a part in contact with the third embedded electrode 53 and a part in contact with the third insulating film 52. Preferably, the second emitter electrode film 92 is electrically connected to the anode region 46 in an opening portion (wide portion) of the third trench 51.

The second emitter electrode film 92 faces the plurality of first trench electrode structures 20, the plurality of first trench connection structures 24, the plurality of second trench electrode structures 30, the plurality of second trench connection structures 34, the plurality of third trench connection structures 54, and the plurality of fourth trench electrode structures 60 across the interlayer insulating film 73. The second emitter electrode film 92 faces the plurality of emitter regions 40, the plurality of well regions 44, and the plurality of boundary well regions 64 across the interlayer insulating film 73. The second emitter electrode film 92 may have a part that directly covers the plurality of third trench connection structures 54.

The semiconductor device 1 includes at least one (in this embodiment, a plurality of) third wiring film 94 arranged on the main surface insulating film 70 in at least one (in this embodiment, a plurality of) street region 10. The third wiring film 94 may be referred to as a “gate wiring line film.” The plurality of third wiring films 94 are each made of conductive polysilicon. The plurality of third wiring films 94 are each formed in a band shape extending along the plurality of street regions 10.

The plurality of third wiring films 94 each have a part that is pulled out from a corresponding one of the street regions 10 onto the adjoining first trench connection structure 24, and are connected to the first embedded electrode 23. The plurality of third wiring films 94 are also parts pulled out from the first embedded electrode 23 to the adjoining street region 10. The plurality of third wiring films 94 have parts pulled out from the plurality of street regions 10 to the outer region 11.

The aforementioned interlayer insulating film 73 covers the plurality of third wiring films 94 in the active region 6 and in the outer region 11. The interlayer insulating film 73 has a plurality of fourth openings 95 that expose the plurality of third wiring films 94, respectively, in the outer region 11. The plurality of fourth openings 95 expose arbitrary places of the plurality of third wiring films 94, respectively. The planar shape and the number of the fourth openings 95 with respect to each of the third wiring films 94 are arbitrary.

The semiconductor device 1 includes a plurality of fourth plug electrodes 96 embedded in the plurality of fourth openings 95 so as to be partially exposed from the interlayer insulating film 73. The plurality of fourth plug electrodes 96 are each electrically connected to a corresponding one of the third wiring films 94 in a corresponding one of the fourth openings 95. Each of the fourth plug electrodes 96 has a layered structure including the first electrode portion 81 and the second electrode portion 82 in the same way as the first plug electrode 80.

The semiconductor device 1 includes a gate main surface electrode 100 (second main surface electrode) arranged on the interlayer insulating film 73 at a distance from the emitter main surface electrode 90 in the outer region 11. The gate main surface electrode 100 has a layered structure including a first gate electrode film 101 and a second gate electrode film 102 stacked together in this order from the interlayer insulating film 73 side. Preferably, the first gate electrode film 101 is made of a metal film (first gate metal film).

The first gate electrode film 101 may include at least one among a tungsten film, a molybdenum film, a nickel film, a pure aluminum film (whose purity is 99% or more), a pure copper film (whose purity is 99% or more), an aluminum alloy film, and a copper alloy film. The first gate electrode film 101 may include at least one among an AlCu alloy film, an AlSi alloy film, and an AlSiCu alloy film as an example of the aluminum alloy film (copper alloy film).

Preferably, the first gate electrode film 101 is thinner than the interlayer insulating film 73. The first gate electrode film 101 may be thicker than the main surface insulating film 70, or may be thinner than the main surface insulating film 70. Particularly preferably, the first gate electrode film 101 includes the same conductive material as the first emitter electrode film 91, and has a thickness substantially equal to that of the first emitter electrode film 91. Preferably, the first gate electrode film 101 has a resistance value less than the resistance value of the third wiring film 94.

Preferably, the first gate electrode film 101 is arranged on the interlayer insulating film 73 so as not to cover either one or both of the IGBT region 8 and the diode region 9. Particularly preferably, the first gate electrode film 101 does not face the RC-IGBT region 7 across the interlayer insulating film 73. The first gate electrode film 101 has a part that directly covers the plurality of fourth plug electrodes 96, and is electrically connected to the plurality of third wiring films 94 through the plurality of fourth plug electrodes 96. Preferably, the first gate electrode film 101 covers the whole area of the plurality of fourth plug electrodes 96.

Specifically, the first gate electrode film 101 has a first pad portion 103 and at least one (in this embodiment, a plurality of) first finger portion 104. The arrangement of the first pad portion 103 is arbitrary. In this embodiment, the first pad portion 103 is arranged in a region in which the first pad portion 103 does not overlap with the RC-IGBT region 7 in a plan view. The first pad portion 103 has a plane area less than the plane area of the emitter main surface electrode 90.

The plane area of the first pad portion 103 may be equal to or less than 20% of the first main surface 3. Preferably, the plane area of the first pad portion 103 is equal to or less than 10% of the first main surface 3. The first pad portion 103 is formed in a polygonal shape (in this embodiment, quadrangular shape) having four sides parallel to the first to fourth side surfaces 5A to 5D in a plan view. The second gate electrode film 102 may be formed in a polygonal shape other than a quadrangular shape, a circular shape or an elliptical shape in a plan view.

The plurality of first finger portions 104 are parts that are pulled out in a band shape from the first pad portion 103 toward the plurality of fourth plug electrodes 96. The plurality of first finger portions 104 cover the plurality of fourth plug electrodes 96, and electrically connect the first pad portion 103 to the plurality of fourth plug electrodes 96. At least one of the plurality of first finger portions 104 may form a mainline portion pulled out from the first pad portion 103, and may form a branch-line portion in which the other first finger portions 104 are pulled out from the mainline portion. As a matter of course, all of the first finger portions 104 may be pulled out from the first pad portion 103.

In a case in which an open portion that exposes a part or all of the street region 10 is formed in the emitter main surface electrode 90, at least one first finger portion 104 may be pulled out from the outer region 11 into the open portion of the emitter main surface electrode 90. In this case, the first finger portion 104 in the open portion may extend along the third wiring film 94.

In this embodiment, a configuration has been shown in which the single first gate electrode film 101 includes the first pad portion 103 and the plurality of first finger portions 104, and collectively covers the plurality of fourth plug electrodes 96. However, the plurality of first gate electrode films 101 may be arranged at a distance from each other on the interlayer insulating film 73 so as to individually cover the plurality of fourth plug electrodes 96. The first gate electrode film 101 is merely required to individually or collectively cover the plurality of fourth plug electrodes 96, and the layout of the first gate electrode film 101 is arbitrary. For example, the presence or absence of the first pad portion 103 and the presence or absence of the first finger portion 104 are arbitrary.

The second gate electrode film 102 forms a main body of the gate main surface electrode 100. Preferably, the second gate electrode film 102 is made of a metal film (second gate metal film). The second gate electrode film 102 may include at least one among a pure aluminum film (whose purity is 99% or more), a pure copper film (whose purity is 99% or more), an aluminum alloy film, and a copper alloy film. The second gate electrode film 102 may include at least one among an AlCu alloy film, an AlSi alloy film, and an AlSiCu alloy film as an example of the aluminum alloy film (copper alloy film).

The second gate electrode film 102 may have a single layer structure made of a single metal film, or may have a layered structure including a plurality of metal films. Preferably, the second gate electrode film 102 has a single layer structure. Preferably, the second gate electrode film 102 includes a conductive material differing from that of the first gate electrode film 101. Particularly preferably, the second gate electrode film 102 is made of a conductive material differing from that of the first gate electrode film 101.

Preferably, the second gate electrode film 102 is thicker than the first gate electrode film 101. Preferably, the second gate electrode film 102 is thicker than the main surface insulating film 70. Particularly preferably, the second gate electrode film 102 is thicker than the interlayer insulating film 73. Particularly preferably, the second gate electrode film 102 includes the same conductive material as the second emitter electrode film 92, and has a thickness substantially equal to that of the second emitter electrode film 92. Preferably, the second gate electrode film 102 has a resistance value less than the resistance value of the third wiring film 94.

The second gate electrode film 102 directly covers the first gate electrode film 101, and is electrically connected to the plurality of fourth plug electrodes 96 through the first gate electrode film 101. Specifically, the second gate electrode film 102 has a second pad portion 105 and at least one (in this embodiment, a plurality of) second finger portion 106. The second pad portion 105 is arranged on the first pad portion 103 so as to directly cover the first pad portion 103.

The plane area of the second pad portion 105 may be equal to or less than 20% of the first main surface 3. Preferably, the plane area of the second pad portion 105 is equal to or less than 10% of the second main surface 4. The second pad portion 105 is formed in a polygonal shape (in this embodiment, quadrangular shape) having four sides parallel to the first to fourth side surfaces 5A to 5D in a plan view. The second gate electrode film 102 may be formed in a polygonal shape other than a quadrangular shape, a circular shape or an elliptical shape in a plan view.

The plurality of second finger portions 106 are pulled out in a band shape from the second pad portion 105 onto the plurality of first finger portions 104 so as to directly cover the plurality of first finger portions 104. The plurality of second finger portions 106 face the plurality of (all) fourth plug electrodes 96 across the plurality of first finger portions 104. Hence, the plurality of second finger portions 106 are electrically connected to the plurality of fourth plug electrodes 96 through the plurality of first finger portions 104.

In a case in which an open portion that exposes a part or all of the street region 10 is formed in the emitter main surface electrode 90, at least one second finger portion 106 may be pulled out from the outer region 11 into the open portion of the emitter main surface electrode 90. In this case, the second finger portion 106 in the open portion may extend along the third wiring film 94.

The semiconductor device 1 includes a collector main surface electrode 110 (third main surface electrode) covering the second main surface 4. The collector main surface electrode 110 is electrically connected to the collector region 14 exposed from the second main surface 4, and is electrically connected to the cathode region 45 exposed from the second main surface 4. The collector main surface electrode 110 may make an ohmic contact with the collector region 14, and may make an ohmic contact with the cathode region 45. The collector main surface electrode 110 may cover the whole area of the second main surface 4 so as to be continuous with the peripheral edge of the chip 2 (first to fourth side surfaces 5A to 5D).

The collector main surface electrode 110 may include at least one among a Ti film, an Ni film, a Pd film, an Au film, an Ag film, and an Al film. The collector main surface electrode 110 may have a single film structure including a Ti film, an Ni film, an Au film, an Ag film, or an Al film. The collector main surface electrode 110 may have a layered structure in which at least two among a Ti film, an Ni film, a Pd film, an Au film, an Ag film, and an Al film are stacked together in an arbitrary manner. In this case, preferably, the collector main surface electrode 110 includes a Ti film that directly covers at least the second main surface 4.

As described above, the semiconductor device 1 includes the chip 2, the IGBT region 8, the diode region 9, the interlayer insulating film 73, the first plug electrode 80, and the emitter main surface electrode 90. The chip 2 has the first main surface 3. The IGBT region 8 is formed at the first main surface 3. The diode region 9 is formed at the first main surface 3. The interlayer insulating film 73 is formed on the first main surface 3 so as to expose the diode region 9 and so as to cover the IGBT region 8.

The first plug electrode 80 is embedded in a part, which covers the IGBT region 8, of the interlayer insulating film 73, and is partially exposed from the interlayer insulating film 73. The emitter main surface electrode 90 includes the first emitter electrode film 91 and the second emitter electrode film 92. The first emitter electrode film 91 covers the first plug electrode 80 so as to expose the diode region 9. The second emitter electrode film 92 covers the first emitter electrode film 91 and the diode region 9.

In a case in which an oxide is formed in the first plug electrode 80, a resistance component caused by this oxide is added to resistance components of the first plug electrode 80. Particularly, the first plug electrode 80 is formed by a comparatively small plane area, and therefore the resistance component caused by the oxide becomes large. In this respect, the first emitter electrode film 91 that conceals the first plug electrode 80 makes it possible to prevent the first plug electrode 80 from coming into contact with external air. This enables the first emitter electrode film 91 to prevent the first plug electrode 80 from being oxidized.

Also, the first emitter electrode film 91 that exposes the diode region 9 is enabled to restrain an unexpected ohmic decrease caused by the first emitter electrode film 91 between the diode region 9 and the second emitter electrode film 92. This makes it possible to improve the properties of the forward voltage VF of the diode region 9. Therefore, it is possible to provide the semiconductor device 1 capable of improving electrical properties.

Preferably, the first emitter electrode film 91 does not cover the diode region 9. Preferably, the diode region 9 includes the anode region 46 formed at the surficial portion of the first main surface 3. In this case, preferably, the first emitter electrode film 91 exposes the anode region 46. Also, preferably, the second emitter electrode film 92 covers the anode region 46.

Preferably, the diode region 9 includes the third trench electrode structure 50 formed at the first main surface 3. In this case, preferably, the first emitter electrode film 91 exposes the third trench electrode structure 50. Also, preferably, the second emitter electrode film 92 covers the third trench electrode structure 50. Preferably, an emitter potential is to be given to the third trench electrode structure 50.

Preferably, the first emitter electrode film 91 directly covers the first plug electrode 80. Preferably, the second emitter electrode film 92 directly covers the first emitter electrode film 91 and the diode region 9. In other words, preferably, the second emitter electrode film 92 directly covers the diode region 9 without a barrier metal film (for example, Ti film).

This structure makes it possible to restrain an unexpected ohmic decrease caused by the barrier metal film between the diode region 9 and the second emitter electrode film 92. This makes it possible to improve the properties of the forward voltage VF of the diode region 9. Preferably, the second emitter electrode film 92 has a part that faces the first plug electrode 80 across the first emitter electrode film 91.

Preferably, the interlayer insulating film 73 has the opening wall surface 79 that defines the diode opening 77 that exposes the diode region 9. In this case, preferably, the first emitter electrode film 91 exposes the opening wall surface 79. Also, preferably, the second emitter electrode film 92 has a part that covers the opening wall surface 79. Preferably, the opening wall surface 79 is inclined so as to make an acute angle with the first main surface 3.

Preferably, the inclination angle of the opening wall surface 79 is more than 45° and less than 90°. This structure enables the second emitter electrode film 92 to face the first main surface 3 through an inclined portion (opening wall surface 79) of the comparatively thick interlayer insulating film 73. This makes it possible to restrain electric field concentration in the vicinity of the inclined portion of the interlayer insulating film 73.

Preferably, the first plug electrode 80 includes tungsten. Preferably, the first emitter electrode film 91 includes at least one among aluminum, aluminum alloy, copper, copper alloy, tungsten, molybdenum, titanium, titanium nitride, and nickel. Preferably, the second emitter electrode film 92 includes at least one among aluminum, aluminum alloy, copper, and copper alloy. Preferably, the second emitter electrode film 92 includes a conductive material differing from that of the first emitter electrode film 91.

Preferably, the first emitter electrode film 91 is thinner than the interlayer insulating film 73. Preferably, the second emitter electrode film 92 is thicker than the first emitter electrode film 91. Particularly preferably, the second emitter electrode film 92 is thicker than the interlayer insulating film 73. Preferably, the first emitter electrode film 91 has a single layer structure. Preferably, the second emitter electrode film 92 has a single layer structure.

The IGBT region 8 may include the p-type base region 15 formed at the surficial portion of the first main surface 3, the first trench electrode structure 20 (gate trench structure) formed at the first main surface 3 so as to pass through the base region 15, and the n-type emitter region 40 formed in a region along the first trench electrode structure 20 in the surficial portion of the base region 15. In this case, the first plug electrode 80 may be electrically connected to the emitter region 40.

The IGBT region 8 may include the contact hole 42 formed in the first main surface 3 so as to expose the emitter region 40 and the p-type contact region 43 formed in a region along the contact hole 42 in the base region 15. In this case, the first plug electrode 80 may be electrically connected to the emitter region 40 and to the contact region 43 in the contact hole 42. The IGBT region 8 may include the n-type CS region 41 formed in a region directly below the base region 15 in the chip 2.

The plurality of IGBT regions 8 may be formed at the first main surface 3. The plurality of diode regions 9 may be formed at the first main surface 3. The plurality of first plug electrodes 80 may be electrically connected to the plurality of IGBT regions 8. The first emitter electrode film 91 may cover the plurality of first plug electrodes 80 so as to expose the plurality of diode regions 9. The second emitter electrode film 92 may cover the plurality of diode regions 9 and the first emitter electrode film 91.

In another respect, the semiconductor device 1 includes the chip 2, the IGBT region 8, the diode region 9, the interlayer insulating film 73, the life time killer region 85, and the emitter main surface electrode 90. The chip 2 has the first main surface 3. The IGBT region 8 is formed at the first main surface 3. The diode region 9 is formed at the first main surface 3. The interlayer insulating film 73 is formed on the first main surface 3 so as to cover the IGBT region 8.

The interlayer insulating film 73 has the diode opening 77 that exposes the diode region 9. The life time killer region 85 is formed inside the chip 2 in the diode region 9 so as to overlap with the diode opening 77 in a plan view. The emitter main surface electrode 90 is arranged on the first main surface 3 so as to be electrically connected to the IGBT region 8 and to the diode region 9. This structure makes it possible to reduce the loss of the diode region 9 during a reverse recovery operation by the regulating effect of a carrier lifetime. Therefore, it is possible to provide the semiconductor device 1 capable of improving electrical properties.

Preferably, the semiconductor device 1 includes the third trench electrode structure 50 (trench structure) formed at the first main surface 3 in the diode region 9. In this case, preferably, the diode opening 77 exposes the third trench electrode structure 50. Also, in this case, preferably, the plurality of third trench electrode structures 50 are formed at the first main surface 3. Preferably, the diode opening 77 exposes the plurality of third trench electrode structures 50.

Preferably, the diode opening 77 collectively exposes all of the third trench electrode structures 50 included in the diode region 9. Preferably, the life time killer region 85 faces the third trench electrode structure 50 in the thickness direction of the chip 2. Preferably, the plurality of diode openings 77 are not formed with respect to the single diode region 9. Preferably, the life time killer region 85 is not formed in the IGBT region 8.

Preferably, the life time killer region 85 has the facing region 86 that faces the interlayer insulating film 73 and the non-facing region 87 that does not face the interlayer insulating film 73 in regard to the thickness direction of the chip 2. Preferably, the life time killer region 85 has the non-facing region 87 in the peripheral edge portion. Preferably, the life time killer region 85 does not have the non-facing region 87 in the inward portion. Preferably, the ratio of the non-facing region 87 in the life time killer region 85 exceeds the ratio of the facing region 86 in the life time killer region 85.

Preferably, the interlayer insulating film 73 has the opening wall surface 79 that defines the diode opening 77. In this case, preferably, the life time killer region 85 has a part that faces the opening wall surface 79 in the thickness direction of the chip 2. Preferably, the opening wall surface 79 makes an acute angle with the first main surface 3. Preferably, the inclination angle of the opening wall surface 79 is more than 45° and less than 90°. This structure enables the emitter main surface electrode 90 to face the first main surface 3 through the inclined portion of the comparatively thick interlayer insulating film 73 (opening wall surface 79). This makes it possible to restrain electric field concentration in the vicinity of the inclined portion of the interlayer insulating film 73.

Preferably, the plurality of IGBT regions 8 are formed at the first main surface 3. Preferably, the plurality of diode regions 9 are formed at the first main surface 3. Preferably, the plurality of diode openings 77 are formed one by one with respect to the plurality of diode regions 9. Preferably, the plurality of life time killer regions 85 are formed one by one with respect to the plurality of diode regions 9.

Preferably, the semiconductor device 1 includes the first plug electrode 80. The first plug electrode 80 is embedded in a part, which covers the IGBT region 8, of the interlayer insulating film 73, and is partially exposed from the interlayer insulating film 73. In this case, preferably, the emitter main surface electrode 90 includes the first emitter electrode film 91 and the second emitter electrode film 92. The first emitter electrode film 91 covers the first plug electrode 80 so as to expose the diode region 9. The second emitter electrode film 92 covers the first emitter electrode film 91 and the diode region 9.

In a case in which an oxide is formed in the first plug electrode 80, a resistance component caused by this oxide is added to resistance components of the first plug electrode 80. Particularly, the first plug electrode 80 is formed with a comparatively small plane area, and therefore the resistance component caused by the oxide becomes large. In this respect, the first emitter electrode film 91 that conceals the first plug electrode 80 makes it possible to prevent the first plug electrode 80 from coming into contact with external air. This enables the first emitter electrode film 91 to prevent the first plug electrode 80 from being oxidized.

Also, the first emitter electrode film 91 that exposes the diode region 9 is enabled to restrain an unexpected ohmic decrease caused by the first emitter electrode film 91 between the diode region 9 and the second emitter electrode film 92. This makes it possible to improve the properties of the forward voltage VF of the diode region 9. Therefore, it is possible to provide the semiconductor device 1 capable of improving electrical properties.

Preferably, the first emitter electrode film 91 does not cover the diode region 9. Preferably, the diode region 9 includes the anode region 46 formed at the surficial portion of the first main surface 3. In this case, preferably, the first emitter electrode film 91 exposes the anode region 46. Also, preferably, the second emitter electrode film 92 covers the anode region 46.

Preferably, the diode region 9 includes the third trench electrode structure 50 formed at the first main surface 3. In this case, preferably, the first emitter electrode film 91 exposes the third trench electrode structure 50. Also, preferably, the second emitter electrode film 92 covers the third trench electrode structure 50. Preferably, an emitter potential is to be given to the third trench electrode structure 50.

Preferably, the first emitter electrode film 91 directly covers the first plug electrode 80. Preferably, the second emitter electrode film 92 directly covers the first emitter electrode film 91 and the diode region 9. In other words, preferably, the second emitter electrode film 92 directly covers the diode region 9 without a barrier metal film (for example, Ti film).

This structure makes it possible to restrain an unexpected ohmic decrease caused by the barrier metal film between the diode region 9 and the second emitter electrode film 92. This makes it possible to improve the properties of the forward voltage VF of the diode region 9. Preferably, the second emitter electrode film 92 has a part that faces the first plug electrode 80 across the first emitter electrode film 91.

Preferably, the interlayer insulating film 73 has the opening wall surface 79 that defines the diode opening 77 that exposes the diode region 9. In this case, preferably, the first emitter electrode film 91 exposes the opening wall surface 79. Also, preferably, the second emitter electrode film 92 has a part that covers the opening wall surface 79. Preferably, the opening wall surface 79 is inclined so as to make an acute angle with the first main surface 3.

Preferably, the inclination angle of the opening wall surface 79 is more than 45° and less than 90°. This structure enables the second emitter electrode film 92 to face the first main surface 3 through an inclined portion (opening wall surface 79) of the comparatively thick interlayer insulating film 73. This makes it possible to restrain electric field concentration in the vicinity of the inclined portion of the interlayer insulating film 73.

Preferably, the first plug electrode 80 includes tungsten. Preferably, the first emitter electrode film 91 includes at least one among aluminum, aluminum alloy, copper, copper alloy, tungsten, molybdenum, titanium, titanium nitride, and nickel. Preferably, the second emitter electrode film 92 includes at least one among aluminum, aluminum alloy, copper, and copper alloy. Preferably, the second emitter electrode film 92 includes a conductive material differing from that of the first emitter electrode film 91.

Preferably, the first emitter electrode film 91 is thinner than the interlayer insulating film 73. Preferably, the second emitter electrode film 92 is thicker than the first emitter electrode film 91. Particularly preferably, the second emitter electrode film 92 is thicker than the interlayer insulating film 73. Preferably, the first emitter electrode film 91 has a single layer structure. Preferably, the second emitter electrode film 92 has a single layer structure.

The IGBT region 8 may include the p-type base region 15 formed at the surficial portion of the first main surface 3, the first trench electrode structure 20 (gate trench structure) formed at the first main surface 3 so as to pass through the base region 15, and the n-type emitter region 40 formed in a region along the first trench electrode structure 20 in the surficial portion of the base region 15. In this case, the first plug electrode 80 may be electrically connected to the emitter region 40.

The IGBT region 8 may include the contact hole 42 formed in the first main surface 3 so as to expose the emitter region 40 and the p-type contact region 43 formed in a region along the contact hole 42 in the base region 15. In this case, the first plug electrode 80 may be electrically connected to the emitter region 40 and to the contact region 43 in the contact hole 42. The IGBT region 8 may include the n-type CS region 41 formed in a region directly below the base region 15 in the chip 2.

The plurality of IGBT regions 8 may be formed at the first main surface 3. The plurality of diode regions 9 may be formed at the first main surface 3. The plurality of first plug electrodes 80 may be electrically connected to the plurality of IGBT regions 8. The first emitter electrode film 91 may cover the plurality of first plug electrodes 80 so as to expose the plurality of diode regions 9. The second emitter electrode film 92 may cover the plurality of diode regions 9 and the first emitter electrode film 91.

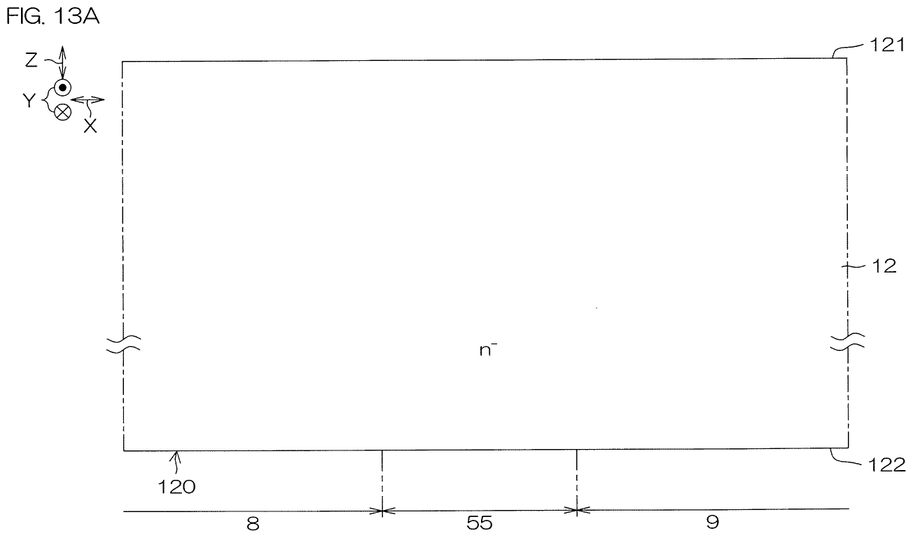

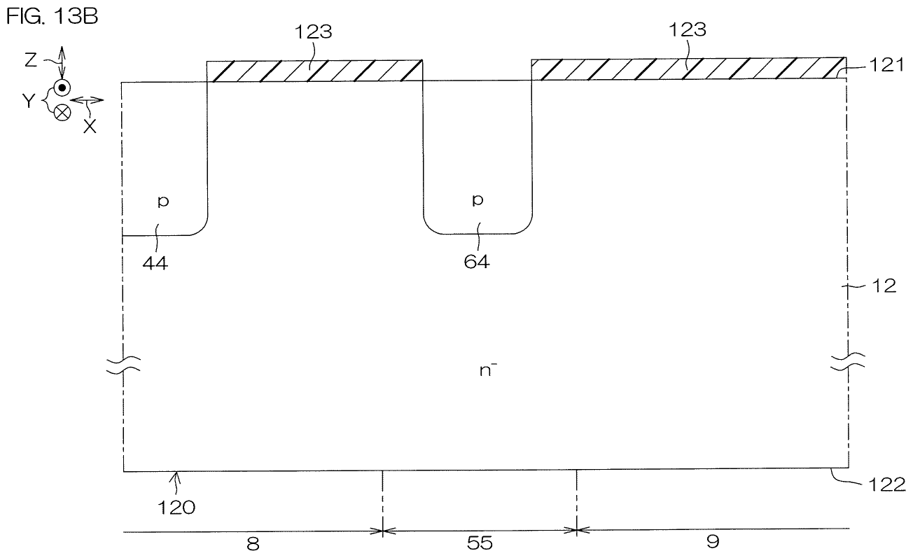

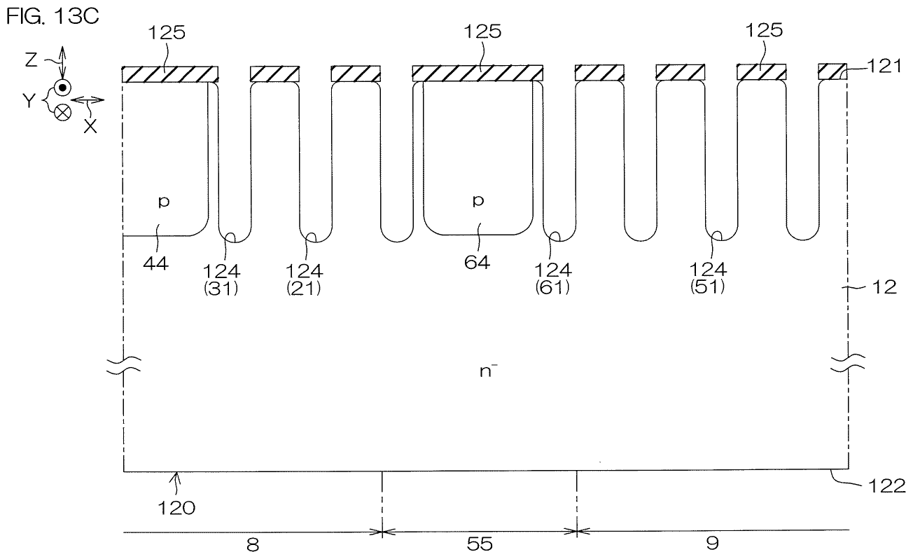

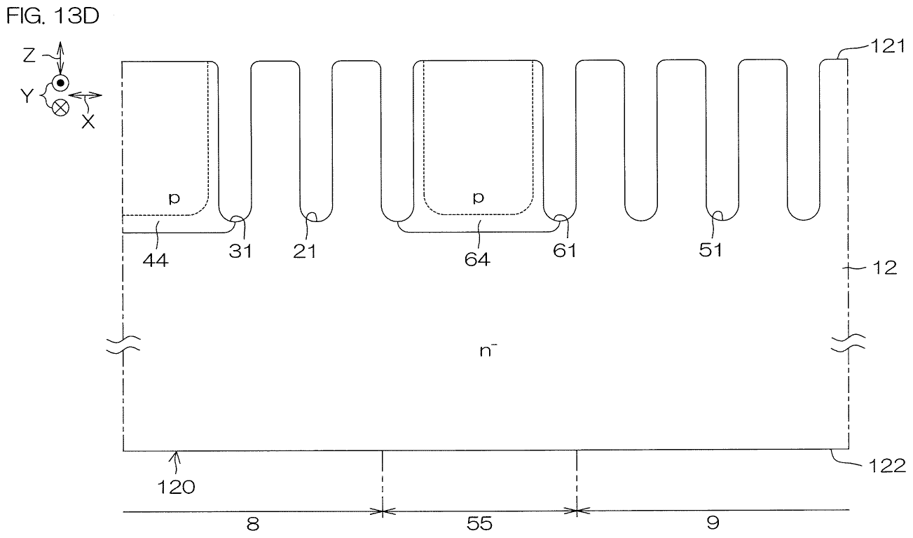

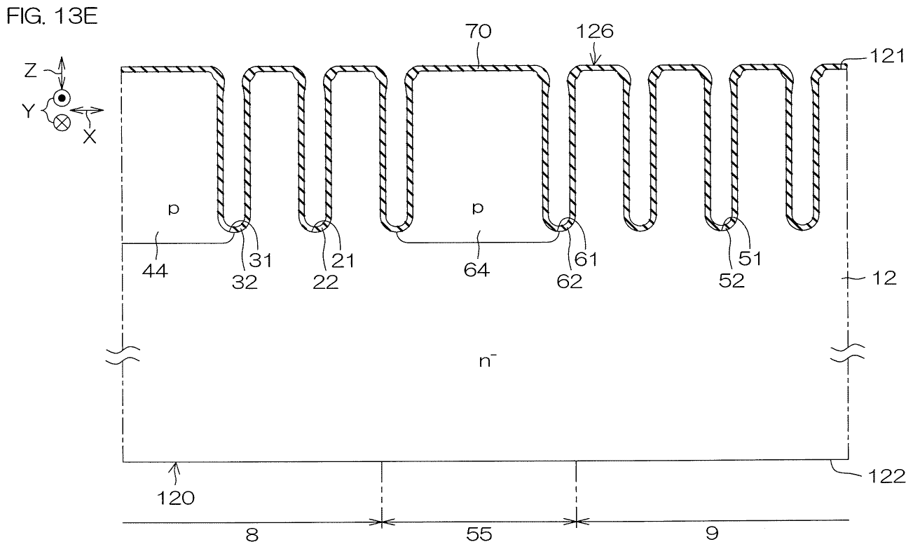

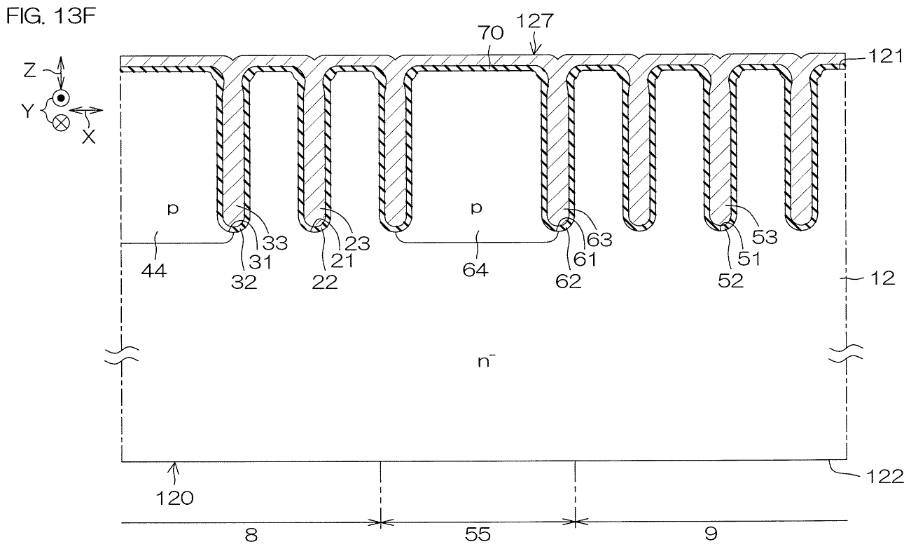

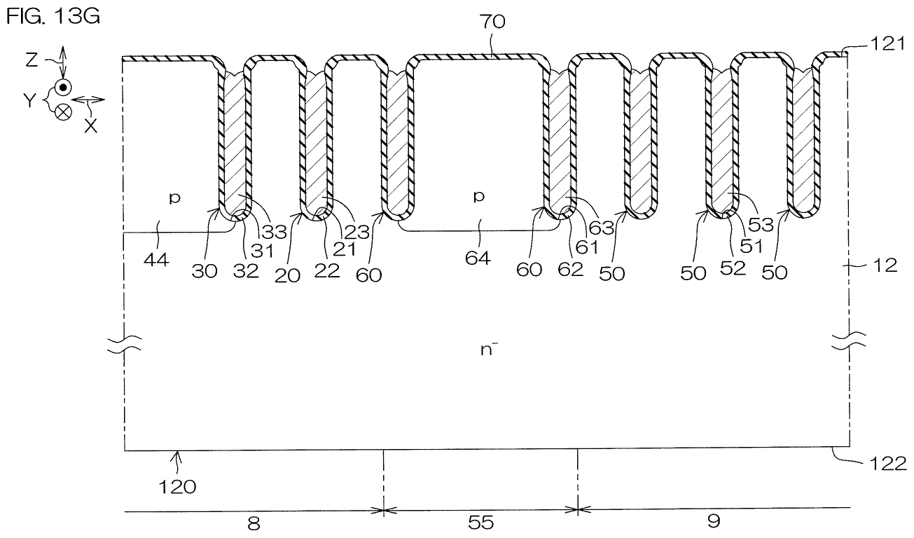

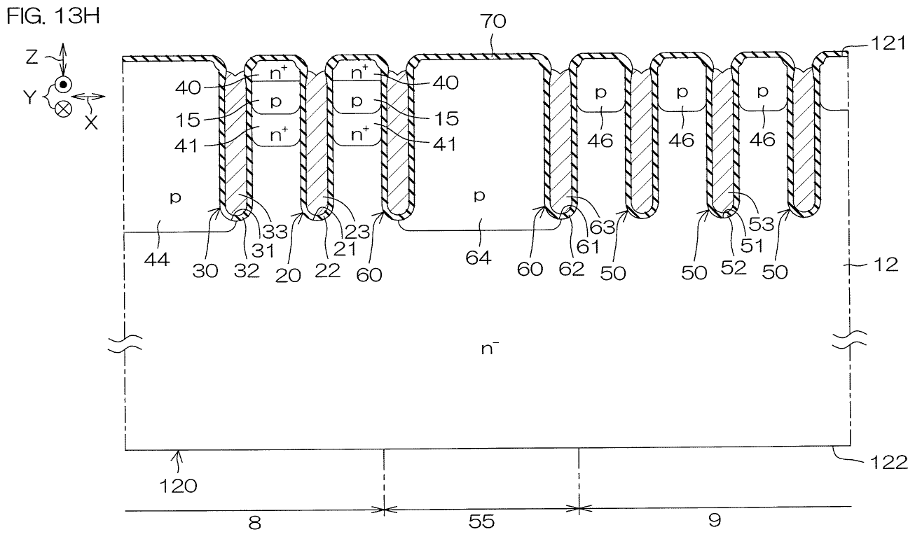

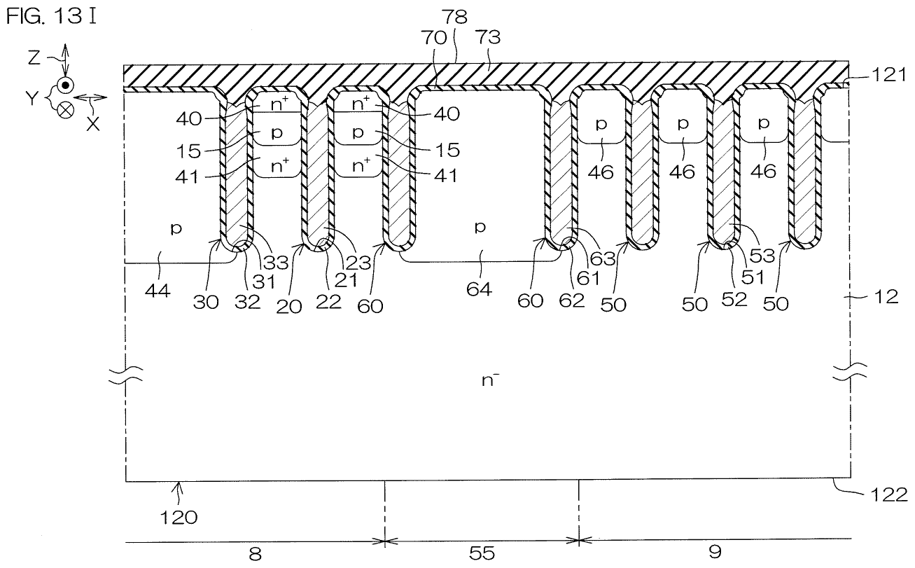

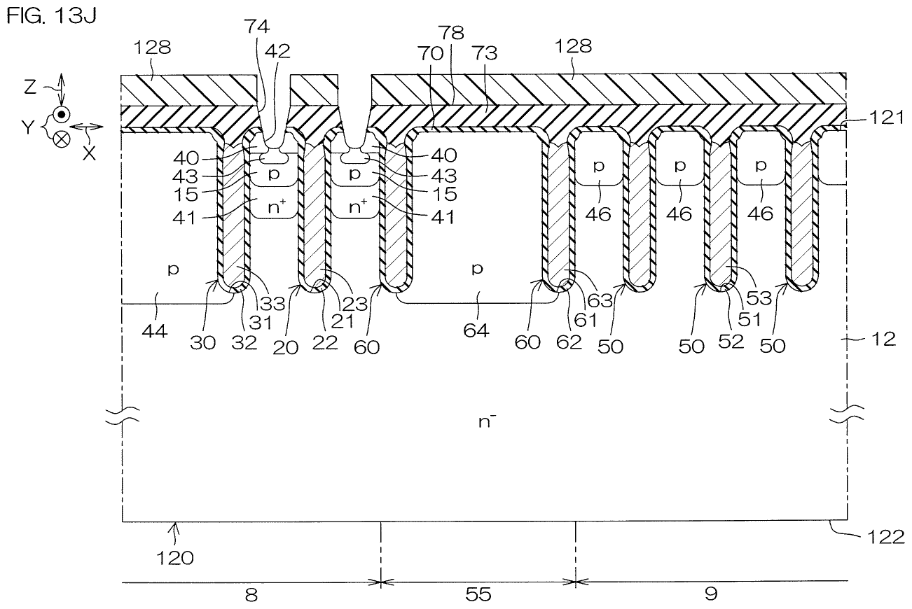

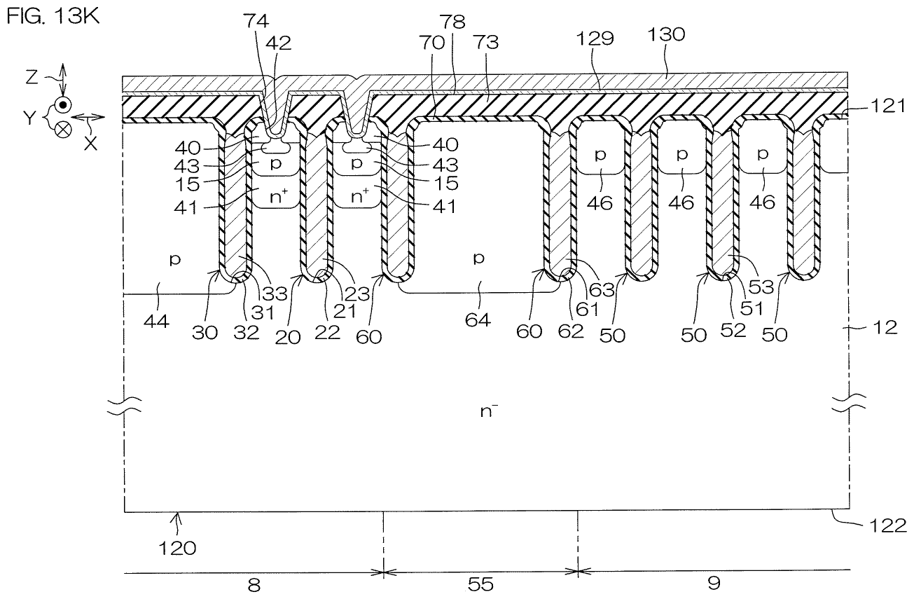

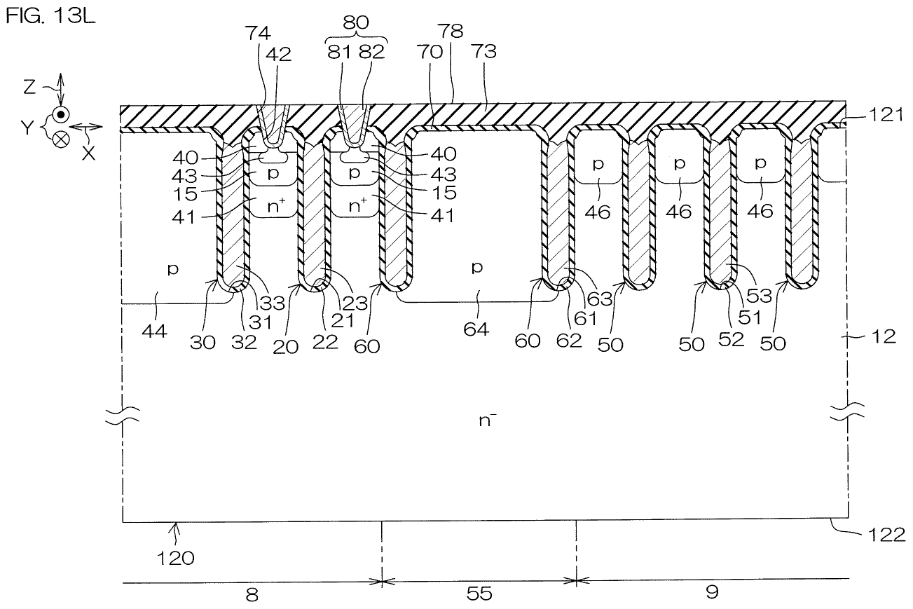

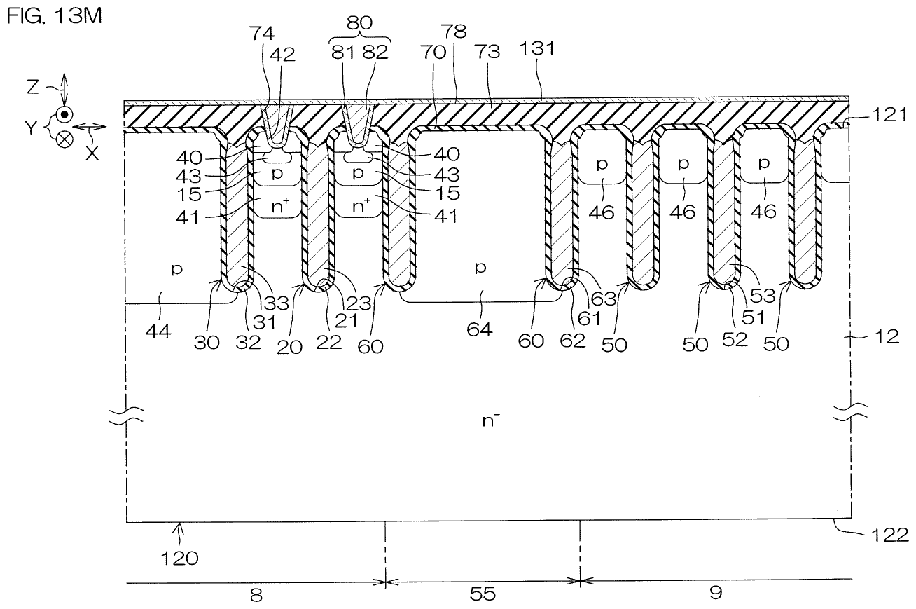

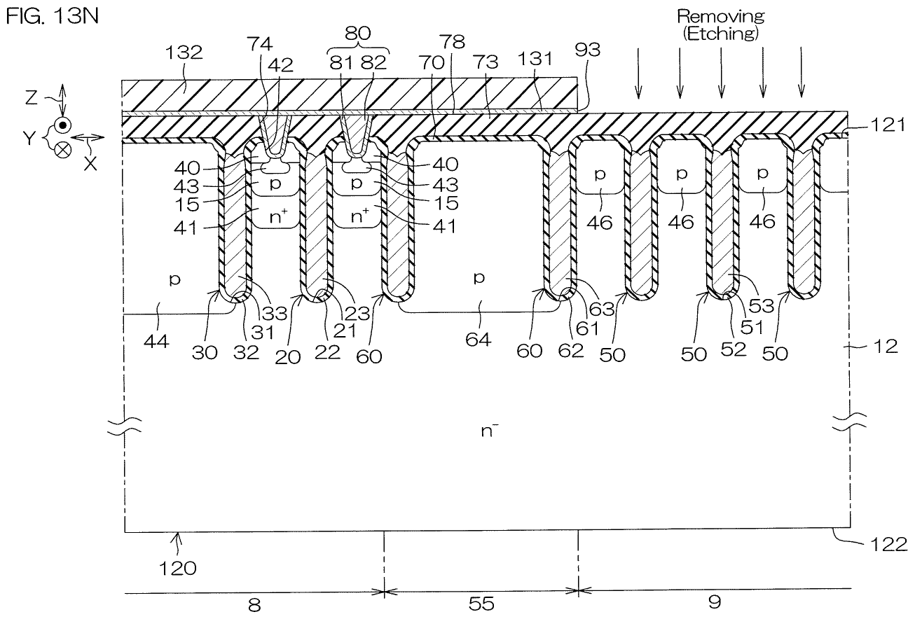

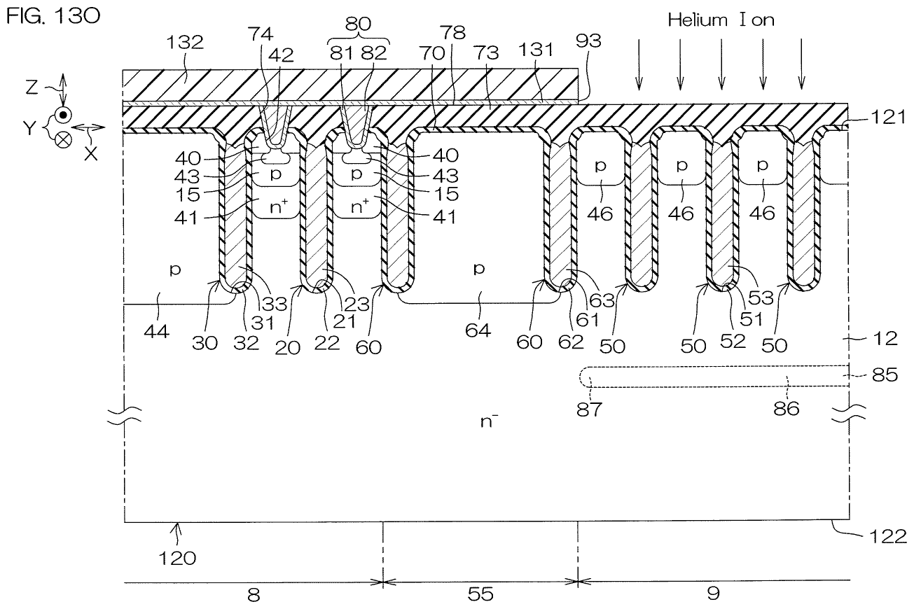

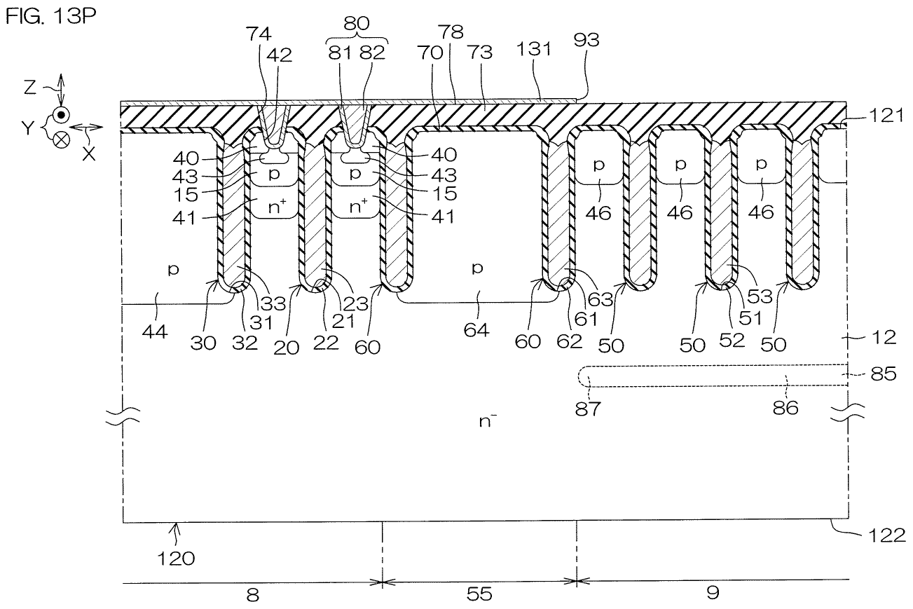

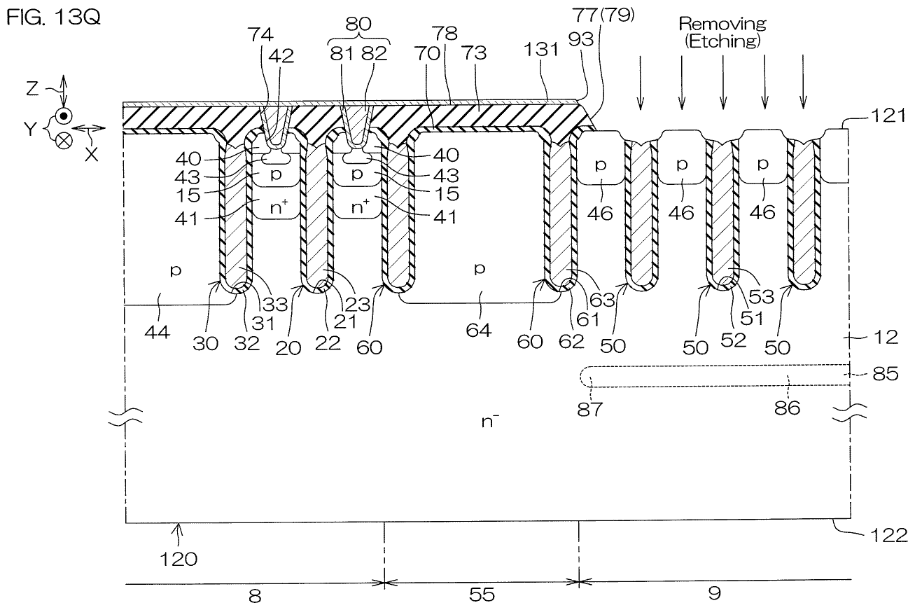

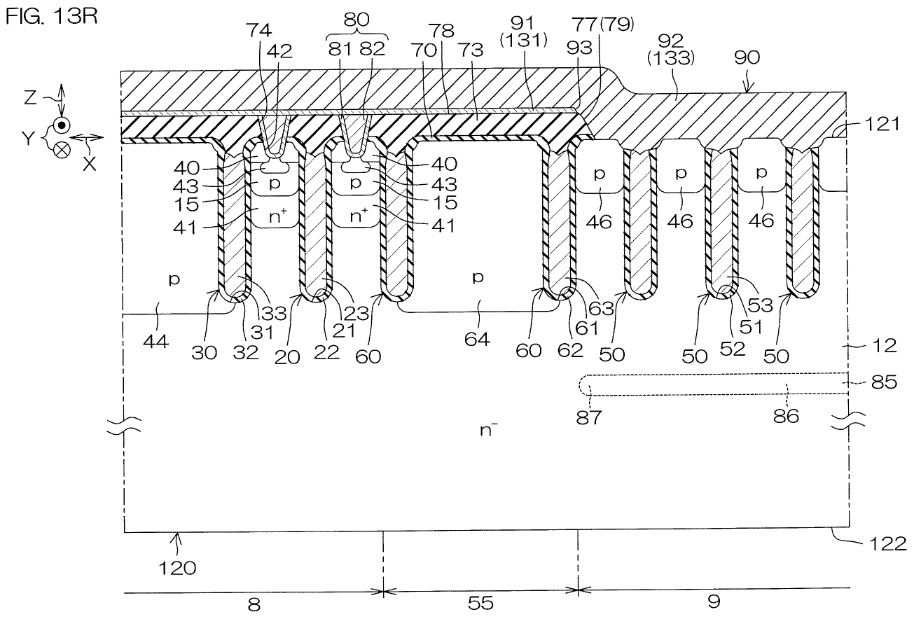

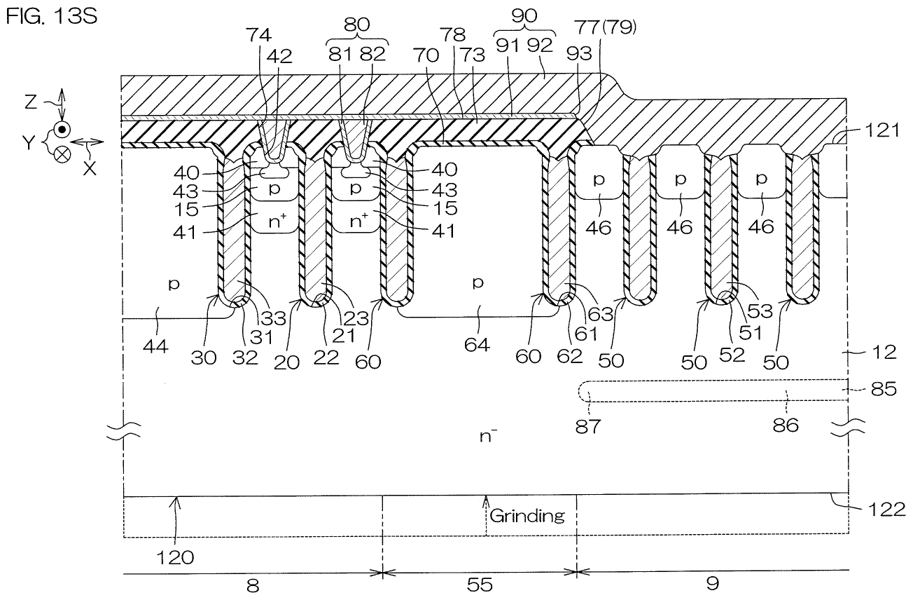

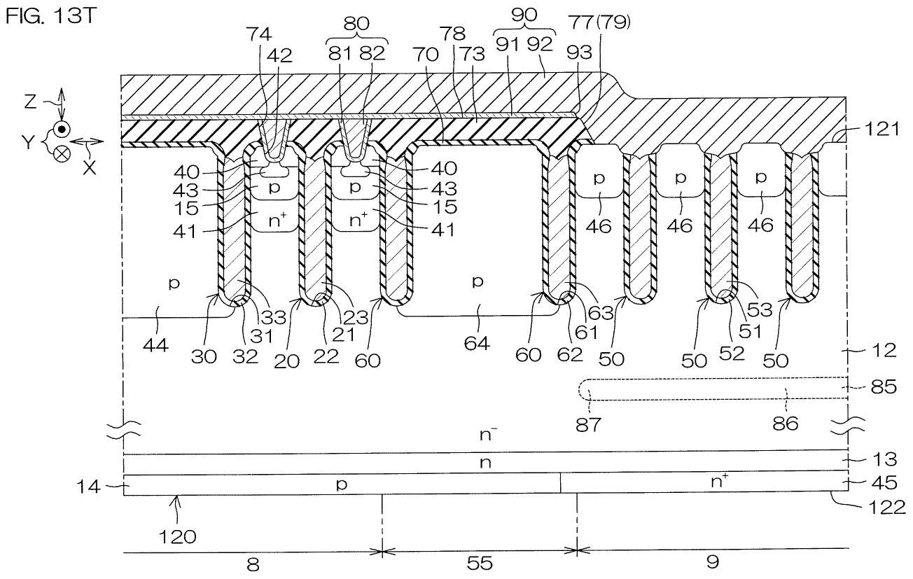

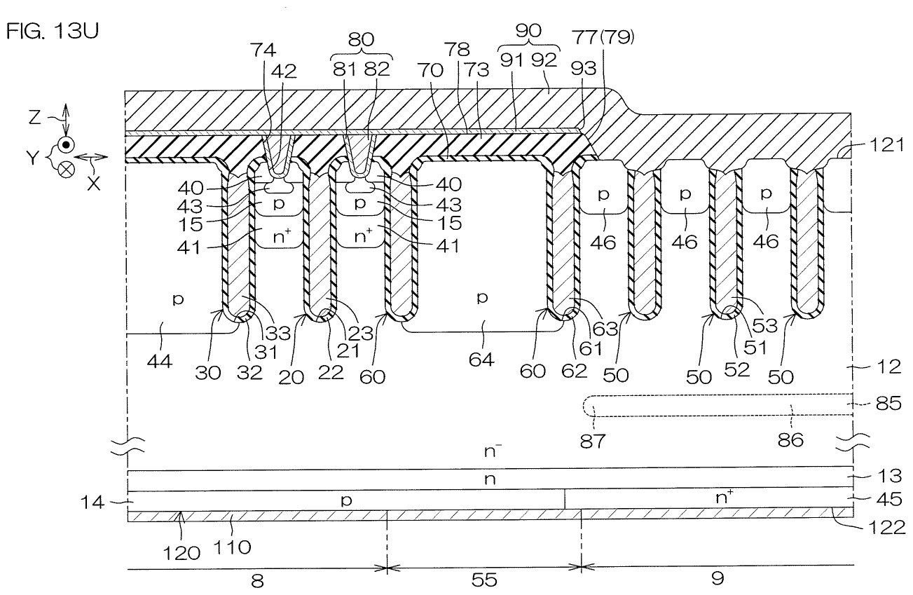

FIG. 13A to FIG. 13U are cross sectional views showing an example of a manufacturing method for the semiconductor device 1 shown in FIG. 1. FIG. 13A to FIG. 13U show regions (i.e., the IGBT region 8 and the diode region 9) corresponding to FIG. 8, respectively.

Referring to FIG. 13A, an n-type wafer 120 that is to be a base of the chip 2 is prepared. The wafer 120 may be an FZ substrate formed through an FZ (Floating Zone) method. The wafer 120 has a first wafer main surface 121 and a second wafer main surface 122. The first wafer main surface 121 and the second wafer main surface 122 correspond to the first main surface 3 and the second main surface 4 of the chip 2, respectively. Next, the RC-IGBT region 7 (plurality of IGBT regions 8 and plurality of diode regions 9) is set in the wafer 120.

Next, referring to FIG. 13B, the plurality of p-type well regions 44 and the plurality of p-type boundary well regions 64 are formed in the RC-IGBT region 7. In this step, a resist mask 123 having a predetermined pattern is first formed on the first wafer main surface 121. The resist mask 123 exposes regions in which the plurality of well regions 44 and the plurality of boundary well regions 64 are to be formed, and covers regions other than these regions of the regions 44 and 64 to be formed. Next, a p-type impurity is introduced into a surficial portion of the first wafer main surface 121 by an ion implantation method through the resist mask 123. Hence, the plurality of well regions 44 and the plurality of boundary well regions 64 are formed in the RC-IGBT region 7. The resist mask 123 is removed afterwards.

Next, referring to FIG. 13C, a plurality of trenches 124 are formed in the RC-IGBT region 7. The plurality of trenches 124 include the plurality of first trenches 21, the plurality of second trenches 31, the plurality of third trenches 51, and the plurality of fourth trenches 61. In this step, a hard mask 125 having a predetermined pattern is formed on the first wafer main surface 121. The hard mask 125 exposes regions in which the plurality of trenches 124 are to be formed, and covers regions other than these regions of the trenches 124 to be formed. The hard mask 125 may be made of an inorganic insulating film.

Next, an unnecessary part of the wafer 120 is removed by an etching method through the hard mask 125. The etching method may be a dry etching method and/or a wet etching method. Hence, the plurality of trenches 124 are formed in the RC-IGBT region 7. The hard mask 125 is removed afterwards.

Next, referring to FIG. 13D, p-type impurities of the plurality of well regions 44 and p-type impurities of the plurality of boundary well regions 64 are diffused into the wafer 120. The p-type impurities of the plurality of well regions 44 are diffused to a depth to which the p-type impurities cover the bottom wall of the second trench 31. Also, the p-type impurities of the plurality of boundary well regions 64 are diffused to a depth to which the p-type impurities cover the bottom wall of the fourth trench 61.

Next, referring to FIG. 13E, a base insulating film 126 is formed at the first wafer main surface 121. The base insulating film 126 includes the first insulating film 22, the second insulating film 32, the third insulating film 52, the fourth insulating film 62, and the main surface insulating film 70. The base insulating film 126 may be formed by a CVD (Chemical Vapor Deposition) method and/or an oxidation treatment method (for example, thermal oxidation treatment method).

Next, referring to FIG. 13F, a base electrode film 127 is formed on the base insulating film 126. The base electrode film 127 serves as a base of the first embedded electrode 23, a base of the second embedded electrode 33, a base of the third embedded electrode 53, a base of the fourth embedded electrode 63, a base of the first wiring film 71, a base of the second wiring film 72, and a base of the third wiring film 94. The base electrode film 127 is embedded in the plurality of trenches 124 with the base insulating film 126 between the base electrode film 127 and the trenches 124, and covers the first wafer main surface 121 with the base insulating film 126 between the base electrode film 127 and the first wafer main surface 121. The base electrode film 127 includes conductive polysilicon. The base electrode film 127 may be formed by the CVD method.

Next, referring to FIG. 13G, an unnecessary part of the base electrode film 127 is removed. In this step, a resist mask (not shown) having a predetermined pattern is formed on the base electrode film 127. The resist mask (not shown) covers a region in which the first wiring film 71, the second wiring film 72, and the third wiring film 94 are to be formed, and exposes regions other than the regions of those wiring films to be formed.

Next, an unnecessary part of the base electrode film 127 is removed by the etching method through a resist mask (not shown). The etching method may be the dry etching method and/or the wet etching method. The unnecessary part of the base electrode film 127 is removed until the main surface insulating film 70 is exposed. Hence, the first embedded electrode 23, the second embedded electrode 33, the third embedded electrode 53, the fourth embedded electrode 63, the first wiring film 71, the second wiring film 72, and the third wiring film 94 are formed. The resist mask (not shown) is removed afterwards.

Next, referring to FIG. 13H, the p-type base region 15, the n-type emitter region 40, the n-type CS region 41, and the p-type anode region 46 are formed at the surficial portion of the first wafer main surface 121 in the RC-IGBT region 7. The base region 15, the emitter region 40, and the CS region 41 are formed at the surficial portion of the first wafer main surface 121 of the IGBT region 8. The anode region 46 is formed at the surficial portion of the first wafer main surface 121 of the diode region 9. The order of the steps of forming these impurity regions is arbitrary. These impurity regions are each formed by injecting an n-type impurity or a p-type impurity through a resist mask (not shown) having a predetermined pattern.

Next, referring to FIG. 13I, the interlayer insulating film 73, which covers the main surface insulating film 70, the first wiring film 71, the second wiring film 72, and the third wiring film 94, is formed. The interlayer insulating film 73 may be formed by the CVD method.

Next, referring to FIG. 13J, a resist mask 128 having a predetermined pattern is formed on the interlayer insulating film 73. The resist mask 128 exposes a region in which the first opening 74, the second opening 75, the third opening 76, and the fourth opening 95 are to be formed, and covers regions other than the region of these openings to be formed.

Next, an unnecessary part of the interlayer insulating film 73 is removed by the etching method through the resist mask 128. The etching method may be the dry etching method and/or the wet etching method. The unnecessary part of the interlayer insulating film 73 is removed until the main surface insulating film 70 is exposed. Hence, the first opening 74, the second opening 75, the third opening 76, and the fourth opening 95 are formed. The resist mask 128 is removed afterwards.

Next, a resist mask (not shown) having a predetermined pattern is formed on the interlayer insulating film 73. The resist mask (not shown) exposes a region (i.e., plurality of first openings 74) in which the plurality of contact holes 42 are to be formed, and covers regions other than the region of the contact holes 42 to be formed. Next, a part, which is exposed from the first opening 74, of the first wafer main surface 121 is further removed by the etching method through the resist mask (not shown). The etching method may be the dry etching method and/or the wet etching method. Hence, the contact hole 42 communicating with the first opening 74 is formed.

Next, a p-type impurity is injected into a part, which is exposed from the plurality of contact holes 42, of the first wafer main surface 121 by an ion implantation method through the resist mask (not shown). Hence, the p-type contact region 43 is formed. The resist mask (not shown) is removed afterwards.

Next, referring to FIG. 13K, a first plug electrode film 129 is formed on the interlayer insulating film 73. The first plug electrode film 129 serves as a base of the first electrode portion 81 according to the first plug electrode 80, the second plug electrode 83, the third plug electrode 84, and the fourth plug electrode 96. The first plug electrode film 129 is formed in a film shape along the interlayer insulating film 73 (insulation main surface 78), the wall surface of the contact hole 42, the wall surface of the first opening 74, the wall surface of the second opening 75, the wall surface of the third opening 76, and the wall surface of the fourth opening 95. The first plug electrode film 129 may be formed by a sputtering method and/or a vapor deposition method.

Next, a second plug electrode film 130 is formed on the first plug electrode film 129. The second plug electrode film 130 serves as a base of the second electrode portion 82 according to the first plug electrode 80, the second plug electrode 83, the third plug electrode 84, and the fourth plug electrode 96. The second plug electrode film 130 fills the contact hole 42, the first opening 74, the second opening 75, the third opening 76, and the fourth opening 95, and covers the first plug electrode film 129. The second plug electrode film 130 may be formed by the sputtering method and/or the vapor deposition method.

Next, referring to FIG. 13L, an unnecessary part of the second plug electrode film 130 is removed. The unnecessary part of the second plug electrode film 130 is removed by the etching method. The etching method may be the dry etching method and/or the wet etching method. In this step, a part, which is located outside the contact hole 42, the first opening 74, the second opening 75, the third opening 76, and the fourth opening 95, of the second plug electrode film 130 is removed.

Next, an unnecessary part of the first plug electrode film 129 is removed. The unnecessary part of the first plug electrode film 129 is removed by the etching method. The etching method may be the dry etching method and/or the wet etching method. In this step, a part, which is located outside the contact hole 42, the first opening 74, the second opening 75, the third opening 76, and the fourth opening 95, of the first plug electrode film 129 is removed. Hence, the first plug electrode 80, the second plug electrode 83, the third plug electrode 84, and the fourth plug electrode 96 are formed.

Next, referring to FIG. 13M, a first base electrode film 131 (first mask) is formed on the interlayer insulating film 73. The first base electrode film 131 serves as a base of the first emitter electrode film 91 and as a base of the first gate electrode film 101. In this embodiment, the first base electrode film 131 is made of a metal film (first base metal film).

The first base electrode film 131 is formed in a film shape extending along the interlayer insulating film 73, and covers the first plug electrode 80, the second plug electrode 83, the third plug electrode 84, and the fourth plug electrode 96. The first base electrode film 131 is a barrier film that prevents the first plug electrode 80, the second plug electrode 83, the third plug electrode 84, and the fourth plug electrode 96 from coming into contact with external air. The first base electrode film 131 may be formed by the sputtering method and/or the vapor deposition method.

Next, referring to FIG. 13N, a resist mask 132 (second mask) having a predetermined pattern is formed on the first base electrode film 131. The resist mask 132 exposes a region in which the plurality of electrode openings 93 are to be formed in the first base electrode film 131, and covers regions other than the region of the electrode openings 93 to be formed. Next, an unnecessary part of the base metal film is removed by the etching method through the resist mask 132. The etching method may be the dry etching method and/or the wet etching method. Hence, the plurality of electrode openings 93 are formed in the first base electrode film 131.

Next, referring to FIG. 13O, the life time killer region 85 is formed in each of the plurality of diode regions 9 inside the wafer 120. In this step, only one life time killer region 85 is formed with respect to the single diode region, and the plurality of life time killer regions 85 are not formed with respect to the single diode region. The life time killer region 85 is formed by irradiating an arbitrary impurity (element) to a region in which the life time killer region 85 is to be formed.

Preferably, the life time killer region 85 is formed by inputting a component (element/impurity) other than a trivalent element (p-type impurity) and a quinquevalent element (n-type impurity) into the wafer 120. The life time killer region 85 may be formed by irradiating either one or both of a hydrogen ion and a helium ion into the wafer 120. In this step, the life time killer region 85 is formed by irradiating a helium ion into the wafer 120.

In this step, the aforementioned resist mask 132 is used as a shielding film, and a helium ion or the like is irradiated into the wafer 120 through the resist mask 132. In other words, the helium ion or the like is introduced from the plurality of electrode openings 93 into the wafer 120. Hence, the life time killer region 85 is formed in a self-aligned manner with respect to the resist mask 132 (electrode opening 93).

According to this step, the life time killer region 85 is formed by use of the resist mask 132 used in the step of forming the electrode opening 93, and therefore the alignment accuracy of the life time killer region 85 with respect to the electrode opening 93 is improved. In other words, the alignment accuracy of the life time killer region 85 with respect to the diode region 9 is improved, thus making it possible to appropriately form the life time killer region 85 only in the diode region 9.

Next, referring to FIG. 13P, the wafer 120 is exposed to an oxygen atmosphere, and the resist mask 132 is removed. In this step, the resist mask 132 is removed by an oxygen ashing method using oxygen (oxygen atmosphere of ozone gas, oxygen gas, and the like). The oxygen ashing method may be a photoexcitation ashing method and/or a plasma ashing method.

In the photoexcitation ashing method, oxygen is excited by ultraviolet light or the like in an ashing room, and is allowed to react with the resist mask 132. In the plasma ashing method, oxygen is plasmatized by non-ionizing radiation (e.g., visible light, high frequency, microwaves, etc.) in an ashing room, and is allowed to react with the resist mask 132. Hence, the resist mask 132 is removed from the top surface of the first base electrode film 131, and the first base electrode film 131 is exposed to an oxygen atmosphere. The oxidation of the first plug electrode 80, the second plug electrode 83, the third plug electrode 84, and the fourth plug electrode 96, which is caused by the oxygen ashing step, is restrained by the first base electrode film 131.

Next, referring to FIG. 13Q, an unnecessary part of the interlayer insulating film 73 and an unnecessary part of the main surface insulating film 70 are removed by the etching method that uses the first base electrode film 131 as a mask. The etching method may be the dry etching method and/or the wet etching method. Preferably, the etching method is an anisotropic etching method. Particularly preferably, the anisotropic etching method is the dry etching method (specifically, RIE (Reactive Ion Etching) method).

In this step, the unnecessary part of the interlayer insulating film 73 and the unnecessary part of the main surface insulating film 70 are removed in sequence. Hence, the plurality of diode openings 77 that positionally overlap with the plurality of electrode openings 93 and with the plurality of life time killer regions 85 are formed at the interlayer insulating film 73. In this step, the opening wall surface 79 of the diode opening 77 is formed on an inclined surface that makes an acute angle with the first wafer main surface 121. Preferably, the inclination angle of the opening wall surface 79 is more than 45° and less than 90°. As a matter of course, the unnecessary part of the interlayer insulating film 73 and the unnecessary part of the main surface insulating film 70 may be removed by an isotropic etching method (for example, wet etching method). In this case, the inclination angle of the opening wall surface 79 may be less than 45°.

In this step, an example has been shown in which the removal step of removing the resist mask 132 is performed before the removal step of removing the interlayer insulating film 73. However, the removal step of removing the resist mask 132 may be performed after the removal step of removing the interlayer insulating film 73. In other words, in the removal step of removing the interlayer insulating film 73, an unnecessary part of the interlayer insulating film 73 and an unnecessary part of the main surface insulating film 70 may be removed by an etching method in which a layered structure including the first base electrode film 131 and the resist mask 132 is used as a mask. The “etching method that uses the first base electrode film 131 as a mask” includes an “etching method that uses a single layer structure consisting of the first base electrode film 131 as a mask,” and Also includes an “etching method that uses a layered structure including both the first base electrode film 131 and the resist mask 132 a mask.”

In the removal step of removing the interlayer insulating film 73, the unnecessary part of the interlayer insulating film 73 is removed by use of the same mask as the mask used when the life time killer region 85 is formed. In other words, the alignment accuracy of the removed part of the interlayer insulating film 73 is substantially equal to the alignment accuracy of the life time killer region 85. This makes it possible to appropriately form the diode opening 77, which exposes the diode region 9, in the interlayer insulating film 73.

Next, referring to FIG. 13R, the second base electrode film 133 is formed on the interlayer insulating film 73 and on the first wafer main surface 121 so as to cover the first base electrode film 131. The second base electrode film 133 serves as a base of the second emitter electrode film 92 and as a base of the second gate electrode film 102. The second base electrode film 133 may be formed by the sputtering method and/or the vapor deposition method.

Next, a resist mask (not shown) having a predetermined pattern is formed on the second base electrode film 133. The resist mask (not shown) covers a region in which the second emitter electrode film 92 and the second gate electrode film 102 are to be formed, and exposes regions other than the region of the electrode films 92 and 102 to be formed. Next, an unnecessary part of the second base electrode film 133 is removed by the etching method through a resist mask (not shown). The etching method may be the dry etching method and/or the wet etching method. Hence, the second emitter electrode film 92 and the second gate electrode film 102 are formed. The resist mask (not shown) is removed afterwards.

Next, a part, which is exposed from the second emitter electrode film 92 and from the second gate electrode film 102, of the first base electrode film 131 is removed by the etching method. The etching method may be the dry etching method and/or the wet etching method. Hence, the first emitter electrode film 91 and the first gate electrode film 101 are formed. In other words, the emitter main surface electrode 90 and the gate main surface electrode 100 are formed.

Next, referring to FIG. 13S, the wafer 120 is thinned until the wafer 120 reaches a predetermined thickness. This step includes a grinding method and/or an etching method with respect to the second wafer main surface 122. The grinding method may be a mechanical polishing method and/or a chemical-mechanical polishing method. The etching method may be the dry etching method and/or the wet etching method. The thinning step of the wafer 120 is not necessarily required to be performed, and may be excluded.

Next, referring to FIG. 13T, the n-type buffer region 13, the p-type collector region 14, and the n-type cathode region 45 are formed at a surficial portion of the second wafer main surface 122. The order of the steps of forming these impurity regions is arbitrary. The buffer region 13 may be formed by injecting an n-type impurity into the whole area of the surficial portion of the second wafer main surface 122. The collector region 14 may be formed by injecting a p-type impurity into the whole area of the surficial portion of the second wafer main surface 122. The cathode region 45 may be formed by injecting an n-type impurity into the surficial portion of the second wafer main surface 122 via a resist mask (not shown) having a predetermined pattern.

Next, referring to FIG. 13U, the collector main surface electrode 110 is formed on the second wafer main surface 122. The collector main surface electrode 110 may be formed by the sputtering method and/or the vapor deposition method. Next, the wafer 120 is cut in the thickness direction, and a plurality of semiconductor devices 1 are cut out. The semiconductor device 1 is manufactured through these steps mentioned above.

As described above, the manufacturing method of the semiconductor device 1 includes the preparation step of preparing the wafer 120, the formation step of forming the interlayer insulating film 73, the embedding step of embedding the first plug electrode 80, the formation step of forming the first base electrode film 131, and the exposure step of exposing the first base electrode film 131. In the preparation step of the wafer 120, the wafer 120 having the first wafer main surface 121 is prepared. In the formation step of the interlayer insulating film 73, the interlayer insulating film 73 covering the first wafer main surface 121 is formed.

In the embedding step of the first plug electrode 80, the first plug electrode 80 is embedded in the interlayer insulating film 73 so as to be partially exposed from the interlayer insulating film 73. In the formation step of the first base electrode film 131, the first base electrode film 131 covering at least the first plug electrode 80 is formed. The exposure step of the first base electrode film 131 is performed subsequent to the formation step of the first base electrode film 131. In this step, the first base electrode film 131 is exposed to an oxygen atmosphere.

In a case in which an oxide is formed in the first plug electrode 80, a resistance component caused by this oxide is added to resistance components of the first plug electrode 80. Particularly, the first plug electrode 80 is formed with a comparatively small plane area, and therefore the resistance component caused by the oxide becomes large. In this respect, the first base electrode film 131 that conceals the first plug electrode 80 is enabled to prevent the first plug electrode 80 from coming into contact with external air. This makes it possible to prevent the first plug electrode 80 from being oxidized in the exposure step of the first base electrode film 131. Therefore, it is possible to manufacture the semiconductor device 1 capable of improving electrical properties.

Specifically, the manufacturing method for the semiconductor device 1 includes the preparation step of preparing the wafer 120, the formation step of forming the IGBT region 8, the formation step of forming the diode region 9, the formation step of forming the interlayer insulating film 73, the embedding step of embedding the first plug electrode 80, the formation step of forming the first base electrode film 131, the formation step of forming the resist mask 132, the removal step of removing the first base electrode film 131, the removal step of removing the interlayer insulating film 73, the removal step of removing the resist mask 132, and the formation step of forming the second base electrode film 133.

In the preparation step of the wafer 120, the wafer 120 having the first wafer main surface 121 is prepared. In the formation step of the IGBT region 8, the IGBT region 8 is formed at the first wafer main surface 121. In the formation step of the diode region 9, the diode region 9 is formed at the first wafer main surface 121. In the formation step of the interlayer insulating film 73, the interlayer insulating film 73 covering both the IGBT region 8 and the diode region 9 is formed. In the embedding step of the first plug electrode 80, the first plug electrode 80 is embedded in a part, which covers the IGBT region 8, of the interlayer insulating film 73 so as to be partially exposed from the interlayer insulating film 73.

In the formation step of the first base electrode film 131, the first base electrode film 131 covering the interlayer insulating film 73 is formed so as to conceal the first plug electrode 80. In the formation step of the resist mask 132, the resist mask 132 having a layout that exposes a part, which overlaps with the diode region 9, of the first base electrode film 131 is formed on the first base electrode film 131. In the removal step of the first base electrode film 131, an unnecessary part of the part, which overlaps with the diode region 9, of the first base electrode film 131 is removed by the etching method through the resist mask 132.

In the removal step of the interlayer insulating film 73, a part, which is exposed from the first base electrode film 131, of the interlayer insulating film 73 is removed by the etching method subsequent to the removal step of the first base electrode film 131. In the removal step of removing the resist mask 132, the resist mask 132 is removed by the oxygen ashing method subsequent to the removal step of the first base electrode film 131 or subsequent to the removal step of the interlayer insulating film 73. In the formation step of the second base electrode film 133, the second base electrode film 133 covering both the first base electrode film 131 and the diode region 9 is formed.

In a case in which an oxide is formed in the first plug electrode 80, a resistance component caused by this oxide is added to resistance components of the first plug electrode 80. Particularly, the first plug electrode 80 is formed with a comparatively small plane area, and therefore the resistance component caused by the oxide becomes large. In this respect, the first emitter electrode film 91 that conceals the first plug electrode 80 is enabled to prevent the first plug electrode 80 from coming into contact with external air. This makes it possible to prevent the first plug electrode 80 from being oxidized caused by the oxygen ashing method according to the removal step of the resist mask 132.

Also, the first emitter electrode film 91 that exposes the diode region 9 makes it possible to restrain an unexpected ohmic decrease caused by the first emitter electrode film 91 between the diode region 9 and the second emitter electrode film 92. This makes it possible to improve the properties of the forward voltage VF of the diode region 9. Therefore, it is possible to manufacture the semiconductor device 1 capable of improving electrical properties.

Preferably, the removal step of the first base electrode film 131 includes a step of forming the first base electrode film 131 that does not cover the diode region 9. Preferably, the formation step of the diode region 9 includes a step of forming the anode region 46 at the surficial portion of the first wafer main surface 121. Preferably, the formation step of the resist mask 132 includes a step of forming the resist mask 132 having a layout that exposes a part, which overlaps with the anode region 46, of the first base electrode film 131.

Preferably, the removal step of the first base electrode film 131 includes a step of removing the part, which overlaps with the anode region 46, of the first base electrode film 131. Preferably, the removal step of the interlayer insulating film 73 includes a step of removing an unnecessary part of the interlayer insulating film 73 until the anode region 46 is exposed. Preferably, the formation step of the second base electrode film 133 includes a step of forming the second base electrode film 133 covering the anode region 46.

Preferably, the formation step of the diode region 9 includes a step of forming the third trench electrode structure 50 at the first wafer main surface 121. Preferably, the removal step of the first base electrode film 131 includes a step of removing a part, which overlaps with the third trench electrode structure 50, of the first base electrode film 131. Preferably, the removal step of the interlayer insulating film 73 includes a step of removing the unnecessary part of the interlayer insulating film 73 until the third trench electrode structure 50 is exposed. Preferably, the formation step of the second base electrode film 133 includes a step of forming the second base electrode film 133 covering the third trench electrode structure 50.

Preferably, the formation step of the diode region 9 includes a step of forming the plurality of third trench electrode structures 50. Preferably, the removal step of the first base electrode film 131 includes a step of removing parts, which overlap with the plurality of third trench electrode structures 50, of the first base electrode film 131. Preferably, the formation step of the second base electrode film 133 includes a step of forming the second base electrode film 133 covering the plurality of third trench electrode structures 50.

Preferably, the formation step of the first base electrode film 131 includes a step of forming the first base electrode film 131 that directly covers the first plug electrode 80. Preferably, the formation step of the second base electrode film 133 includes a step of forming the second base electrode film 133 that directly covers the first base electrode film 131 and the diode region 9. In other words, preferably, the second emitter electrode film 92 is directly connected to the diode region 9 without a barrier metal film (for example, Ti film).

According to this manufacturing method, it is possible to restrain an unexpected ohmic decrease caused by the barrier metal film between the diode region 9 and the second emitter electrode film 92. This makes it possible to improve the properties of the forward voltage VF of the diode region 9. Preferably, the formation step of the second base electrode film 133 includes a step of forming the second base electrode film 133 covering the first plug electrode 80 through the first base electrode film 131.

Preferably, the removal step of the interlayer insulating film 73 includes a step of forming the interlayer insulating film 73 having the opening wall surface 79 that defines an opening that exposes the diode region 9. Preferably, the removal step of the first base electrode film 131 includes a step of forming the first base electrode film 131 that exposes the opening wall surface 79. Preferably, the formation step of the second base electrode film 133 includes a step of forming the second base electrode film 133 covering the opening wall surface 79.

Preferably, the opening wall surface 79 makes an acute angle with the first wafer main surface 121. Preferably, the inclination angle of the opening wall surface 79 is more than 45° and less than 90°. This manufacturing method enables the second base electrode film 133 to face the first wafer main surface 121 across an inclined portion (opening wall surface 79) of the comparatively thick interlayer insulating film 73. This makes it possible to restrain electric field concentration in the vicinity of the inclined portion of the interlayer insulating film 73.

Preferably, the formation step of the first base electrode film 131 includes a step of forming the first base electrode film 131 thinner than the interlayer insulating film 73. Preferably, the formation step of the second base electrode film 133 includes a step of forming the second base electrode film 133 thicker than the first base electrode film 131. Preferably, the first base electrode film 131 has a single layer structure. Preferably, the second base electrode film 133 has a single layer structure.

Preferably, the first plug electrode 80 includes tungsten. Preferably, the first base electrode film 131 includes at least one among aluminum, an aluminum alloy, copper, a copper alloy, tungsten, molybdenum, titanium, titanium nitride, nickel. Preferably, the second base electrode film 133 includes at least one among aluminum, aluminum alloy, copper, and copper alloy. Preferably, the second base electrode film 133 includes a conductive material differing from that of the first base electrode film 131.

Preferably, the formation step of the IGBT region 8 includes a step of forming the first trench electrode structure 20 (gate trench structure) at the first wafer main surface 121, a step of forming the p-type base region 15 in a region along the first trench electrode structure 20 in the surficial portion of the first wafer main surface 121, and a step of forming the n-type emitter region 40 in a region along the first trench electrode structure 20 in the surficial portion of the base region 15. In this case, preferably, the formation step of the first plug electrode 80 includes a step of forming the first plug electrode 80 that is electrically connected to the emitter region 40.

Preferably, the formation step of the IGBT region 8 includes a step of forming the contact hole 42 that exposes the emitter region 40 to the first wafer main surface 121 and a step of forming the p-type contact region 43 in a region along the contact hole 42 within the base region 15. In this case, preferably, the formation step of the first plug electrode 80 includes a step of forming the first plug electrode 80 that is electrically connected to the emitter region 40 and to the contact region 43 within the contact hole 42. Preferably, the formation step of the IGBT region 8 includes a step of forming the n-type CS region 41 in a region directly below the base region 15.

Preferably, the plurality of IGBT regions 8 are formed. Preferably, the plurality of diode regions 9 are formed. Preferably, the formation step of the first plug electrode 80 includes a step of forming the plurality of first plug electrodes 80 that are electrically connected to the plurality of IGBT regions 8. Preferably, the removal step of the first base electrode film 131 includes a step of forming the first base electrode film 131 that covers the plurality of first plug electrodes 80 so as to expose the plurality of diode regions 9. Preferably, the formation step of the second base electrode film 133 includes a step of forming the second base electrode film 133 that covers the plurality of diode regions 9 and the first base electrode film 131.

In another respect, the manufacturing method for the semiconductor device 1 includes the preparation step of the wafer 120, the formation step of the IGBT region 8, the formation step of the diode region 9, the formation step of the interlayer insulating film 73, the formation step of a mask, the formation step of the life time killer region 85, and the removal step of the interlayer insulating film 73. In the preparation step of the wafer 120, the wafer 120 having the first wafer main surface 121 is prepared. In the formation step of the IGBT region 8, the IGBT region 8 is formed at the first wafer main surface 121. In the formation step of the diode region 9, the diode region 9 is formed at the first wafer main surface 121.

In the formation step of the interlayer insulating film 73, the interlayer insulating film 73 that covers both the IGBT region 8 and the diode region 9 is formed. In the formation step of the mask, the mask having a layout that exposes a part, which covers the diode region 9, of the interlayer insulating film 73 is formed on the interlayer insulating film 73. In the formation step of the life time killer region 85, the life time killer region 85 is formed inside the wafer 120 by use of the mask. In the removal step of the interlayer insulating film 73, the part, which covers the diode region 9, of the interlayer insulating film 73 is removed by the etching method using the mask.

According to this manufacturing method, the life time killer region 85 is formed in a self-aligned manner with respect to the mask, and therefore the alignment accuracy of the life time killer region 85 with respect to the diode region 9 is improved. This makes it possible to appropriately form the life time killer region 85 in the diode region 9, thus making it possible to reduce the loss of the diode region 9 during a reverse recovery operation by the regulating effect of a carrier lifetime.

Also, according to this manufacturing method, the removed part of the interlayer insulating film 73 is formed in a self-aligned manner with respect to the mask, and therefore the alignment accuracy of the removed part of the interlayer insulating film 73 with respect to the diode region 9 (life time killer region 85) is also improved. Therefore, it is possible to restrain a change in electrical properties caused by a positional deviation of the removed part. Therefore, it is possible to manufacture the semiconductor device 1 capable of improving electrical properties.

Preferably, the formation step of the life time killer region 85 includes a step of irradiating elements other than a trivalent element and a quinquevalent element into the wafer 120. Preferably, the formation step of the life time killer region 85 includes a step of irradiating either one or both of a hydrogen ion and a helium ion into the wafer 120.

Preferably, the formation step of the mask includes a formation step of the first base electrode film 131 as a first mask, a formation step of the resist mask 132 as a second mask, and a removal step of the first base electrode film 131. In the formation step of the first base electrode film 131, the first base electrode film 131 is formed on the interlayer insulating film 73. In the formation step of the resist mask 132, the resist mask 132 having a layout that exposes a part, which overlaps with the diode region 9, of the first base electrode film 131 is formed on the first base electrode film 131.

In the removal step of the first base electrode film 131, the part, which overlaps with the diode region 9, of the first base electrode film 131 is removed by the etching method using the resist mask 132. In this case, preferably, the formation step of the life time killer region 85 includes a step of forming the life time killer region 85 inside the wafer 120 by use of the resist mask 132.

According to this manufacturing method, the life time killer region 85 is formed in a self-aligned manner with respect to the resist mask 132 (removed part of the first base electrode film 131). Therefore, it is possible to improve the alignment accuracy of the life time killer region 85 with respect to the diode region 9 by means of the resist mask 132 (removed part of the first base electrode film 131). Also, the first base electrode film 131 is present, and therefore it is also possible to reduce the film thickness of the resist mask 132 and to reduce costs of the resist mask 132.

Preferably, the manufacturing method for the semiconductor device 1 includes a removal step of, subsequent to the formation step of the life time killer region 85, removing the resist mask 132 so as to leave the first base electrode film 131. In this case, preferably, the removal step of the interlayer insulating film 73 includes a removal step of, subsequent to the removal step of the resist mask 132, removing a part, which covers the diode region 9, of the interlayer insulating film 73 by the etching method using the first base electrode film 131. Preferably, the removal step of the resist mask 132 includes a step of removing the resist mask 132 by the oxygen ashing method.

Preferably, the manufacturing method for the semiconductor device 1 includes a step of, subsequent to the removal step of the interlayer insulating film 73, forming the second base electrode film 133 covering the first base electrode film 131. According to this manufacturing method, elements (impurities) etc., which are introduced when the formation step of the life time killer region 85 is performed, are not trapped by the second base electrode film 133. In other words, it is possible to form the second base electrode film 133 (emitter main surface electrode 90 and gate main surface electrode 100) that does not include the elements (impurities) included in the life time killer region 85.

This makes it possible to appropriately form the life time killer region 85, and, simultaneously, makes it possible to appropriately form the second base electrode film 133. Also, it is possible to arrange a part of the second base electrode film 133 within the removed part of the interlayer insulating film 73 having a high alignment accuracy. This makes it possible to electrically connect the second base electrode film 133 to the diode region 9 in an appropriate manner.

Preferably, the removal step of the interlayer insulating film 73 includes a step of forming the interlayer insulating film 73 having the opening wall surface 79 that defines the diode opening 77 that exposes the diode region 9. Preferably, the removal step of the first base electrode film 131 includes a step of forming the first base electrode film 131 that exposes the opening wall surface 79. Preferably, the formation step of the second base electrode film 133 includes a step of forming the second base electrode film 133 covering the opening wall surface 79.

Preferably, the opening wall surface 79 makes an acute angle with the first wafer main surface 121. Preferably, the inclination angle of the opening wall surface 79 is more than 45° and less than 90°. This manufacturing method enables the second base electrode film 133 to face the first wafer main surface 121 across an inclined portion (opening wall surface 79) of the comparatively thick interlayer insulating film 73. This makes it possible to restrain electric field concentration in the vicinity of the inclined portion of the interlayer insulating film 73.

Preferably, the formation step of the first base electrode film 131 includes a step of forming the first base electrode film 131 thinner than the interlayer insulating film 73, and the formation step of the second base electrode film 133 includes a step of forming the second base electrode film 133 thicker than the first base electrode film 131. Preferably, the second base electrode film 133 includes a conductive material differing from that of the first base electrode film 131. Preferably, the first base electrode film 131 has a single layer structure. Preferably, the second base electrode film 133 has a single layer structure.

Preferably, the removal step of the first base electrode film 131 includes a step of forming the first base electrode film 131 that does not cover the diode region 9. Preferably, the formation step of the diode region 9 includes a step of forming the anode region 46 at the surficial portion of the first wafer main surface 121. Preferably, the formation step of the resist mask 132 includes a step of forming the resist mask 132 having a layout that exposes a part, which overlaps with the anode region 46, of the first base electrode film 131. Preferably, the removal step of the first base electrode film 131 includes a step of removing the part, which overlaps with the anode region 46, of the first base electrode film 131.

Preferably, the formation step of the diode region 9 includes a step of forming the third trench electrode structure 50 at the first wafer main surface 121. Preferably, the removal step of the first base electrode film 131 includes a step of removing a part, which overlaps with the third trench electrode structure 50, of the first base electrode film 131. Preferably, the plurality of third trench electrode structures 50 are formed, and the part, which overlaps with the plurality of third trench electrode structures 50, of the first base electrode film 131 is removed.

Preferably, the manufacturing method for the semiconductor device 1 includes a step of, prior to the formation step of the first base electrode film 131, embedding the first plug electrode 80 in a part, which covers the IGBT region 8, of the interlayer insulating film 73 so as to be partially exposed from the interlayer insulating film 73. In this case, preferably, the formation step of the first base electrode film 131 includes a step of forming the first base electrode film 131 covering the first plug electrode 80.

In a case in which an oxide is formed in the first plug electrode 80, a resistance component caused by this oxide is added to resistance components of the first plug electrode 80. Particularly, the first plug electrode 80 is formed with a comparatively small plane area, and therefore the resistance component caused by the oxide becomes large. In this respect, the first base electrode film 131 that conceals the first plug electrode 80 is enabled to prevent the first plug electrode 80 from coming into contact with external air after the formation step of the first base electrode film 131. This makes it possible to prevent the first plug electrode 80 from being oxidized. Therefore, it is possible to manufacture the semiconductor device 1 capable of improving electrical properties. Preferably, the first plug electrode 80 includes tungsten.

Preferably, the formation step of the IGBT region 8 includes a step of forming the first trench electrode structure 20 (gate trench structure) at the first wafer main surface 121, a step of forming the p-type base region 15 in a region along the first trench electrode structure 20 in the surficial portion of the first wafer main surface 121, and a step of forming the n-type emitter region 40 in a region along the first trench electrode structure 20 in the surficial portion of the base region 15. In this case, preferably, the formation step of the first plug electrode 80 includes a step of forming the first plug electrode 80 that is electrically connected to the emitter region 40.

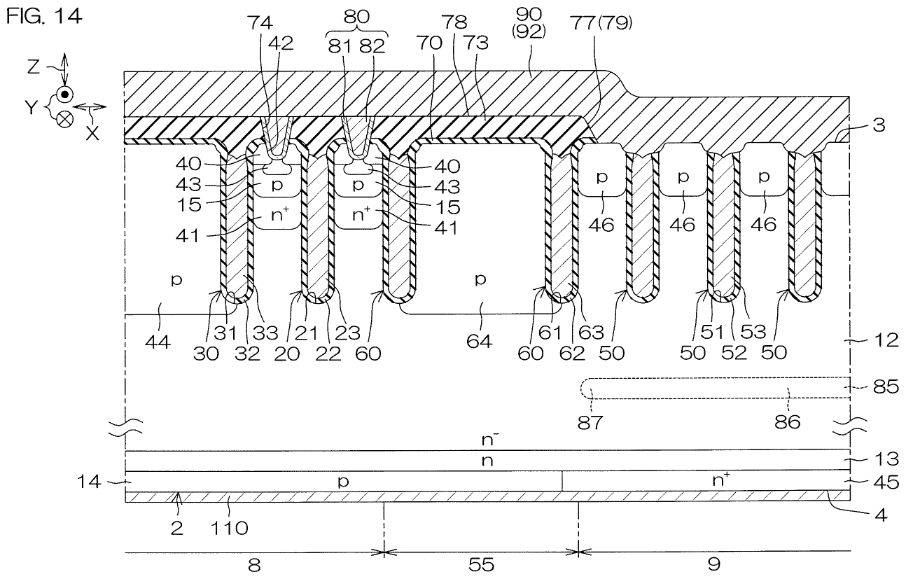

Modifications of the semiconductor device 1 are hereinafter shown. FIG. 14 is a cross sectional view showing a semiconductor device 1 according to a first modification. The aforementioned semiconductor device 1 includes the emitter main surface electrode 90 having the first emitter electrode film 91 and the second emitter electrode film 92. On the other hand, the emitter main surface electrode 90 of the semiconductor device 1 according to the first modification does not have the first emitter electrode film 91, and has a single layer structure consisting of the second emitter electrode film 92.

Likewise, the gate main surface electrode 100 of the semiconductor device 1 according to the first modification does not have the first gate electrode film 101, and has a single layer structure consisting of the second gate electrode film 102. In the manufacturing method for the semiconductor device 1 according to the first modification, the formation step of the first base electrode film 131 (first emitter electrode film 91 and first gate electrode film 101) is excluded (see FIG. 13M). The life time killer region 85 and the diode opening 77 are formed by use of the resist mask 132.

With the semiconductor device 1 according to the first modification, the same effect as the effect described with respect to the semiconductor device 1 according to the embodiment is fulfilled except the effect according to the first base electrode film 131 (first emitter electrode film 91 and first gate electrode film 101) as described above.

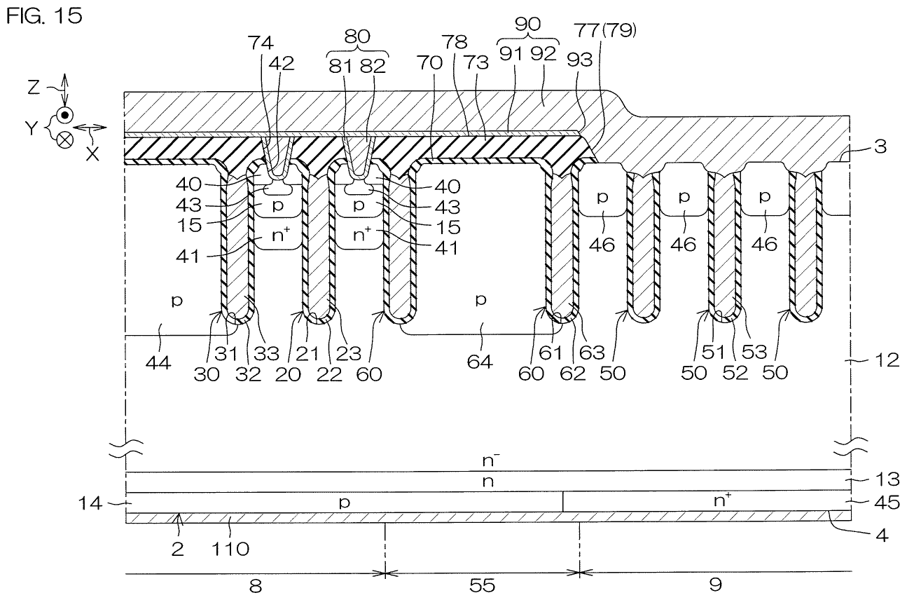

FIG. 15 is a cross sectional view showing a semiconductor device 1 according to a second modification. The aforementioned semiconductor device 1 has the life time killer region 85 as described above. On the other hand, the semiconductor device 1 according to the second modification does not have the life time killer region 85. In the manufacturing method for the semiconductor device 1 according to the second modification, the formation step of the life time killer region 85 is excluded (see FIG. 13O), and the removal step of the resist mask 132 (see FIG. 13P) is performed subsequent to the formation step of the resist mask 132 (see FIG. 13N).

With the semiconductor device 1 according to the second modification, the same effect as the effect described with respect to the semiconductor device 1 according to the embodiment is fulfilled except the effect according to the life time killer region 85 as described above.

The aforementioned embodiment can be carried out in still other modes. For example, the plurality of CS regions 41 are formed as described in the aforementioned embodiment. However, the presence or absence of the CS region 41 is arbitrary, and a form that does not have the CS region 41 may be employed.

An IE structure (i.e., the second trench electrode structure 30, the second trench connection structure 34, and the well region 44) is formed in a region between the pair of first trench electrode structures 20 as described in the aforementioned embodiment. However, the presence or absence of the IE structure is arbitrary, and a form that does not have the IE structure may be employed. In this case, the plurality of first trench electrode structures 20 are arranged at a distance from each other in the first direction X so as to adjoin each other.

A boundary IE structure (i.e., the third trench connection structure 54, the fourth trench electrode structure 60, and the boundary well region 64) is formed in the boundary region 55 between the IGBT region 8 and the diode region 9 as described in the aforementioned embodiment. However, the presence or absence of the boundary IE structure is arbitrary, and a form that does not have the boundary IE structure may be employed. In this case, the third trench electrode structure 50 may adjoin the first trench electrode structure 20 in the first direction X. As a matter of course, the third trench electrode structure 50 may adjoin the second trench electrode structure 30 in the first direction X.

The single diode opening 77 is formed with respect to the single diode region 9 as described in the aforementioned embodiment. However, the plurality of diode openings 77 may be formed with respect to the single diode region 9. In this case, the plurality of diode openings 77 may respectively expose parts of the plurality of third trench electrode structures 50 in each of the diode regions 9. Preferably, the plurality of diode openings 77 expose all of the third trench electrode structures 50 in each of the diode regions 9 as a whole.

The anode region 46 that is shallower than the plurality of third trench electrode structures 50 is formed as described in the aforementioned embodiment. However, the anode region 46 that is deeper than the plurality of third trench electrode structures 50 may be formed. In this case, the anode region 46 may have a part (bottom portion) that covers the bottom wall of the plurality of third trench electrode structures 50.

The chip 2 is made of a silicon single crystal substrate as described in the aforementioned embodiment. However, the chip 2 may be made of an SiC (silicon carbide) single crystal substrate. In the aforementioned embodiment, the n-type semiconductor region may be replaced by a p-type semiconductor region, and the p-type semiconductor region may be replaced by an n-type semiconductor region. A specific configuration in this case can be obtained by replacing the “n-type” with the “p-type” and, simultaneously, by replacing the “p-type” with the “n-type” in the foregoing description and in the accompanying drawings.

The first and second directions X and Y are defined by the extending directions of the first to fourth side surfaces 5A to 5D as described in the aforementioned embodiment. However, the first and second directions X and Y may be arbitrary directions as long as the relationship of intersecting each other (specifically, perpendicularly intersecting each other) is maintained. For example, the first direction X may be a direction intersecting the first to fourth side surfaces 5A to 5D, and the second direction Y may be a direction intersecting the first to fourth side surfaces 5A to 5D.

Characteristic examples extracted from this description and from the drawings are hereinafter shown. Hereinafter, alphanumeric characters etc., in parentheses represent corresponding components in the aforementioned embodiment, and yet this representation does not denote that the scope of each clause is limited to the embodiment. The “semiconductor device” according to the following clauses may be replaced by a “semiconductor switching device” or an “RC-IGBT semiconductor device.”

[A1] A semiconductor device (1) comprising: a chip (2) having a main surface (3); an IGBT region (8) formed at the main surface (3); a diode region (9) formed at the main surface (3); an insulating film (73) formed on the main surface (3) so as to expose the diode region (9) and so as to cover the IGBT region (8); a plug electrode (80, 83, 84) embedded in a part, which covers the IGBT region (8), of the insulating film (73) so as to be partially exposed from the insulating film (73); and a main surface electrode (90) that includes a first electrode film (91) covering the plug electrode (80, 83, 84) so as to expose the diode region (9) and a second electrode film (92) covering the first electrode film (91) and the diode region (9).

[A2] The semiconductor device (1) according to A1, wherein the first electrode film (91) does not cover the diode region (9).

[A3] The semiconductor device (1) according to A1 or A2, wherein the diode region (9) includes an anode region (46) formed at a surficial portion of the main surface (3), the first electrode film (91) exposes the anode region (46), and the second electrode film (92) covers the anode region (46).

[A4] The semiconductor device (1) according to any one of A1 to A3, wherein the diode region (9) includes a trench electrode structure (50) formed at the main surface (3), the first electrode film (91) exposes the trench electrode structure (50), and the second electrode film (92) covers the trench electrode structure (50).

[A5] The semiconductor device (1) according to A4, wherein the trench electrode structures (50) are formed at the main surface (3), the first electrode film (91) exposes the trench electrode structures (50), and the second electrode film (92) covers the trench electrode structures (50).

[A6] The semiconductor device (1) according to any one of A1 to A5, wherein the first electrode film (91) directly covers the plug electrode (80, 83, 84), and the second electrode film (92) directly covers the first electrode film (91) and the diode region (9).

[A7] The semiconductor device (1) according to any one of A1 to A6, wherein the second electrode film (92) has a part that faces the plug electrode (80, 83, 84) across the first electrode film (91).

[A8] The semiconductor device (1) according to any one of A1 to A7, wherein the insulating film (73) has an opening wall surface (79) that defines an opening (77) that exposes the diode region (9), the first electrode film (91) exposes the opening wall surface (79), and the second electrode film (92) covers the opening wall surface (79).

[A9] The semiconductor device (1) according to A8, wherein the opening wall surface (79) is inclined so as to make an acute angle with the main surfaces (3).

[A10] The semiconductor device (1) according to any one of A1 to A9, wherein the first electrode film (91) is thinner than the insulating film (73), and the second electrode film (92) is thicker than the first electrode film (91).

[A11] The semiconductor device (1) according to any one of A1 to A10, wherein the plug electrode (80, 83, 84) includes tungsten.

[A12] The semiconductor device (1) according to any one of A1 to A11, wherein the first electrode film (91) includes at least one among aluminum, aluminum alloy, copper, copper alloy, tungsten, molybdenum, titanium, titanium nitride, and nickel.

[A13] The semiconductor device (1) according to any one of A1 to A12, wherein the second electrode film (92) includes at least one among aluminum, aluminum alloy, copper, and copper alloy.

[A14] The semiconductor device (1) according to any one of A1 to A13, wherein the second electrode film (92) includes a conductive material differing from that of the first electrode film (91).

[A15] The semiconductor device (1) according to any one of A1 to A14, wherein the first electrode film (91) has a single layer structure.

[A16] The semiconductor device (1) according to any one of A1 to A15, wherein the second electrode film (92) has a single layer structure.

[A17] The semiconductor device (1) according to any one of A1 to A16, wherein the IGBT region (8) includes: a first conductivity type (p-type) base region (15) formed at the surficial portion of the main surface (3); a gate trench structure (20) formed at the main surface (3) so as to pass through the base region (15); and a second conductivity type (n-type) emitter region (40) formed in a region along the gate trench structure (20) in a surficial portion of the base region (15); and wherein the plug electrode (80) is electrically connected to the emitter region (40).

[A18] The semiconductor device (1) according to A17, wherein the IGBT region (8) includes: a contact hole (42) formed in the main surface (3) so as to expose the emitter region (40); and a first conductivity type (p-type) contact region (43) formed in a region along the contact hole (42) in the base region (15); and wherein the plug electrode (80) is electrically connected to the emitter region (40) and to the contact region (43) in the contact hole (42).

[A19] The semiconductor device (1) according to A17 or A18, wherein the IGBT region (8) further includes: a second conductivity type (n-type) carrier storage region (41) formed in a region directly below the base region (15) in the chip (2).

[A20] The semiconductor device (1) according to any one of A1 to A19, wherein the IGBT regions (8) are formed at the main surface (3), the diode regions (9) are formed at the main surface (3), the plug electrodes (80, 83, 84) are electrically connected to the IGBT regions (8), the first electrode film (91) covers the plug electrodes (80, 83, 84) so as to expose the diode regions (9), and the second electrode film (92) covers the first electrode film (91) and the diode regions (9).

[B1] A manufacturing method for a semiconductor device (1), comprising: a step of preparing a wafer (120) having a main surface (121); a formation step of forming an IGBT region (8) and a diode region (9) at the main surface (121); a formation step of forming an insulating film (73) covering both the IGBT region (8) and the diode region (9); a step of embedding a plug electrode (80, 83, 84) in a part, which covers the IGBT region (8), of the insulating film (73) so as to be partially exposed from the insulating film (73); a formation step of forming a first electrode film (91, 131) covering the insulating film (73) so as to conceal the plug electrode (80, 83, 84); a formation step of forming a resist mask (132) having a layout that exposes a part, which overlaps with the diode region (9), of the first electrode film (91, 131) on the first electrode film (91, 131); a removal step of removing the part, which overlaps with the diode region (9), of the first electrode film (91, 131) by an etching method through the resist mask (132); a removal step of removing a part, which is exposed from the first electrode film (91, 131), of the insulating film (73) by the etching method, subsequent to the removal step of the first electrode film (91, 131); a removal step of removing the resist mask (132) by an oxygen ashing method, subsequent to the removal step of the first electrode film (91, 131) or subsequent to the removal step of the insulating film (73); and a formation step of forming a second electrode film (92, 133) covering the first electrode film (91, 131) and the diode region (9).

[B2] The manufacturing method for the semiconductor device (1) according to B1, wherein the removal step of the first electrode film (91, 131) includes a step of forming the first electrode film (91, 131) that does not cover the diode region (9).

[B3] The manufacturing method for the semiconductor device (1) according to B1 or B2, wherein the formation step of the diode region (9) includes a step of forming an anode region (46) at a surficial portion of the main surface (121), the formation step of the resist mask (132) includes a step of forming the resist mask (132) having a layout that exposes a part, which overlaps with the anode region (46), of the first electrode film (91, 131), the removal step of the first electrode film (91, 131) includes a step of removing the part, which overlaps with the anode region (46), of the first electrode film (91, 131), the removal step of the insulating film (73) includes a step of removing a part, which covers the anode region (46), of the insulating film (73), and the formation step of the second electrode film (92, 133) includes a step of forming the second electrode film (92, 133) covering the anode region (46).

[B4] The manufacturing method for the semiconductor device (1) according to any one of B1 to B3, wherein the formation step of the diode region (9) includes a step of forming a trench electrode structure (50) at the main surface (121), the removal step of the first electrode film (91, 131) includes a step of removing a part, which overlaps with the trench electrode structure (50), of the first electrode film (91, 131), the removal step of the insulating film (73) includes a step of removing a part, which covers the trench electrode structure (50), of the insulating film (73), and the formation step of the second electrode film (92, 133) includes a step of forming the second electrode film (92, 133) covering the trench electrode structure (50).

[B5] The manufacturing method for the semiconductor device (1) according to B4, wherein the formation step of the diode region (9) includes a step of forming the trench electrode structures (50), the removal step of the first electrode film (91, 131) includes a step of removing a part, which overlaps with the plurality of trench electrode structures (50), of the first electrode film (91, 131), the removal step of the insulating film (73) includes a step of removing a part, which covers the trench electrode structures (50), of the insulating film (73), and the formation step of the second electrode film (92, 133) includes a step of forming the second electrode film (92, 133) covering the trench electrode structures (50).

[B6] The manufacturing method for the semiconductor device (1) according to any one of B1 to B5, wherein the formation step of the first electrode film (91, 131) includes a step of forming the first electrode film (91, 131) that directly covers the plug electrode (80, 83, 84), and the formation step of the second electrode film (92, 133) includes a step of forming the second electrode film (92, 133) that directly covers the first electrode film (91, 131) and the diode region (9).

[B7] The manufacturing method for the semiconductor device (1) according to any one of B1 to B6, wherein the formation step of the second electrode film (92, 133) includes a step of forming the second electrode film (92, 133) having a part that faces the plug electrode (80, 83, 84) across the first electrode film (91, 131).

[B8] The manufacturing method for the semiconductor device (1) according to any one of B1 to B7, wherein the removal step of the insulating film (73) includes a step of forming the insulating film (73) having an opening wall surface (79) that defines an opening (77) that exposes the diode region (9), the removal step of the first electrode film (91, 131) includes a step of forming the first electrode film (91, 131) that exposes the opening wall surface (79), and the formation step of the second electrode film (92, 133) includes a step of forming the second electrode film (92, 133) covering the opening wall surface (79).

[B9] The manufacturing method for the semiconductor device (1) according to B8, wherein the opening wall surface (79) makes an acute angle with the main surface (121).

[B10] The manufacturing method for the semiconductor device (1) according to any one of B to B9, wherein the formation step of the first electrode film (91, 131) includes a step of forming the first electrode film (91, 131) thinner than the insulating film (73), and the formation step of the second electrode film (92, 133) includes a step of forming the second electrode film (92, 133) thicker than the first electrode film (91, 131).

[B11] The manufacturing method for the semiconductor device (1) according to any one of B1 to B10, wherein the plug electrode (80, 83, 84) includes tungsten.

[B12] The manufacturing method for the semiconductor device (1) according to any one of B1 to B11, wherein the first electrode film (91, 131) includes at least one among aluminum, aluminum alloy, copper, copper alloy, tungsten, molybdenum, titanium, titanium nitride, and nickel.

[B13] The manufacturing method for the semiconductor device (1) according to any one of B1 to B12, wherein the second electrode film (92, 133) includes at least one among aluminum, aluminum alloy, copper, and copper alloy.

[B14] The manufacturing method for the semiconductor device (1) according to any one of B1 to B13, wherein the second electrode film (92, 133) includes a conductive material differing from that of the first electrode film (91, 131).

[B15] The manufacturing method for the semiconductor device (1) according to any one of B1 to B14, wherein the first electrode film (91, 131) has a single layer structure.

[B16] The manufacturing method for the semiconductor device (1) according to any one of B1 to B15, wherein the second electrode film (92, 133) has a single layer structure.

[B17] The manufacturing method for the semiconductor device (1) according to any one of B1 to B16, wherein the formation step of the IGBT region (8) includes: a step of forming a gate trench structure (20) at the main surface (121); a step of forming a first conductivity type (p-type) base region (15) in a region along the gate trench structure (20) in the surficial portion of the main surface (121); and a step of forming a second conductivity type (n-type) emitter region (40) in a region along the gate trench structure (20) in the surficial portion of the main surface (121); and wherein the formation step of the plug electrode (80, 83, 84) includes a step of forming the plug electrode (80) that is electrically connected to the emitter region (40).

[B18] The manufacturing method for the semiconductor device (1) according to B17, wherein the formation step of the IGBT region (8) includes: a step of forming a contact hole (42) that exposes the emitter region (40) in the main surface (121); and a step of forming a first conductivity type (p-type) contact region (43) in a region along the contact hole (42) inside the base region (15); and wherein the formation step of the plug electrode (80, 83, 84) includes a step of forming the plug electrode (80) that is electrically connected to the emitter region (40) and to the contact region (43) in the contact hole (42).

[B19] The manufacturing method for the semiconductor device (1) according to B17 or B18, wherein the formation step of the IGBT region (8) includes a step of forming a second conductivity type (n-type) carrier storage region (41) in a region directly below the base region (15).

[B20] The manufacturing method for the semiconductor device (1) according to any one of B1 to B19, wherein the IGBT regions (8) are formed, the diode regions (9) are formed, the formation step of the plug electrode (80, 83, 84) includes a step of forming the plug electrodes (80, 83, 84) that are electrically connected to the IGBT regions (8), the removal step of the first electrode film (91, 131) includes a step of forming the first electrode film (91, 131) covering the plug electrodes (80, 83, 84) so as to expose the diode regions (9), and the formation step of the second electrode film (92, 133) includes a step of forming the second electrode film (92, 133) that covers the first electrode film (91, 131) and the diode regions (9).

[C1] A manufacturing method for a semiconductor device (1), comprising: a step of preparing a wafer (120) having a main surface (121); a step of forming an insulating film (73) covering the main surface (121); a step of embedding a plug electrode (80, 83, 84, 96) in the insulating film (73) so as to be partially exposed from the insulating film (73); a formation step of forming a first electrode film (91, 101, 131) covering at least the plug electrode (80, 83, 84, 96); and an exposure step of exposing the first electrode film (91, 101, 131) to an oxygen atmosphere, subsequent to the formation step of the first electrode film (91, 101, 131).

[C2] The manufacturing method for the semiconductor device (1) according to C1, further comprising: a step of forming a second electrode film (92, 102, 133) covering the first electrode film (91, 101, 131), subsequent to the exposure step.

[C3] The manufacturing method for the semiconductor device (1) according to C1 or C2, further comprising: a step of forming a resist mask (132) having a layout that partially exposes the first electrode film (91, 101, 131) on the first electrode film (91, 101, 131), prior to the exposure step; and a removal step of removing an unnecessary part of the first electrode film (91, 101, 131) by an etching method through the resist mask (132), prior to the exposure step; wherein the exposure step includes a step of removing the resist mask (132) by an oxygen ashing method, subsequent to the removal step of the first electrode film (91, 101, 131).

[D1] A semiconductor device (1) comprising: a chip (2) having a main surface (3); an IGBT region (8) formed at the main surface (3); a diode region (9) formed at the main surface (3); an insulating film (73) that is formed on the main surface (3) so as to cover the IGBT region (8) and that has an opening (77) exposing the diode region (9); and a life time killer region (85) formed inside the chip (2) in the diode region (9) so as to overlap with the opening (77) in a plan view.

[D2] The semiconductor device (1) according to D1, further comprising: a trench structure (50) formed at the main surface (3) in the diode region (9); wherein the opening (77) exposes the trench structure (50).

[D3] The semiconductor device (1) according to D2, wherein the trench structures (50) are formed at the main surface (3), and the opening (77) exposes the trench structures (50).

[D4] The semiconductor device (1) according to D2 or D3, wherein the opening (77) collectively exposes all of the trench structures (50) included in the diode region (9).

[D5] The semiconductor device (1) according to any one of D2 to D4, wherein the life time killer region (85) faces the trench structure (50) in a thickness direction of the chip (2).

[D6] The semiconductor device (1) according to any one of D1 to D5, wherein the openings (77) are not formed with respect to the single diode region (9).

[D7] The semiconductor device (1) according to any one of D1 to D6, wherein the life time killer region (85) has a facing region (86) that faces the insulating film (73) and a non-facing region (87) that does not face the insulating film (73) in regard to a thickness direction of the chip (2).

[D8] The semiconductor device (1) according to D7, wherein the life time killer region (85) has the non-facing region (87) in a peripheral edge portion.

[D9] The semiconductor device (1) according to D7 or D8, wherein the life time killer region (85) does not have the non-facing region (87) in an inward portion.

[D10] The semiconductor device (1) according to any one of D7 to D9, wherein a ratio of the non-facing region (87) in the life time killer region (85) exceeds a ratio of the facing region (86) in the life time killer region (85).

[D11] The semiconductor device (1) according to any one of D1 to D10, wherein the insulating film (73) has an opening wall surface (79) that defines the opening (77), and the life time killer region (85) has a part that faces the opening wall surface (79) in a thickness direction of the chip (2).

[D12] The semiconductor device (1) according to D11, wherein the opening wall surface (79) makes an acute angle with the main surfaces (3).

[D13] The semiconductor device (1) according to any one of D1 to D12, wherein the life time killer region (85) has a crystal defect formed by components other than a trivalent element and a quinquevalent element.

[D14] The semiconductor device (1) according to any one of D1 to D13, wherein the life time killer region (85) has a crystal defect formed by a helium ion.

[D15] The semiconductor device (1) according to any one of D1 to D14, wherein the diode regions (9) are formed at the main surface (3), the openings (77) are formed one by one with respect to the diode regions (9), and the life time killer regions (85) are formed one by one with respect to the diode regions (9).

[D16] The semiconductor device (1) according to any one of D1 to D15, further comprising: a plug electrode (80, 83, 84) embedded in a part, which covers the IGBT region (8), of the insulating film (73) so as to be partially exposed from the insulating film (73); and a main surface electrode (90) that includes a first electrode film (91) covering the plug electrode (80, 83, 84) so as to expose the diode region (9) and a second electrode film (92) covering the first electrode film (91) and the diode region (9).

[D17] The semiconductor device (1) according to D16, wherein the first electrode film (91) does not cover the diode region (9).

[D18] The semiconductor device (1) according to D16 or D17, wherein the first electrode film (91) is thinner than the insulating film (73), and the second electrode film (92) is thicker than the first electrode film (91).

[D19] The semiconductor device (1) according to any one of D16 to D18, wherein the second electrode film (92) includes a conductive material differing from that of the first electrode film (91).

[D20] The semiconductor device (1) according to any one of D16 to D19, wherein the first electrode film (91) has a single layer structure, and the second electrode film (92) has a single layer structure.

[E1] A manufacturing method for a semiconductor device (1) comprising: a step of preparing a wafer (120) having a main surface (121); a formation step of forming an IGBT region (8) and a diode region (9) at the main surface (121); a formation step of forming an insulating film (73) covering the IGBT region (8) and the diode region (9); a formation step of forming a mask (131, 132) having a layout that exposes a part, which covers the diode region (9), of the insulating film (73) on the insulating film (73); a formation step of forming a life time killer region (85) inside the wafer (120) by use of the mask (131, 132); and a removal step of removing the part, which covers the diode region (9), of the insulating film (73) by an etching method using the mask (131, 132).

[E2] The manufacturing method for the semiconductor device (1) according to E1, wherein the formation step of the life time killer region (85) includes a step of irradiating components other than a trivalent element and a quinquevalent element into the wafer (120).

[E3] The manufacturing method for the semiconductor device (1) according to E1 or E2, wherein the formation step of the life time killer region (85) includes a step of irradiating either one or both of a hydrogen ion and a helium ion into the wafer (120).

[E4] The manufacturing method for the semiconductor device (1) according to any one of E1 to E3, wherein the formation step of the mask (131, 132) includes: a formation step of forming a metallic first mask (131) covering the insulating film (73); a formation step of forming a resinous second mask (132) having a layout that exposes a part, which overlaps with the diode region (9), of the first mask (131) on the first mask (131); and a removal step of removing the part, which overlaps with the diode region (9), of the first mask (131) by an etching method using the second mask (132); and wherein the formation step of the life time killer region (85) includes a formation step of forming the life time killer region (85) inside the wafer (120) by use of the second mask (132).

[E5] The manufacturing method for the semiconductor device (1) according to E4, further comprising: a removal step of removing the second mask (132) so as to leave the first mask (131), subsequent to the formation step of the life time killer region (85); wherein the removal step of the insulating film (73) includes a removal step of removing the part, which covers the diode region (9), of the insulating film (73) by an etching method using the first mask (131), subsequent to the removal step of the second mask (132).

[E6] The manufacturing method for the semiconductor device (1) according to E5, wherein the removal step of the second mask (132) includes a removal step of removing the second mask (132) by an oxygen ashing method.

[E7] The manufacturing method for the semiconductor device (1) according to E5 or E6, further comprising: a step of forming the electrode film (92, 102, 133) covering the first mask subsequent to the removal step of the insulating film (73).

[E8] The manufacturing method for the semiconductor device (1) according to E7, wherein the removal step of the insulating film (73) includes a formation step of forming the insulating film (73) having an opening wall surface (79) that defines an opening (77) that exposes the diode region (9), the removal step of the first mask (131) includes a formation step of forming the first mask (131) that exposes the opening wall surface (79), and the formation step of the electrode film (92, 102, 133) includes a formation step of forming the electrode film (92, 102, 133) covering the opening wall surface (79).

[E9] The manufacturing method for the semiconductor device (1) according to E8, wherein the opening wall surface (79) makes an acute angle with the main surface (121).

[E10] The manufacturing method for the semiconductor device (1) according to any one of E7 to E9, wherein the formation step of the first mask (131) includes a formation step of forming the first mask (131) thinner than the insulating film (73), and the formation step of the electrode film (92, 102, 133) includes a formation step of forming the electrode film (92, 102, 133) thicker than the first mask (131).

[E11] The manufacturing method for the semiconductor device (1) according to any one of E7 to E10, wherein the electrode film (92, 102, 133) includes a conductive material differing from that of the first mask (131).

[E12] The manufacturing method for the semiconductor device (1) according to any one of E7 to E11, wherein the first mask (131) has a single layer structure.

[E13] The manufacturing method for the semiconductor device (1) according to any one of E7 to E12, wherein the electrode film (92, 102, 133) has a single layer structure.

[E14] The manufacturing method for the semiconductor device (1) according to any one of E4 to E13, wherein the removal step of the first mask (131) includes a formation step of forming the first mask (131) that does not cover the diode region (9).

[E15] The manufacturing method for the semiconductor device (1) according to any one of E4 to E14, wherein the formation step of the diode region (9) includes a formation step of forming an anode region (46) at a surficial portion of the main surface (121), the formation step of the second mask (132) includes a formation step of forming the second mask (132) having a layout that exposes a part, which overlaps with the anode region (46), of the first mask (131), and the removal step of the first mask (131) includes a removal step of removing the part, which overlaps with the anode region (46), of the first mask (131).

[E16] The manufacturing method for the semiconductor device (1) according to any one of E4 to E15, wherein the formation step of the diode region (9) includes a formation step of forming a trench electrode structure (50) at the main surface (121), and the removal step of the first mask (131) includes a removal step of removing a part, which overlaps with the trench electrode structure (50), of the first mask (131).

[E17] The method for the manufacturing semiconductor device (1) according to E16, wherein the trench electrode structures (50) are formed, and parts, which overlap with the trench electrode structures (50), of the first mask (131) are removed.

[E18] The manufacturing method for the semiconductor device (1) according to any one of E4 to E17, further comprising: a step of embedding a plug electrode (80, 83, 84) in a part, which covers the IGBT region (8), of the insulating film (73) so as to be partially exposed from the insulating film (73), prior to the formation step of the first mask (131); wherein the formation step of the first mask (131) includes a formation step of forming the first mask (131) covering the plug electrode (80, 83, 84).

[E19] The manufacturing method for the semiconductor device (1) according to E18, wherein the plug electrode (80, 83, 84) includes tungsten.

[E20] The manufacturing method for the semiconductor device (1) according to E18 or E19, wherein the formation step of the IGBT region (8) includes: a step of forming a gate trench structure (20) at the main surface (121); a step of forming a first conductivity type (p-type) base region (15) in a region along the gate trench structure (20) in the surficial portion of the main surface (121); and a step of forming a second conductivity type (n-type) emitter region (40) in a region along the gate trench structure (20) in the surficial portion of the main surface (121); and wherein the formation step of the plug electrode (80, 83, 84) includes a step of forming the plug electrode (80) that is electrically connected to the emitter region (40).

Although the embodiments have been described in detail as above, these are merely concrete examples used to clarify the technical contents of the present invention. Various technical thoughts extracted from this description can be appropriately combined together without being limited to the explanatory order in the description.

What is claimed is:

1. A semiconductor device comprising:
a chip having a main surface;
an IGBT region formed at the main surface;
a diode region formed at the main surface;
an insulating film formed on the main surface so as to expose the diode region and so as to cover the IGBT region;
a plug electrode embedded in a part, which covers the IGBT region, of the insulating film so as to be partially exposed from the insulating film; and
a main surface electrode that includes a first electrode film covering the plug electrode so as to expose the diode region and a second electrode film covering the first electrode film and the diode region.

2. The semiconductor device according to claim 1,
wherein the first electrode film does not cover the diode region.

3. The semiconductor device according to claim 1,
wherein the diode region includes an anode region formed at a surficial portion of the main surface, and
the first electrode film exposes the anode region, and
the second electrode film covers the anode region.

4. The semiconductor device according to claim 1,
wherein the diode region includes a trench electrode structure formed at the main surface,
the first electrode film exposes the trench electrode structure, and
the second electrode film covers the trench electrode structure.

5. The semiconductor device according to claim 4,
wherein the trench electrode structures are formed at the main surface, and
the first electrode film exposes the trench electrode structures, and
the second electrode film covers the trench electrode structures.

6. The semiconductor device according to claim 1,
wherein the first electrode film directly covers the plug electrode, and
the second electrode film directly covers the first electrode film and the diode region.

7. The semiconductor device according to claim 1,
wherein the second electrode film has a part that faces the plug electrode across the first electrode film.

8. The semiconductor device according to claim 1,
wherein the insulating film has an opening wall surface that defines an opening that exposes the diode region,
the first electrode film exposes the opening wall surface, and
the second electrode film covers the opening wall surface.

9. The semiconductor device according to claim 8,
wherein the opening wall surface makes an acute angle with the main surface.

10. The semiconductor device according to claim 1,
wherein the first electrode film is thinner than the insulating film, and
the second electrode film is thicker than the first electrode film.

11. The semiconductor device according to claim 1,
wherein the plug electrode includes tungsten.

12. The semiconductor device according to claim 1,
wherein the first electrode film includes at least one among aluminum, aluminum alloy, copper, copper alloy, tungsten, molybdenum, titanium, titanium nitride, and nickel, and
the second electrode film includes at least one among aluminum, aluminum alloy, copper, and copper alloy.

13. The semiconductor device according to claim 1,
wherein the second electrode film includes a conductive material differing from a conductive material of the first electrode film.

14. The semiconductor device according to claim 1,
wherein the first electrode film has a single layer structure, and
the second electrode film has a single layer structure.

15. The semiconductor device according to claim 1,
wherein the IGBT region includes:
a first conductivity type base region formed at the surficial portion of the main surface;
a gate trench structure formed at the main surface so as to pass through the base region; and
a second conductivity type emitter region formed in a region along the gate trench structure in a surficial portion of the base region; and
wherein the plug electrode is electrically connected to the emitter region.

16. The semiconductor device according to claim 15,
wherein the IGBT region includes:
a contact hole formed in the main surface so as to expose the emitter region; and
a first conductivity type contact region formed in a region along the contact hole in the base region; and
wherein the plug electrode is electrically connected to the emitter region and to the contact region in the contact hole.

17. The semiconductor device according to claim 1,
wherein the IGBT regions are formed at the main surface,
the diode regions are formed at the main surface,
the plug electrodes are electrically connected to the IGBT regions,
the first electrode film covers the plug electrodes so as to expose the diode regions, and
the second electrode film covers the first electrode film and the diode regions.

18. A manufacturing method for a semiconductor device comprising:
a step of preparing a wafer having a main surface;
a step of forming an insulating film covering the main surface;
a step of embedding a plug electrode in the insulating film so as to be partially exposed from the insulating film;
a formation step of forming a first electrode film that covers at least the plug electrode; and
an exposure step of exposing the first electrode film to an oxygen atmosphere, subsequent to the formation step of the first electrode film.

19. The manufacturing method for the semiconductor device according to claim 18, further comprising:
a step of forming a second electrode film covering the first electrode film, subsequent to the exposure step.

20. The manufacturing method for the semiconductor device according to claim 18, further comprising:
a step of forming a resist mask, which has a layout that partially exposes the first electrode film, on the first electrode film, prior to the exposure step; and
a removal step of removing an unnecessary part of the first electrode film by an etching method through the resist mask, prior to the exposure step;
wherein the exposure step includes a step of removing the resist mask by an oxygen ashing method, subsequent to the removal step of the first electrode film.
